(19) United States
(12) Patent Application Publication
(10) Pub. No.: US 2026/0282628 A1
(43) Pub. Date: Sep. 17, 2026

(54) SEMICONDUCTOR DEVICE

(71) Applicant: Semiconductor Energy Laboratory Co., Ltd., Atsugi-shi (JP)

(72) Inventors: Koji KUSUNOKI, Isehara (JP); Kazunori WATANABE, Machida (JP)

(21) Appl. No.: 19/557,334

(22) Filed: Mar. 5, 2026

(30) Foreign Application Priority Data
Mar. 13, 2025 (JP) 2025-040662

(51) Int. Cl. H10H 29/32; G09G 3/32; G09G 3/3233; H03K 17/687; H10K 59/121

(52) U.S. Cl. CPC H10H 29/32; H03K 17/6871; H10K 59/1213; H10K 59/1216; G09G 3/32; G09G 3/3233; G09G 2300/0426; G09G 2300/0852; G09G 2310/08

(57) ABSTRACT

A semiconductor device with high display quality is provided. The semiconductor device includes first to eighth transistors, first to third capacitors, and a light-emitting device. A first terminal of the first transistor is connected to a first terminal of the third transistor and a first terminal of the sixth transistor; a gate of the first transistor is connected to a first terminal of the first capacitor and a first terminal of the eighth transistor; a second terminal of the sixth transistor is connected to a first terminal of the seventh transistor and an anode of the light-emitting device; and a second terminal of the third transistor is connected to a second terminal of the eighth transistor and a first terminal of the fourth transistor. A second terminal of the first capacitor is connected to a first terminal of the second transistor, a first terminal of the fifth transistor, a first terminal of the second capacitor, and a first terminal of the third capacitor.

### BACKGROUND OF THE INVENTION

### 1. Field of the Invention

One embodiment of the present invention relates to a semiconductor device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus (including a liquid crystal display apparatus), a light-emitting apparatus, a power storage device, an imaging device, a memory device, a processing device, a signal processing device, a sensor, an arithmetic device (including a processor), an electronic device, a system, a driving method thereof, a manufacturing method thereof, and a testing method thereof.

### 2. Description of the Related Art

Display apparatuses included in, for example, wearable devices for extended reality or cross reality (XR) such as virtual reality (VR) or augmented reality (AR), monitors, mobile phones such as smartphones, wrist-watch-type information terminals, tablet information terminals, notebook personal computers (PCs), and the like have been improved in various aspects in recent years. For example, display apparatuses have been developed, which exhibit improvement such as increasing the screen definition, increasing display quality, increasing the color reproducibility (e.g., DCI-P3 coverage), downsizing the driver circuit, and reducing the power consumption.

In particular, as a method for improving display quality of a display apparatus, correction of the threshold voltage of a driving transistor included in a pixel circuit can be given. Among a plurality of pixel circuits included in a display apparatus, a difference in the amount of source-drain current of driving transistors might be caused depending on a variation in the threshold voltages, which affects the display quality. To prevent the variation in the threshold voltages, a pixel circuit capable of correcting the threshold voltage is disclosed in Patent Documents 1 to 3 and Non-Patent Document 1. In addition, Patent Documents 2 and 3 and Non-Patent Document 1 disclose a pixel circuit that can alleviate the influence of hysteresis exhibited in the characteristics of source-drain current and gate-source voltage (sometimes referred to as I_{ds}−V_{gs} characteristics) of a driving transistor.

### REFERENCE

[Patent Document 1] United States Patent Application Publication No. 2021/351260
[Patent Document 2] United States Patent Application Publication No. 2024/021165
[Patent Document 3] United States Patent Application Publication No. 2024/078963

### Non-Patent Document

[Non-Patent Document 1] H. Kim, et al., SID Symposium Digest of Technical Papers, Vol. 55, Issue 1, 2024, pp. 382-385.

### SUMMARY OF THE INVENTION

There is a tendency to increase the number of transistors in a pixel circuit that incorporates a function of correcting a threshold voltage of a driving transistor, a function of alleviating the influence of hysteresis of the I_{ds}−V_{gs} characteristics, and the like. Thus, the circuit area in the pixel circuit is increased, which might decrease the pixel density in the display apparatus or the aperture ratio of the pixel circuit.

An object of one embodiment of the present invention is to provide a semiconductor device with high display quality. Another object of one embodiment of the present invention is to provide a semiconductor device with a small circuit area. Another object of one embodiment of the present invention is to provide a semiconductor device with low power consumption. Another object of one embodiment of the present invention is to provide a semiconductor device capable of retaining a potential corresponding to an image signal for a long time. Another object of one embodiment of the present invention is to provide a semiconductor device allowing a short takt time. Another object of one embodiment of the present invention is to provide a novel semiconductor device.

Note that objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention achieves at least one of the above objects and the other objects and does not necessarily achieve all of the above objects and the other objects.

(1)

One embodiment of the present invention is a semiconductor device including a first transistor that is a p-channel transistor, second to eighth transistors that are n-channel transistors, first to third capacitors, and a light-emitting device.

One of a source and a drain of the first transistor is electrically connected to one of a source and a drain of the third transistor and one of a source and a drain of the sixth transistor. A gate of the first transistor is electrically connected to a first terminal of the first capacitor and one of a source and a drain of the eighth transistor. The other of the source and the drain of the sixth transistor is electrically connected to one of a source and a drain of the seventh transistor and an anode of the light-emitting device. The other of the source and the drain of the third transistor is electrically connected to the other of the source and the drain of the eighth transistor and one of a source and a drain of the fourth transistor. A second terminal of the first capacitor is electrically connected to one of a source and a drain of the second transistor, one of a source and a drain of the fifth transistor, a first terminal of the second transistor, and a first terminal of the third capacitor. The other of the source and the drain of the first transistor and a second terminal of the second capacitor are electrically connected to a first wiring. A second terminal of the third capacitor is electrically connected to a second wiring. A gate of the third transistor and a gate of the fifth transistor are electrically connected to a third wiring.

(2)

Alternatively, in the above (1) of one embodiment of the present invention, the p-channel transistor may include a first semiconductor layer containing silicon, and each of the n-channel transistors may include a second semiconductor layer containing an oxide semiconductor.

(3)

Alternatively, in the above (2) of one embodiment of the present invention, the silicon may contain low-temperature polysilicon, and the oxide semiconductor may contain indium.

(4)

Alternatively, in the above (3) of one embodiment of the present invention, the oxide semiconductor preferably contains one or more selected from zin and an element M.

Note that the element M is one or more selected from aluminum, gallium, silicon, yttrium, tin, copper, vanadium, chromium, manganese, beryllium, boron, titanium, iron, nickel, germanium, zirconium, molybdenum, lanthanum, cerium, neodymium, hafnium, tantalum, tungsten, magnesium, calcium, strontium, barium, cobalt, and antimony.

(5)

Alternatively, in any one of above (1) to (4) of one embodiment of the present invention, the n-channel transistor may include a back gate. In particular, the gate and the back gate of the n-channel transistor are preferably electrically connected to each other.

One embodiment of the present invention can provide a semiconductor with high display quality. Another embodiment of the present invention can provide a semiconductor device with a small circuit area. Another embodiment of the present invention can provide a semiconductor device with low power consumption. Another embodiment of the present invention can provide a semiconductor device capable of retaining a potential corresponding to an image signal for a long time. Another embodiment of the present invention can provide a semiconductor device allowing a short takt time. Another embodiment of the present invention can provide a novel semiconductor device.

Note that the effects of one embodiment of the present invention are not limited to the effects mentioned above. The effects listed above do not preclude the existence of other effects. The other effects are not described above and will be described below. Effects that are not described in this section are derived from the description of the specification, the drawings, and the like and can be extracted as appropriate from the description by those skilled in the art. One embodiment of the present invention has at least one of the above effects and the other effects. Accordingly, one embodiment of the present invention does not have the effects listed above in some cases.

### BRIEF DESCRIPTION OF THE DRAWINGS

FIGS. 1A and 1B are each a circuit diagram showing a structure example of a pixel circuit.

FIGS. 2A and 2B are each a timing chart showing an operation example of a pixel circuit.

FIGS. 3A and 3B are each a circuit diagram showing an operation example of a pixel circuit.

FIGS. 4A and 4B are each a circuit diagram showing an operation example of a pixel circuit.

FIGS. 5A and 5B are each a circuit diagram showing an operation example of a pixel circuit.

FIGS. 6A and 6B are each a circuit diagram showing an operation example of a pixel circuit.

FIGS. 7A and 7B are each a circuit diagram showing an operation example of a pixel circuit.

FIG. 8 is a timing chart showing an operation example of a pixel circuit.

FIGS. 9A and 9B are each a circuit diagram showing an operation example of a pixel circuit.

FIGS. 10A and 10B are each a circuit diagram showing an operation example of a pixel circuit.

FIGS. 11A and 11B are each a circuit diagram showing an operation example of a pixel circuit.

FIG. 12 is a block diagram showing a display apparatus.

FIG. 13 is a circuit diagram showing a structure example of a pixel circuit.

FIG. 14 is a timing chart showing an operation example of a pixel circuit.

FIG. 15 is a timing chart showing an operation example of a pixel circuit.

FIGS. 16A and 16B are each a circuit diagram showing a structure example of a pixel circuit.

FIGS. 17A and 17B are each a circuit diagram showing a structure example of a pixel circuit.

FIGS. 18A and 18B are each a schematic perspective view showing an example of a display apparatus.

FIGS. 19A and 19B are each a schematic perspective view showing an example of a display apparatus.

FIG. 20 is a block diagram showing a structure example of a display apparatus.

FIG. 21 is a schematic plan view showing an example of a pixel circuit.

FIG. 22 is a schematic plan view showing an example of a pixel circuit.

FIG. 23 is a schematic plan view showing an example of a pixel circuit.

FIG. 24A is a schematic plan view showing an example of a transistor, and FIGS. 24B and 24C are cross-sectional views showing the example of the transistor.

FIG. 25A is a schematic plan view showing an example of a transistor, and FIGS. 25B and 25C are cross-sectional views showing the example of the transistor.

FIG. 26A is a schematic plan view showing an example of a transistor, and FIGS. 26B and 26C are cross-sectional views showing the example of the transistor.

FIG. 27 is a schematic plan view showing an example of a transistor.

FIGS. 28A and 28B are each a schematic cross-sectional view showing a structure example of a display apparatus.

FIG. 29 is a schematic cross-sectional view showing an example of a display apparatus.

FIG. 30A is a schematic cross-sectional view showing a structure example of a display apparatus, and FIGS. 30B and 30C are schematic cross-sectional views showing structure examples of a transistor.

FIG. 31 is a schematic cross-sectional view showing an example of a display apparatus.

FIGS. 32A to 32D are schematic cross-sectional views showing examples of a display apparatus.

FIGS. 33A to 33I each illustrate an example of an electronic device.

FIGS. 34A1 to 34A7 and FIGS. 34B1 to 34B6 are each a circuit diagram showing electrical connection.

### DETAILED DESCRIPTION OF THE INVENTION

### Notes on Description of this Specification

In this specification and the like, a semiconductor device means a device that utilizes semiconductor characteristics, and refers to a circuit including a semiconductor element (e.g., a transistor, a diode, or a photodiode), and a device including the circuit. The semiconductor device also means devices that can function by utilizing semiconductor characteristics. As an example of a semiconductor device, an integrated circuit can be given. As another example of a semiconductor device, a chip including an integrated circuit can be given. As another example of a semiconductor device, an electronic component in which a chip is stored in a package can be given. Furthermore, a memory device, a display apparatus, a light-emitting apparatus, a lighting device, and an electronic device themselves are semiconductor devices in some cases and include a semiconductor device in other cases.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example. Note that A, B, and later-described C each denote an object such as an element, a circuit, a wiring, an electrode, a terminal, a semiconductor layer, or a conductive layer.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

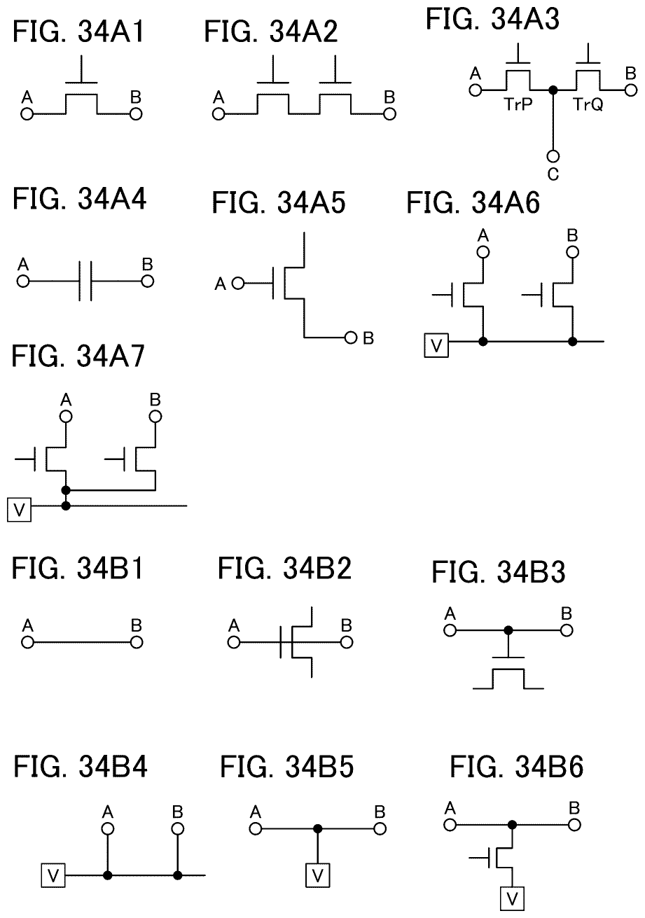

Specific examples of the case of “indirect connection” are described below. First, examples of the case where the expression “A and B are indirectly connected” can be used include the case where A and B are connected to each other through a source and a drain of at least one transistor as in FIGS. 34A1 and 34A2. Another example thereof is the case where A and B are connected to each other with at least one switch therebetween. In the case where the expression “A and B are indirectly connected” can be used, one transistor between A and B is brought into an on state, a conduction state, or a state where current can flow at least once on the assumption that a circuit is in operation. The case where the expression “A and B are indirectly connected” can be used may include a period in which the one transistor between A and B is brought into an off state or a non-conduction state. In the case where the expression “A and B are indirectly connected” can be used, each of a plurality of transistors between A and B is brought into an on state, a conduction state, or a state where current can flow at least once when the plurality of transistors are connected between A and B on the assumption that a circuit is in operation. That is, in the case where the expression “A and B are indirectly connected” can be used, it is not necessary that all of the plurality of transistors be brought into an on state, a conduction state, or a state where current can flow at the same time. Accordingly, in the case where the expression “A and B are indirectly connected” can be used, the plurality of transistors between A and B may be brought into an off state or a non-conduction state at the same time or at different times. For another example, when A and C are connected to each other through a source and a drain of a transistor TrP and B and C are connected to each other through a source and a drain of a transistor TrQ as illustrated in FIG. 34A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 34A4. Another example thereof is the case where there is a gate insulating film of a transistor or the like between A and B as in FIG. 34A5. In this case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 34A6 and 34A7. In this case, the expression “A and B are indirectly connected” cannot be used; however, the expression “A and V are indirectly connected” or “B and V are indirectly connected” can be used. Note that in FIG. 34A3, when A and C are connected to each other through the source and the drain of the transistor TrP, B and C are connected to each other through the source and the drain of the transistor TrQ, and a constant potential Vis supplied to C from a power source, a GND, or the like, the same connection relation as that in FIGS. 34A6 and 34A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus, in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 34B1, 34B2, and 34B3. When A and B are connected to a power source, GND, or the like from which a constant potential V is supplied without a circuit element therebetween as in FIGS. 34B4 and 34B5, the expression “A and B are directly connected”, “A and V are directly connected”, or “B and V are directly connected” can be used. Note that when A (or B) is connected to a constant potential V through a source and a drain of a transistor as in FIG. 34B6, the expression “A and B are directly connected” can also be used. Note that A and V or B and V are connected to each other through the source and the drain of the transistor, and thus, they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus, in the case where the expression “A and B are directly connected” is used, the expression “A and B are electrically connected” can also be used.

Even when independent components are connected to each other in a circuit diagram, one component has functions of a plurality of components in some cases. For example, when part of a “wiring” also functions as an “electrode”, one conductive film has functions of both components: a function of the “wiring” and a function of the “electrode”. For example, when part of a “wiring” also functions as a “terminal”, one conductive film has functions of both components: a function of the “wiring” and a function of the “terminal”. Thus, it can be sometimes said that two or more selected from “electrode”, “wiring”, and “terminal” are formed in an integrated manner. Moreover, the terms “electrode”, “wiring”, and “terminal” are sometimes replaced with the term “region”, for example. Thus, “connection” in this specification includes in its category such a case where one conductive film has functions of a plurality of components.

The term “switch” mentioned in this specification is described as an element that is turned on or off, thereby having a function of controlling whether current flows or not or a function of selecting and switching a path where current flows.

In this specification, the expression “conduction state” refers to a state where current can flow between two input/output terminals, and the expression “non-conduction state” refers to a state where the two input/output terminals are regarded as being electrically disconnected. In this specification, the on state of the switch is included in the scope of “conduction state”, and the off state of the switch is included in the scope of “non-conduction state”. Thus, for the switch in this specification, the expressions “conduction state” and “on state” can be replaced with each other, and the expressions “non-conduction state” and “off state” can be replaced with each other.

In this specification, the expression “electrical continuity” or “conduction state” used in the case where conductive layers are in direct contact with each other refers to a state where current can flow between the conductive layers, for example.

The switch may have two or more terminals through which a current flows, in addition to a control terminal. For example, an electrical switch or a mechanical switch can be used. That is, the switch is not limited to a certain element as long as it has a function of controlling current.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. An analog switch is also included in the examples of the electrical switch. An example of a mechanical switch is a switch using a microelectromechanical systems (MEMS) technology. Such a switch includes an electrode that can be moved mechanically, and its on state and off state are controlled with movement of the electrode.

In this specification and the like, a transistor includes three terminals called a gate, a source, and a drain. The gate is a control terminal for controlling the conduction state and the non-conduction state of the transistor. The two terminals functioning as the source and the drain are input/output terminals of the transistor. Functions of the two input/output terminals of the transistor depend on the conductivity type (n-channel type or p-channel type) of the transistor and the levels of potentials applied to the three terminals of the transistor, and one of the two terminals serves as a source and the other serves as a drain. Therefore, the terms “source” and “drain” can be sometimes used interchangeably in this specification and the like. In this specification, the expressions “one of a source and a drain” and “the other of the source and the drain” are used in description of the connection relationship of a transistor. In this specification, one of a source and a drain is sometimes referred to as a “first electrode of a transistor” or a “first terminal of a transistor”, and the other of the source and the drain is sometimes referred to as a “second electrode of a transistor” or a “second terminal of a transistor”. Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

Examples of the transistor mentioned in this specification include a transistor with a multi-gate structure having two or more gate electrodes in some cases. With the multi-gate structure, channel formation regions are connected in series; accordingly, a plurality of transistors are connected in series. Thus, with the multi-gate structure, the amount of off-state current can be reduced, and the breakdown voltage of the transistor can be increased (the reliability can be improved). Moreover, with the multi-gate structure, a source-drain current (I_{ds}) does not change very much even if a source-drain voltage (V_{ds}) changes when the transistor operates in a saturation region of I_{ds}−V_{ds} characteristics, so that a flat slope of the I_{ds}−V_{ds} characteristics can be obtained. Note that in this specification, the state where the change in current is small in the saturation region is sometimes described using the expression “high saturation characteristics”. Utilizing the I_{ds}−V_{ds} characteristics in this region enables an ideal current source circuit or an active load with an extremely high resistance value. Accordingly, a differential circuit, a current mirror circuit, or the like having excellent properties can be obtained.

In this specification, the term “capacitor” refers to a circuit element including a dielectric and a pair of conductors between which the dielectric is sandwiched. The term “a pair of conductors” of the “capacitor” can be replaced with the term “a pair of electrodes”, “a pair of conductive layers”, “a pair of conductive regions”, “a pair of regions”, “a pair of terminals”, or the like. The terms “one of a pair of electrodes” and “the other of the pair of electrodes” are respectively referred to as a first terminal and a second terminal in some cases.

The threshold voltage of the transistor is generally a voltage generated between a subthreshold region (weak inversion region) and a strong inversion region, and can also be referred to as a voltage at which switching between the subthreshold region and the strong inversion region occurs. An example of a method for measuring the threshold voltage is such that I_{ds}^{1/2}−V_{gs} characteristics are plotted on the basis of I_{ds}−V_{gs} characteristics, and V_{gs} when I_{ds}^{1/2=0} on a tangent with the steepest slope of the I_{ds}^{1/2}−V_{gs} characteristics is regarded as a threshold voltage. In another example of a measuring method, V_{gs} when I_{ds}=1.0×10⁻¹² A in the I_{ds}−V_{gs} characteristics with a drain potential of 1.2 V is regarded as a threshold voltage.

A single circuit element shown in a circuit diagram may include a plurality of circuit elements. For example, a single resistor shown in a circuit diagram may be two or more resistors electrically connected to each other in series. For another example, a single capacitor shown in a circuit diagram may be two or more capacitors electrically connected to each other in parallel. For another example, a single transistor shown in a circuit diagram may be two or more transistors which are connected to each other in series and whose gates are connected to each other. For another example, a single switch shown in a circuit diagram may be a switch including two or more transistors which are electrically connected to each other in series or in parallel and whose gates are electrically connected to each other.

In this specification and the like, a node can be referred to as a terminal, a wiring, an electrode, a conductive layer, a conductor, an impurity region, or the like depending on the circuit configuration and the device structure. Furthermore, a terminal, a wiring, and the like can be referred to as a node.

Ordinal numbers such as “first”, “second”, and “third” in this specification and the like are used in order to avoid confusion among components. Thus, the terms do not limit the number of components. The terms do not limit the order of components including, for example, the order of steps, the stacking order of layers, either. A term without an ordinal number in this specification might be provided with an ordinal number in a claim in order to avoid confusion among components. A term with an ordinal number in this specification might be provided with a different ordinal number in a claim. Moreover, a term with an ordinal number in this specification might not be provided with any ordinal number in a claim and the like. For example, a component provided with an ordinal number “first” in one embodiment in this specification can be a component provided with a different ordinal number such as “second” or “third” in other embodiments or the scope of claims. For another example, a component provided with an ordinal number “first” in one embodiment in this specification can be omitted in other embodiments or the scope of claims.

In this specification and the like, a timing chart is used in some cases to describe an operation method of a semiconductor device. In this specification and the like, the timing chart shows an ideal operation example, and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed as appropriate depending on the circumstances. For example, even when two periods are shown to have an equal length, the two periods have different lengths in some cases. Furthermore, for example, even when one of two periods is shown longer than the other, the two periods can have the equal length in some cases, or the one of the two periods has a shorter length than the other in other cases. To clearly show the timing chart, two or more overlapping signals are sometimes shown to be intentionally shifted from each other, for example.

The embodiments in this specification are described with reference to drawings. Note that the embodiments can be implemented in many different modes, and it will be readily appreciated by those skilled in the art that modes and details can be changed in various ways without departing from the spirit and scope of the present invention. Therefore, the present invention should not be construed as being limited to the description of the embodiments. Note that in the structures of the invention described in the embodiments, the same portions or portions having similar functions are denoted by the same reference numerals in different drawings and the description of such portions is not repeated in some cases. In order to clarify a component to be described in drawings such as perspective views, illustration of another component might be omitted.

In this specification and the like, when a plurality of components denoted by the same reference numerals need to be distinguished from each other, identification signs such as “_1”, “[n]”, and “[m,n]” are sometimes added to the reference numerals. Components denoted with identification signs such as “_1”, “[n]”, and “[m,n]” in drawings and the like are sometimes denoted without such identification signs in this specification and the like when the components do not need to be distinguished from each other.

In the drawings of this specification, the size, the layer thickness, or the region is exaggerated for clarity in some cases. Thus, the size, the layer thickness, or the region is not limited to the shown scale. The drawings are schematic views showing ideal examples, and embodiments of the present invention are not limited to shapes, values, or the like shown in the drawings. For example, the following can be included: a variation in a signal, a voltage, or a current due to noise or difference in timing.

### Embodiment 1

In this embodiment, a structure example of a pixel circuit that is a semiconductor device of one embodiment of the present invention will be described.

### Structure Example of Pixel Circuit

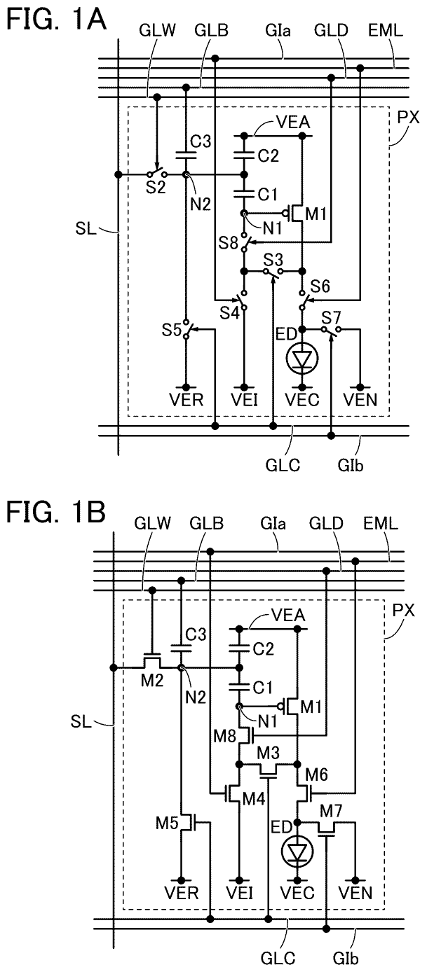

A pixel circuit PX shown in FIG. 1A is a structure example of a pixel circuit that is a semiconductor device of one embodiment of the present invention. The pixel circuit PX has a function of correcting the threshold voltage of a driving transistor and a function of alleviating the influence of hysteresis that appears in the I_{ds}−V_{gs} characteristics of the driving transistor. When the pixel circuits PX are arranged as pixel circuits in a cell array provided in a display apparatus, a variation in the threshold voltages of the driving transistors included in the pixel circuits can be corrected and a desired current can flow between an anode and a cathode of a light-emitting device, leading to enhancement in display quality of the display apparatus. Furthermore, a fluctuation in the source-drain current of the driving transistor due to the influence of hysteresis that appears in the I_{ds}−V_{gs} characteristics can be made small, which can also enhance the display quality of the display apparatus.

The pixel circuit PX includes a transistor M1 that is a p-channel transistor, switches S2, S3, S4, S5, S6, S7, and S8, capacitors C1, C2, and C3, and a light-emitting device ED, for example.

As each of the switches S2 to S8, an electrical switch can be used, for example. Examples of the electrical switch include a transistor. Other than the electrical switch, a mechanical switch may be used as each of the switches S2 to S8, for example.

FIG. 1B shows an example of the pixel circuit PX in FIG. 1A. The pixel circuit PX shown in FIG. 1B has a circuit configuration in which transistors M2, M3, M4, M5, M6, M7, and M8, which are n-channel transistors, are used as the switches S2 to S8 shown in FIG. 1A.

As the transistor M1 in FIG. 1B, a transistor containing silicon in its channel formation region (also referred to as Si transistor) can be used. Use of a Si transistor as the transistor M1 makes it possible to increase the amount of on-state current (current flowing between a source and a drain in an on state of a transistor) flowing in the transistor M1. Applicable silicon is amorphous silicon, microcrystalline silicon, polycrystalline silicon, or a single crystal silicon. Low temperature polysilicon (LTPS) is included as a type of polycrystalline silicon. LTPS can be formed at a temperature equivalent to that for forming amorphous silicon and thus enables the manufacturing cost to be reduced particularly. In this specification, a transistor containing LTPS in its channel formation region is referred to as an LTPS transistor in some cases.

Each of the transistors M2 to M8 in FIG. 1B is preferably a transistor including an oxide semiconductor in its channel formation region (also referred to as OS transistor). Since the OS transistor has a characteristic of an extremely low source-drain current flowing in an off state (such a current is also referred to as off-state current), a malfunction due to the off-state current can be prevented. Examples of an oxide semiconductor include indium oxide and indium gallium zinc oxide. In particular, a transistor containing indium oxide in a channel formation region (hereinafter referred to as IO transistor) can have characteristics of a low off-state current and a high on-state current. Thus, when an IO transistor is used as each of the transistors M2 to M8, a malfunction due to an off-state current can be prevented, and a high operation speed owing to a high on-state current can be achieved. Note that indium oxide will be described later in Embodiment 3.

Besides an OS transistor, the Si transistor applicable to the transistor M1 can be used as each of the transistors M2 to M8.

A first terminal of the transistor M1 is connected to a first terminal of the transistor M3 and a first terminal of the transistor M6, and a gate of the transistor M1 is connected to a first terminal of the transistor M8 and a first terminal of the capacitor C1. A second terminal of the transistor M3 is connected to a second terminal of the transistor M8 and a first terminal of the transistor M4. A second terminal of the transistor M6 is connected to a first terminal of the transistor M7 and an anode of the light-emitting device ED. A first terminal of the transistor M2 is connected to a second terminal of the capacitor C1, a first terminal of the capacitor C2, a first terminal of the capacitor C3, and a first terminal of the transistor M5.

In particular, in FIG. 1B, a connection portion of the gate of the transistor M1, the first terminal of the transistor M8, and the first terminal of the capacitor C1 is denoted by a node N1. A connection portion of the first terminal of the transistor M2, the second terminal of the capacitor C1, the first terminal of the capacitor C2, the first terminal of the capacitor C3, and the first terminal of the transistor M5 is denoted by a node N2.

A second terminal of the transistor M1 and a second terminal of the capacitor C2 are connected to a wiring VEA. A second terminal of the transistor M2 is connected to a wiring SL, and a gate of the transistor M2 is connected to a wiring GLW. A gate of the transistor M3 and a gate of the transistor M5 are connected to a wiring GLC. A second terminal of the transistor M4 is connected to a wiring VEI, and a gate of the transistor M4 is connected to a wiring GIa. A second terminal of the transistor M5 is connected to a wiring VER. A gate of the transistor M6 is connected to a wiring EML. A second terminal of the transistor M7 is connected to a wiring VEN, and a gate of the transistor M7 is connected to a wiring GIb. A gate of the transistor M8 is connected to a wiring GLD.

The wiring VEA has a function of a wiring supplying a fixed potential, for example. The fixed potential can be, for example, an anode potential supplied to the anode of the light-emitting device ED.

A wiring VEC has a function of a wiring supplying a fixed potential, for example. The fixed potential can be, for example, a cathode potential supplied to a cathode of the light-emitting device ED.

The wiring VEI has a function of a wiring supplying a fixed potential, for example. The fixed potential can be, for example, an initialization potential supplied to the node N1. The wiring VEN has a function of a wiring for releasing electric charge accumulated in the anode of the light-emitting device ED, for example. Thus, the wiring VEN preferably supplies a fixed potential lower than the anode potential. The fixed potential can be equal to the fixed potential supplied by the wiring VEI.

The wiring VER has a function of a wiring supplying a fixed potential, for example. The fixed potential can be, for example, a reference potential supplied to the node N2.

The wiring SL has a function of a wiring transmitting an image signal to be written to the pixel circuit PX, for example.

The wiring EML has a function of a wiring for controlling switching of the on state and the off state of the transistor M6, for example. The wiring GLW has a function of a wiring for controlling switching of the on state and the off state of the transistor M2, for example. The wiring GLD serves as a wiring for controlling switching of the on state and the off state of the transistor M8, for example. The wiring GLC has a function of a wiring for controlling switching of the on state and the off state of each of the transistor M3 and the transistor M5, for example.

The wiring GIa has a function of a wiring for controlling switching of the on state and the off state of the transistor M4, for example. The wiring GIb has a function of a wiring for controlling switching of the on state and the off state of the transistor M7, for example.

The transistor M1 has a function of a driving transistor in the pixel circuit PX. In particular, the transistor M1 preferably has high saturation in a saturation region of the I_{ds}−V_{ds} characteristics. To reach the high saturation in the saturated region, the transistor M1 preferably has a large channel length.

The transistor M2 has a function of a switching transistor for supplying a potential corresponding to an image signal supplied from the wiring SL to the node N2 or stopping the input of the image signal to the node N2. Accordingly, the wiring GLW connected to the gate of the transistor M2 can be regarded as a wiring for transmitting a signal for controlling whether or not an image signal is input from the wiring SL to the node N2. Thus, the transistor M2 is also referred to as a selection transistor in some cases.

The transistor M2 also has a function of retaining a potential of the node N2 in collaboration with the transistor M5 described later, besides a function of a selection transistor. Therefore, the above-described OS transistor having an extremely low off-state current is preferably used as the transistor M2 and the transistor M5. Use of OS transistors as the transistor M2 and the transistor M5 enables the potential of the node N2 to be retained for a long period of time; thus, operation at a low frame rate at a variable refresh rate (VRR) can be performed in the pixel circuit PX.

When one transistor M2 serves as the selection transistor and the transistor that retains the potential of the node N2 is provided as shown in FIG. 1B, the number of transistors in the pixel circuit PX can be small.

The transistor M3 has a function of a switching transistor for controlling switching of the conduction state and the non-conduction state between the first terminal of the transistor M1 and the second terminal of the transistor M8. Accordingly, the wiring GLC connected to the gate of the transistor M3 can be regarded as a wiring for transmitting a signal for controlling switching of the conduction state and the non-conduction state.

The transistor M8 has a function of retaining a potential of the node N1. Accordingly, the transistor M8 has a function of a switching transistor. The transistor M8 connected in series with the second terminal of the transistor M3 preferably has the same polarity as the transistor M3. Specifically, each of the transistor M3 and the transistor M8 is preferably an n-channel transistor, for example. It is particularly preferable to use the above-described OS transistors having an extremely low off-state current as the transistors M3 and M8. When the transistor M3 and the transistor M8 have the same polarity, the effective channel length of one transistor that is a combination of the transistor M3 and the transistor M8 can be increased, so that the leakage current in the current path between the node N1 and the first terminal of the transistor M1 can be reduced. The above applies to the transistor M4 connected in series with the second terminal of the transistor M8.

The transistor M4 has a function of a switching transistor for supplying a potential of the wiring VEI to the second terminal of the transistor M3 and the second terminal of the transistor M8 or for stopping the supply of the potential. Accordingly, the wiring GIa connected to the gate of the transistor M4 can be regarded as a wiring for transmitting a signal for controlling whether or not the potential of the wiring VEI is supplied to the second terminal of the transistor M3 and the second terminal of the transistor M8.

The transistor M5 has a function of a switching transistor for supplying a potential of the wiring VER to the node N2 or stopping the supply of the potential. Accordingly, the wiring GLC connected to the gate of the transistor M5 can be regarded as a wiring for transmitting a signal for controlling whether or not the potential of the wiring VER is supplied to the node N2. As described above, the transistor M5 also has a function of retaining the potential of the node N2.

The transistor M6 has a function of a switching transistor for supplying current to the anode of the light-emitting device ED or stopping the supply of the current. Accordingly, the wiring EML connected to the gate of the transistor M6 can be regarded as a wiring for transmitting a signal that controls a supply or a stop of the supply of current to the light-emitting device ED. In particular, when the above-described OS transistor having an extremely low off-state current is used as the transistor M6, the light-emitting device ED can be prevented from emitting minute light due to the off-state current of the transistor M6.

The transistor M7 has a function of a switching transistor for supplying a potential of the wiring VEN to the anode of the light-emitting device ED or stopping the supply of the potential. Accordingly, the wiring GIb connected to the gate of the transistor M7 can be regarded as a wiring for transmitting a signal for controlling whether or not the potential of the wiring VEN is supplied to the anode of the light-emitting device ED. For example, when the potential of the wiring VEN is lower than the potential of the wiring VEA, the second terminal of the transistor M7 functions as a source, which indicates that an n-channel transistor is preferable as the transistor M7. Also, an OS transistor is preferable to reduce the off-state current.

As described above, the transistors M2 to M8 each have a function of a switching transistor. These transistors preferably have a high on-state current. Thus, in order to increase the on-state current, these transistors preferably have short channel lengths. In view of the above, the transistors M2 to M8 are not required to have saturation as favorable as the transistor M1; thus, the channel length of each of the transistors M2 to M8 is preferably shorter than that of the transistor M1.

The light-emitting device ED can be a self-luminous light-emitting element such as an organic EL element that is also referred to as an organic light-emitting diode (OLED), for example. As another example of the light-emitting device ED, a self-luminous light-emitting element such as a light-emitting diode (LED), a micro LED, a quantum-dot LED (QLED), or a semiconductor laser can be used.

### Operation Example 1 of Pixel Circuit

Next, an operation example of the pixel circuit PX in FIG. 1B, for alleviating the influence of hysteresis of the I_{ds}−V_{gs} characteristics of the transistor M1 and correcting the threshold voltage of the transistor M1, is described.

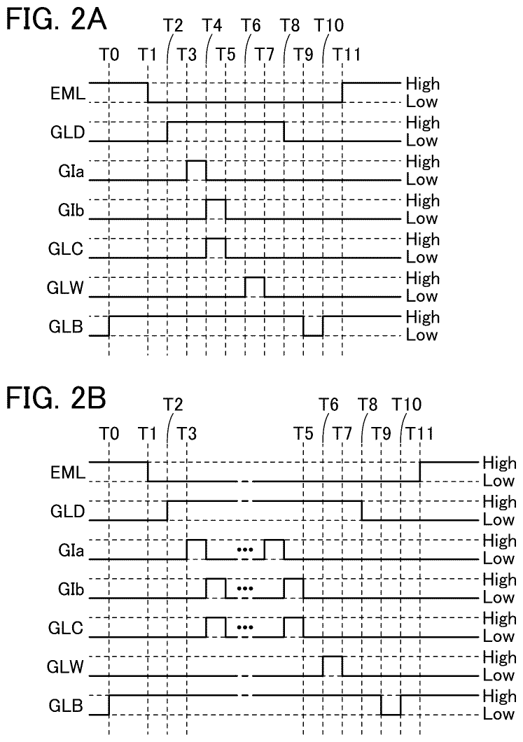

FIG. 2A is a timing chart showing the operation example of the pixel circuit PX. The timing chart shows potential fluctuations of the wiring EML, the wiring GLD, the wiring GIa, the wiring GIb, the wiring GLC, the wiring GLW, and a wiring GLB during the period from Time TO to Time T11 and in the vicinity of the period.

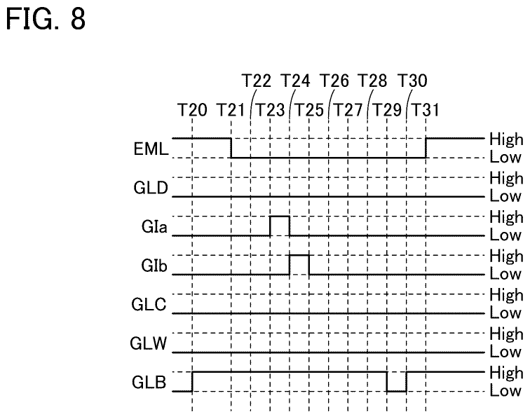

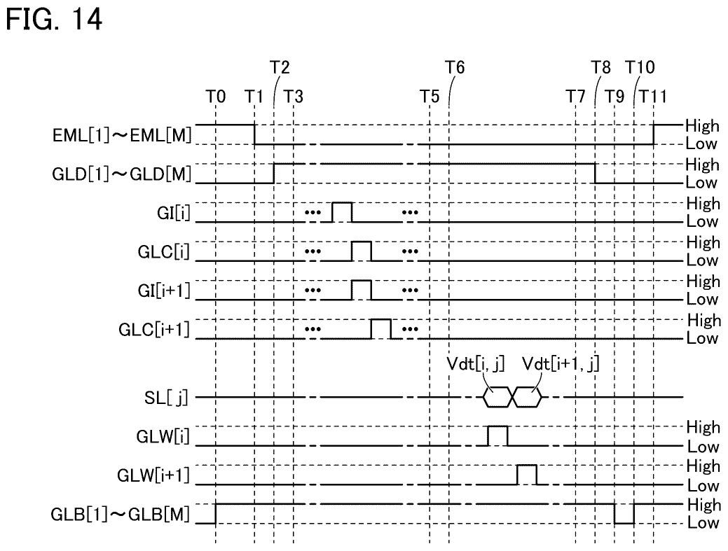

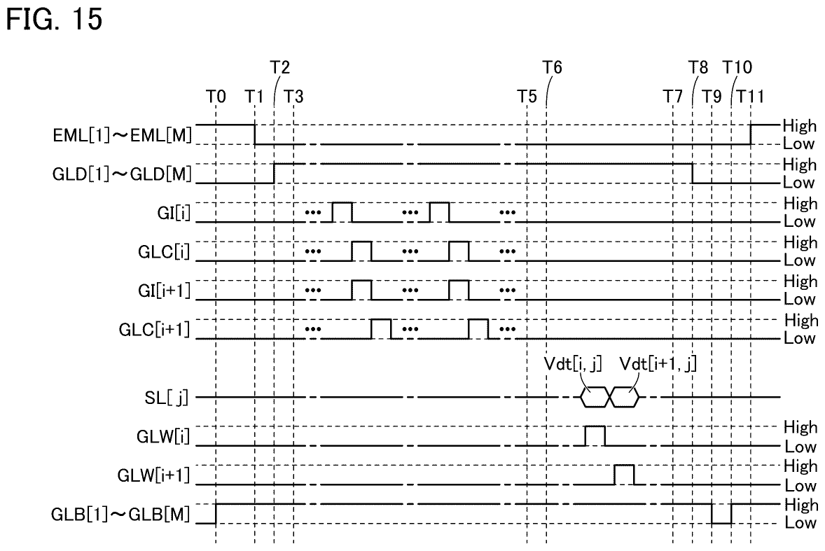

In the timing chart in FIG. 2A, the reference numerals of the wirings are shown on the left side, and the potential levels are shown on the right side as “High” and “Low” representing a high-level potential and a low-level potential. The same applies to timing charts in FIG. 2B, FIG. 8, FIG. 14, and FIG. 15 described later.

In this operation example, a fixed potential supplied by the wiring VEA is referred to as Vₐₙ, and a fixed potential supplied by the wiring VEI is referred to as Vᵢₙ. Note that Vₐₙ is higher than Vᵢₙ. A fixed potential supplied by the wiring VER is V_{rf}. A fixed potential supplied by the wiring VEN is Vₐᵢ. In addition, a potential corresponding to an image signal supplied by the wiring SL is V_{dt}.

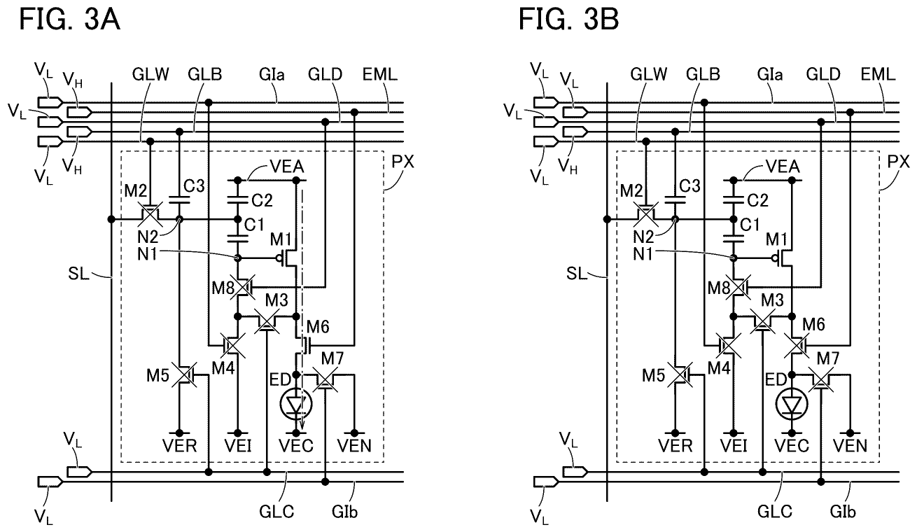

FIGS. 3A and 3B, FIGS. 4A and 4B, FIGS. 5A and 5B, and FIGS. 6A and 6B, and FIGS. 7A and 7B show specific circuit operations in Time T0 to Time T11 described in the timing chart in FIG. 2A. Transistors marked with crosses indicate that the transistors are in an off state at that time.

### [Time T0]

At Time T0, a high-level potential is supplied to each of the wiring EML and the wiring GLB, and a low-level potential is supplied to each of the wiring GLD, the wiring GIa, the wiring GIb, the wiring GLC, and the wiring GLW. Accordingly, the transistor M6 is turned on, and the transistors M2 to M5, M7, and M8 are turned off. A second terminal of the capacitor C3 is supplied with the high-level potential (see FIG. 3A).

At Time T0, a potential corresponding to an image signal is retained in advance at the node N1 and the node N2. At Time T0, when the potential of the second terminal of the capacitor C3 is set at a high level, the potential of the node N2 (the first terminal of the capacitor C3) is increased by capacitive coupling, and the potential of the node N1 (the first terminal of the capacitor C1) is also increased.

As described above, since the transistor M6 is in an on state at Time T0, the source-drain current of the transistor M1, the amount of which corresponds to the image signal, flows from the wiring VEA to the wiring VEC through the transistor M1, the transistor M6, and the light-emitting device ED. Note that a dashed-dotted arrow in FIG. 3A denotes the source-drain current. Accordingly, the current, the amount of which corresponds to the image signal, flows between the anode and the cathode of the light-emitting device ED, so that the light-emitting device ED emits light with luminance corresponding to the image signal.

### [Time T1]

At Time T1, a low-level potential is supplied to the wiring EML. Accordingly, the transistor M6 is turned off, and the source-drain current of the transistor M1, the amount of which corresponds to the above-described image signal, does not flow between the anode and the cathode of the light-emitting device ED. Thus, at Time T1, light emission from the light-emitting device ED is stopped (see FIG. 3B).

### [Time T2]

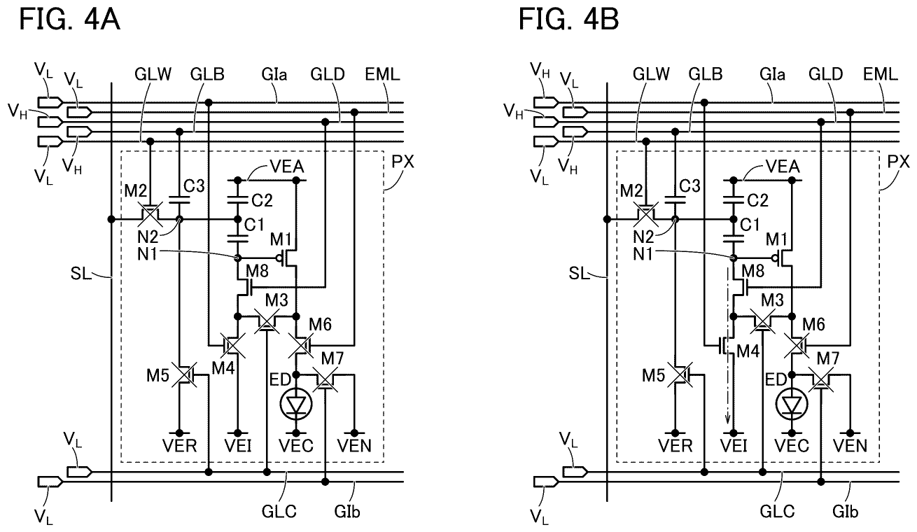

At Time T2, a high-level potential is supplied to the wiring GLD. Accordingly, the transistor M8 is turned on, so that electrical continuity is established between the node N1 and the first terminal of the transistor M4 (see FIG. 4A).

### [Time T3]

At Time T3, a high-level potential is supplied to the wiring GIa. Accordingly, the transistor M4 is turned on, so that the gate of the transistor M1 and the first terminal of the capacitor C1 (the node N1) have electrical continuity with the wiring VEI (see FIG. 4B). Thus, the potential of the node N1 becomes Vᵢₙ that is the fixed potential supplied by the wiring VEI. Note that a dashed-dotted arrow in FIG. 4B denotes the current flowing from the node N1 to the wiring VEI. Since Vₐₙ supplied by the wiring VEA is a potential higher than Vᵢₙ as described above, the transistor M1 remains in an on state.

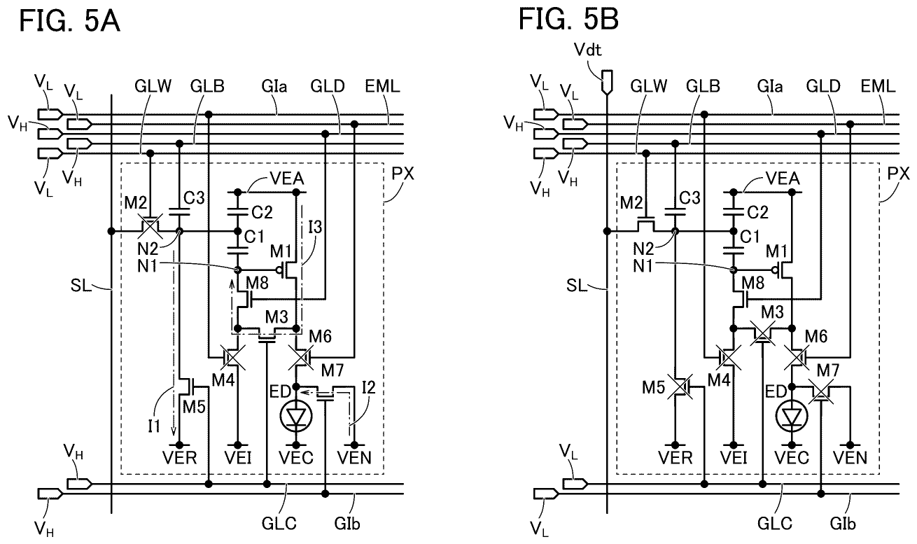

Note that the wiring GIa is supplied with a low-level potential at Time T4 described later. Thus, the transistor M4 is turned off by Time T4, so that the gate of the transistor M1 and the first terminal of the capacitor C1 (the node N1) have no electrical continuity with the wiring VEI, and a release of charge from the node N1 to the wiring VEI is stopped (see FIG. 5A). The timing at which a low-level potential is supplied to the wiring GIa may be the same as that at which it is Time T4 as shown in FIG. 2A.

### [Time T4]

At Time T4, a high-level potential is supplied to each of the wiring GIb and the wiring GLC. Accordingly, the transistor M3, the transistor M5, and the transistor M7 are turned on (see FIG. 5A).

When the transistor M5 is turned on, electrical continuity is established between the node N2 and the wiring VER, and the potential of the node N2 becomes V_{rf} that is the fixed potential supplied by the wiring VER. That is, the potential corresponding to the image signal, which has been written to the node N2, is reset. Note that in FIG. 5A, a current I1 flowing from the wiring VER to the node N2 is denoted by a dashed-dotted arrow. Although the arrow direction of the current I1 is the direction from the node N2 to the first terminal of the transistor M5 in FIG. 5A, the arrow direction may be from the first terminal of the transistor M5 to the node N2. Thus, a voltage of V_{rf}−Vₐₙ is written between the first terminal and the second terminal of the capacitor C2.

When the transistor M7 is turned on, electrical continuity is established between the anode of the light-emitting device ED and the wiring VEN, and the potential of the anode of the light-emitting device ED becomes Vₐᵢ that is the fixed potential supplied by the wiring VEN. Accordingly, the potential applied to the anode of the light-emitting device ED is reset. Note that in FIG. 5A, a current I2 flowing from the wiring VEN to the anode of the light-emitting device ED is denoted by a dashed-dotted arrow. Although the arrow direction of the current I2 is the direction from the wiring VEN to the anode of the light-emitting device ED in FIG. 5A, the arrow direction may be from the light-emitting device ED to the wiring VEN.

When the transistor M3 is turned on, electric charge flowing from the wiring VEA is accumulated in the gate of the transistor M1 through the source and the drain of each of the transistor M1, the transistor M3 and the transistor M8, and the potential of the gate of the transistor M1 increases until the transistor M1 is turned off. For example, the potential of the gate of the transistor M1 is Vᵢₙ just before the transistor M3 is turned on, and the potential of the gate of the transistor M1 increases to Vₐₙ+Vₜₕ after the transistor M3 is turned on. Note that Vₜₕ is the threshold voltage of the transistor M1 and is lower than 0 V. Thus, a voltage of Vₐₙ+Vₜₕ−V_{rf} is written between the first terminal and the second terminal of the capacitor C1. Note that in FIG. 5A, a current I3 flowing from the wiring VEA to the node N1 through the source and the drain of each of the transistor M1, the transistor M3, and the transistor M8 is denoted by a dashed-dotted arrow. Although the arrow direction of the current I3 is from the wiring VEA to the node N1 in FIG. 5A, the arrow direction may be from the node N1 to the wiring VEA.

The wiring GIb and the wiring GLC are supplied with a low-level potential at Time T5. Thus, after Time T5, the transistor M3, the transistor M5, and the transistor M7 are brought into an off state. Specifically, when the transistor M3 is turned off, the node N1 is brought into a floating state. When the transistor M7 is turned off, the wiring VEN and the anode of the light-emitting device ED are electrically disconnected, so that a release of charge from the anode of the light-emitting device ED to the wiring VEN is stopped. Note that the timing at which a low-level potential is supplied to the wiring GIb or the wiring GLC may be the same as that at which it is Time T5 as shown in FIG. 2A.

When the transistor M3 and the transistor M5 are turned off, the voltage of Vₐₙ+Vₜₕ−V_{rf} is retained in the capacitor C1, and the voltage of V_{rf}−Vₐₙ is retained in the capacitor C2. At this time, the gate-source voltage of the transistor M1 becomes Vₜₕ.

### [Time T6]

At Time T6, a high-level potential is supplied to the wiring GLW. Accordingly, transistor M2 is turned on (see FIG. 5B).

In addition, at Time T6, the wiring SL is supplied with V_{dt} as a potential corresponding to the image signal. Accordingly, the potential of the node N2 changes from V_{rf} to V_{dt}. The voltage between the first terminal and the second terminal of the capacitor C2 is Vₐₙ−V_{dt}.

Since the node N1 is in a floating state, changing the potential of the node N2 is followed by a change in the potential of the node N1 due to capacitive coupling of the capacitor C1. Since the amount of change in the potential of the node N2 is V_{dt}−V_{rf}, the amount of change in the potential of the node N1 is also V_{dt}−V_{rf} on the assumption that the capacitive coupling coefficient of the node N1 with respect to the node N2 is 1. Thus, the potential of the node N1 becomes Vₐₙ+Vₜₕ+V_{dt}−V_{rf}.

### [Time T7]

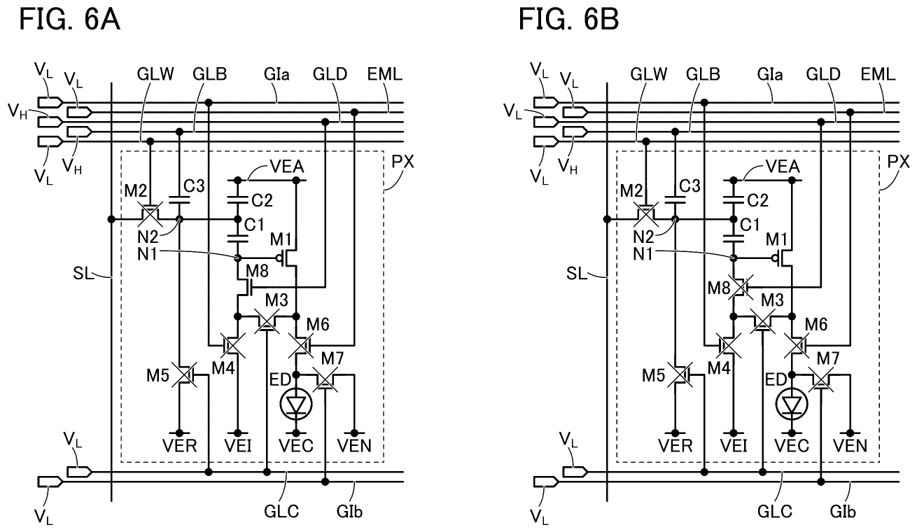

At Time T7, a low-level potential is supplied to the wiring GLW. Accordingly, the transistor M2 is turned off (see FIG. 6A).

### [Time T8]

At time T8, a low-level potential is supplied to the wiring GLD. Accordingly, the transistor M8 is turned off (see FIG. 6B).

### [Time T9]

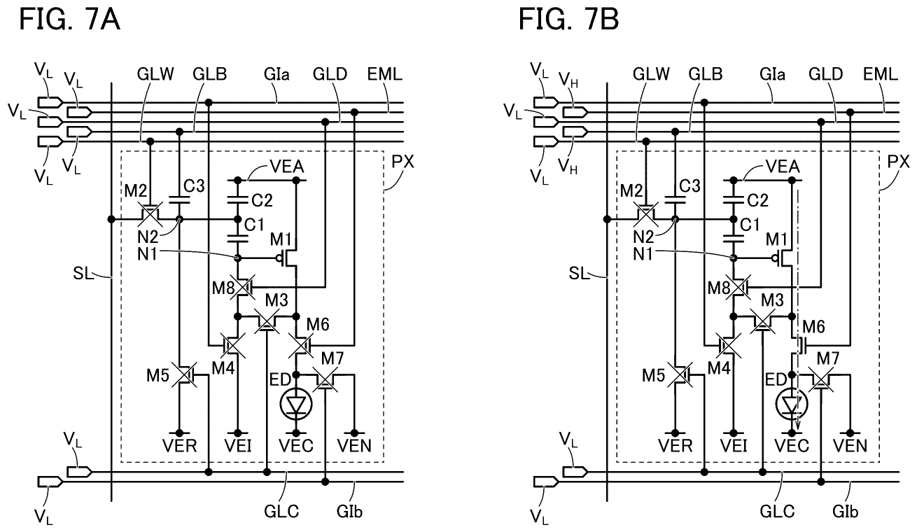

At Time T9, the potential of the wiring GLB decreases from the high-level potential to the low-level potential (see FIG. 7A). Since the node N2 is in a floating state, a decrease in the potential of the wiring GLB is followed by a decrease in the potential of the node N2 due to capacitive coupling by the capacitor C3. Similarly, the decrease in the potential of the node N2 is followed by a decrease in the potential of the node N1 due to capacitive coupling by the capacitor C1. The fluctuation amounts of potentials at the node N1 and the node N2 are determined in accordance with the capacitance distribution of the capacitors C1 to C3. That is, the fluctuation amount can be determined at the design stage of the pixel circuit PX.

The capacitance values of the capacitors C1 to C3 are preferably sufficiently larger than the gate capacitance value of the transistor M1. In this case, the fluctuation amount of the potential of the node N2, ΔV_{N2}, can be expressed as ΔV_{N2}≈ΔV_{GLB}×C₃/(C₁+C₂+C₃) where ΔV_{GLB} represents the fluctuation amount of the potential of the wiring GLB and C₁, C₂, and C₃ represent electrostatic capacitance values of the capacitors C1, C2, and C3. When the fluctuation amount of the potential of the node N1 is substantially equal to the fluctuation amount of the potential of the node N2 (ΔV_{N2}) the fluctuation amount of the potential of the transistor M1 can be determined depending on the amount of electrostatic capacitance of the capacitor C3 and ΔV_{GLB}. Therefore, in the case of increasing the fluctuation amount of the potential of the transistor M1, the electrostatic capacitance value of the capacitor C3 is preferably larger than the electrostatic capacitance values of the capacitors C1 and C2.

Here, the potential of the node N1 decreases from Vₐₙ+Vₜₕ+V_{dt}−V_{rf} to Vₜₕ+V_{dt}−V_{rf} in accordance with the decrease in the potential of the wiring GLB. That is, the amount of the voltage drop at the node N1 is Vₐₙ, and thus the potential of the gate of the transistor M1 decreases from Vₐₙ+Vₜₕ+V_{dt}−V_{rf} to Vₜₕ+V_{dt}−V_{rf}. Then, the transistor M1 is given the amount of change in the gate voltage due to capacitive coupling of the capacitors C1 to C3, so that the gate voltage applied to the transistor M1 is increased (the gate potential of the transistor M1 can be significantly decreased in the pixel circuit PX in FIG. 1B and the operation example in FIG. 2A). An increase in the gate voltage is referred to as an on-bias voltage in this specification.

A decrease in the gate potential of the transistor M1 at Time T9 enables a decrease in the gate-source voltage of the transistor M1 and application of the on-bias voltage. Thus, it is possible to alleviate the influence of hysteresis of the I_{ds}−V_{gs} characteristics of the transistor M1; the hysteresis might be generated when the gate potential of the transistor M1 (potential of the node N1) changes at Time T6.

Assuming that the gate of the transistor M1 is a reference, a decrease in the gate potential of the transistor M1 allows the source potential of the transistor M1 to increase relatively.

In the case where the source potential of the transistor M1 is directly increased, a structure example (not illustrated) to be considered is such that a fixed potential of the wiring VEA is applied to the transistor M1 by turning on a switch provided between the second terminal of the transistor M1 and the wiring VEA. In that case, charge flows from the wiring VEA to the second terminal of the transistor M1 when the switch is turned on, so that a fixed potential supplied to the wiring VEA sometimes decreases temporarily. A power supply circuit supplying a fixed potential to the wiring VEA compensates for the decreased voltage, and thus the power consumption of the power supply circuit is increased. By contrast, when the source potential of the transistor M1 is relatively increased by the operation at Time T9, the charge does not flow to the pixel circuit PX; thus, the power consumption can be lower than the above case where the source potential of the transistor M1 is directly increased.

### [Time T10]

At Time T10, the potential of the wiring GLB decreased at Time T9 increases up to a high-level potential. The voltages supplied from the wirings to the pixel circuit PX at Time T10 are equivalent to those at Time T8, and the potential of the node N1 returns from Vₜₕ+V_{dt}−V_{rf} to Vₐₙ+Vₜₕ+V_{dt}−V_{rf}.

### [Time T11]

At Time T11, a high-level potential is supplied to the wiring EML (see FIG. 7B). Accordingly, the transistor M6 is turned on, and the source-drain current of the transistor M1, which corresponds to the image signal (Vat as the potential) written at Time T6, flows from the wiring VEA to the wiring VEC through the transistor M1, the transistor M6, and the light-emitting device ED. As a result, the current, the amount of which corresponds to the image signal, flows between the anode and the cathode of the light-emitting device ED, so that the light-emitting device ED emits light with luminance corresponding to the image signal. In particular, the amount of the current is determined by a difference between the gate-source voltage (Vₐₙ+Vₜₕ+V_{dt}−V_{rf})−Vₐₙ and the threshold voltage Vₜₕ of the transistor M1; the difference is V_{dt}−V_{rf}. Thus, a current that does not depend on the threshold voltage of the transistor M1 can flow through the light-emitting device ED. Note that a dashed-dotted arrow in FIG. 7B denotes the current flowing from the node N1 to the wiring VEI.

With the operation from Time T1 to Time T11 described above, the threshold voltage of the transistor M1 can be corrected. Accordingly, the current, the amount of which corresponds to the image signal, can be appropriately supplied between the anode and the cathode of the light-emitting device ED, so that the light-emitting device ED can emit light with desired luminance.

Since the gate potential of the transistor M1 changes at the time of correcting the threshold voltage in the above operation example, the hysteresis of the I_{ds}−V_{gs} characteristics of the transistor M1 might affect the circuit operation at the correcting timing. The timing chart in FIG. 2B is a variation of the timing chart in FIG. 2A and includes an operation for alleviating the influence of the hysteresis.

The timing chart in FIG. 2B is different from the timing chart in FIG. 2A in that a potential having a pulse width is supplied a plurality of times to the wiring GIa, the wiring GIb, and the wiring GLC during the period from Time T3 to Time T5. Specifically, during the period from Time T3 to Time T5 in the timing chart in FIG. 2B, the operation from Time T3 to Time T5 in the timing chart in FIG. 2A is repeated.

By performing the operation during the period from Time T3 to Time T5 in the timing chart in FIG. 2B, the operation shown in FIG. 4B and FIG. 5A is repeated in the pixel circuit PX. The repetition of the operation enables the gate potential of the transistor M1 to be increased and lowered repeatedly. Accordingly, the influence of hysteresis of the I_{ds}−V_{gs} characteristics of the transistor M1 can be alleviated, and the fluctuation of source-drain current of the transistor M1 due to the influence can be prevented. Thus, the current, the amount of which corresponds to the image signal, can be appropriately supplied between the anode and the cathode of the light-emitting device ED, so that the light-emitting device ED can emit light with desired luminance. That is, when the pixel circuit PX operates in accordance with the above timing chart, the color reproducibility of the pixel circuit PX can be increased and the display quality of the display apparatus can be improved. Note that, depending on the degree of the influence of the hysteresis of the I_{ds}−V_{gs} characteristics of the transistor M1, each of the wiring GIa, the wiring GIb, and the wiring GLC may be supplied twice, three times, or four or more times with a potential having a pulse width (also referred to as pulse signal, pulse voltage, pulse potential, or simply pulse in some cases) in the operation during the period from Time T3 to Time T5 of the timing chart in FIG. 2B.

Although the timing chart in FIG. 2B shows an example where the wiring GIb is also supplied with a potential having a pulse width a plurality of times during the period from Time T3 to Time T5, a potential having a pulse width may be supplied one time to the wiring GIb in the operation during the period from Time T3 to Time T5.

### Operation Example 2 of Pixel Circuit

Next, an operation example of the pixel circuit PX, which is different from the timing charts in FIGS. 2A and 2B, is described.

FIG. 8 is a timing chart showing an operation example of the pixel circuit PX in which data corresponding to a written image signal is retained and the influence of hysteresis of the I_{ds}−V_{gs} characteristics is alleviated. Note that this operation example can be used for a variable refresh rate (VRR) or the like. The timing chart shows potential fluctuations of the wiring EML, the wiring GLD, the wiring GIa, the wiring GIb, the wiring GLC, the wiring GLW, and the wiring GLB during the period from Time T20 to Time T31 and in the vicinity of the period.

In this operation example, for fixed potentials supplied from the wiring VEA, the wiring VEI, the wiring VER, and the wiring VEN, the description of the timing chart in FIG. 2A is referred to.

The operation shown in the timing chart in FIG. 8 is performed after the operation shown in the timing chart of FIG. 2A. That is, in the pixel circuit PX, the threshold voltage Vₜₕ of the transistor M1 is assumed to have been corrected during the operation in the timing chart of FIG. 2A

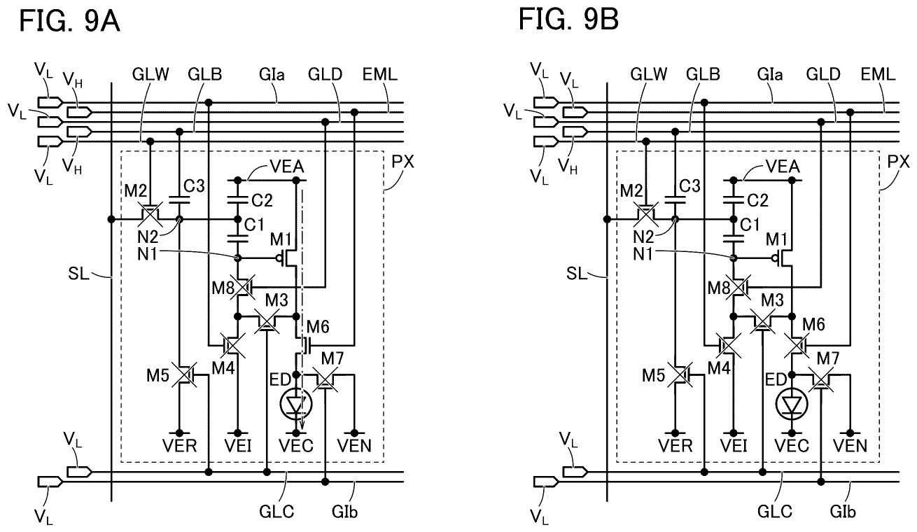

FIGS. 9A and 9B, FIGS. 10A and 10B, and FIGS. 11A and 11B show specific circuit operations in Time T20 to Time T31 described in the timing chart in FIG. 8. Transistors marked with crosses indicate that the transistors are in an off state at that time.

### [Time T20]

At Time T20, a high-level potential is supplied to each of the wiring EML and the wiring GLB, and a low-level potential is supplied to each of the wiring GLD, the wiring GIa, the wiring GIb, the wiring GLC, and the wiring GLW, as in Time TO in FIGS. 2A and 2B. Accordingly, the transistor M6 is turned on, and the transistors M2 to M5, M7, and M8 are turned off. A high-level potential is supplied to the second terminal of the capacitor C3 (see FIG. 9A).

At Time T20, a potential corresponding to an image signal is written to the node N1 and the node N2 in advance. At Time T20, when the potential of the second terminal of the capacitor C3 is set at a high level, the potential of the node N2 (the first terminal of the capacitor C3) is increased by capacitive coupling, and the potential of the node N1 (the first terminal of the capacitor C1) is also increased.

As described above, since the transistor M6 is in an on state at Time T20, the source-drain current of the transistor M1, the amount of which corresponds to the potential of the node N1, flows from the wiring VEA to the wiring VEC through the transistor M6 and the light-emitting device ED. Note that a dashed-dotted arrow in FIG. 9A denotes the source-drain current. Accordingly, the current, the amount of which corresponds to the image signal, flows between the anode and the cathode of the light-emitting device ED, so that the light-emitting device ED emits light with luminance corresponding to the image signal. In particular, in the pixel circuit PX, a variation in luminance of light emitted from the light-emitting device ED is suppressed because the threshold voltage Vₜₕ of the transistor M1 has been corrected.

### [Time T21]

At Time T21, a low-level potential is supplied to the wiring EML. Accordingly, the transistor M6 is turned off, and the source-drain current of the transistor M1 does not flow between the anode and the cathode of the light-emitting device ED. Thus, at Time T21, light emission from the light-emitting device ED is stopped (see FIG. 9B).

### [Time T22]

The potentials supplied to the wirings at Time T22 do not change from the potentials supplied to the respective wirings at Time T21. Note that in the timing charts in FIGS. 2A and 2B, a high-level potential is supplied to the wiring GLD at Time T2, which is different from the timing chart in FIG. 8.

### [Time T23]

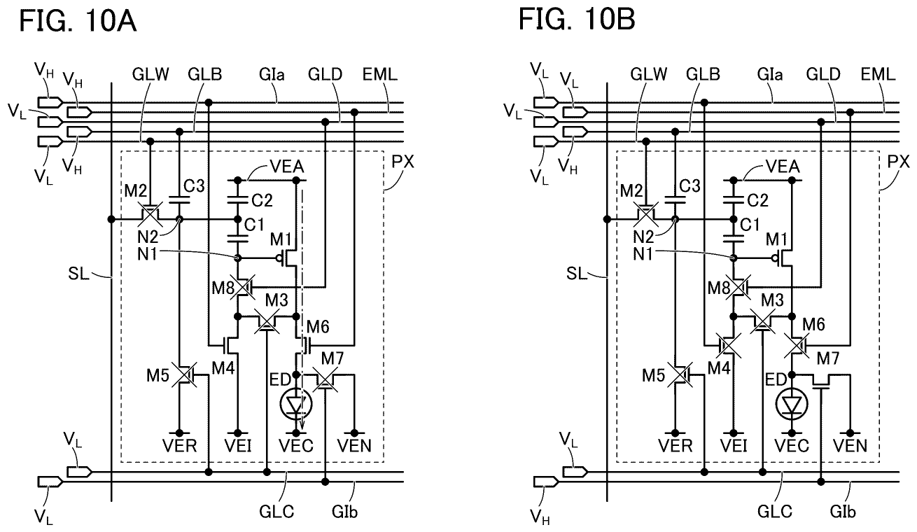

At Time T23, a high-level potential is supplied to the wiring GIa. Accordingly, the transistor M4 is turned on, so that the second terminal of the transistor M3 and the second terminal of the transistor M8 have electrical continuity with the wiring VEI (see FIG. 10A). Thus, the potentials of the second terminal of the transistor M3 and the second terminal of the transistor M8 become Vᵢₙ that is a fixed potential supplied by the wiring VEI.

Note that the wiring GIa is supplied with a low-level potential at Time T24 described later. Thus, the transistor M4 is turned off by Time T24, so that the second terminal of the transistor M3 and the second terminal of the transistor M8 have no electrical continuity with the wiring VEI. Note that the timing at which a low-level potential is supplied to the wiring GIa may be the same as that at which it is Time T24 as shown in FIG. 8.

### [Time T24]

At Time T24, a high-level potential is supplied to the wiring GIb. Accordingly, the transistor M7 is turned on (see FIG. 10B).

When the transistor M7 is turned on, electrical continuity is established between the anode of the light-emitting device ED and the wiring VEN, and the potential of the anode of the light-emitting device ED becomes Vₐᵢ that is a fixed potential supplied from the wiring VEN. Accordingly, a potential applied to the anode of the light-emitting device ED is reset.

At Time T24, the wiring GLC is continuously supplied with a low-level potential, and the transistor M3 and the transistor M5 remain in an off state. Note that in the timing charts in FIGS. 2A and 2B, a high-level potential is supplied to the wiring GLC at Time T4, which is different from the timing chart in FIG. 8.

### [Time T25]

At Time T25, a low-level potential is supplied to the wiring GIb. Accordingly, the transistor M7 is turned off. Consequently, the voltages supplied from the wirings to the pixel circuit PX at Time T25 are equivalent to those at Time T21 and Time T22 (see FIG. 9B).

### [Time T26 to Time T28]

At Time T26 to Time T28, the potentials supplied to the wirings do not change from those at Time T25. Note that in the timing chart in FIGS. 2A and 2B, a high-level potential is supplied to the wiring GLW during the period from Time T6 to Time T7, which is different from the timing chart in FIG. 8. In addition, in the timing chart in FIGS. 2A and 2B, potential transition from the high level from the low level occurs in the wiring GLD at Time T8, which is different from the timing chart in FIG. 8.

### [Time T29]

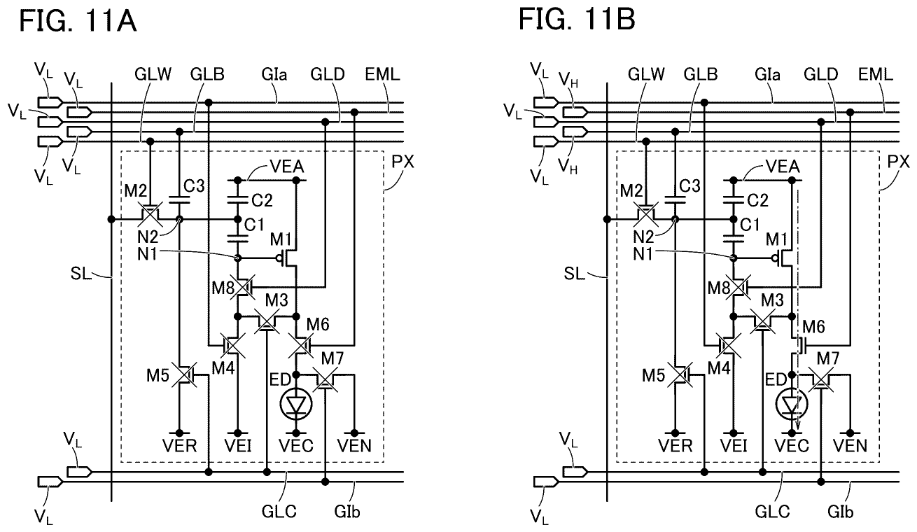

At Time T29, the potential of the wiring GLB decreases from a high-level potential to a low-level potential (see FIG. 11A). Since the node N2 is in a floating state, a decrease in the potential of the wiring GLB is followed by a decrease in the potential of the node N2 due to capacitive coupling by the capacitor C3. Similarly, the decrease in the potential of the node N2 is followed by a decrease in the potential of the node N1 due to capacitive coupling by the capacitor C1. In other words, the operation similar to that at Time T9 in the timing charts in FIGS. 2A and 2B is performed. Thus, the potential of the gate of the transistor M1 decreases from Vₐₙ+Vₜₕ+V_{dt}−V_{rf} to Vₜₕ+V_{dt}−V_{rf}.

A decrease in the gate potential of the transistor M1 at Time T29 enables the influence of the hysteresis of the I_{ds}−V_{gs} characteristics of the transistor M1 to be avoided. Accordingly, it is possible to prevent the fluctuation of the source-drain current amount of the transistor M1 due to by the influence of the hysteresis.

### [Time T30]

At Time T30, the potential of the wiring GLB decreased at Time T29 increases up to a high-level potential. The voltages supplied from the wirings to the pixel circuit PX at Time T30 are equivalent to those at Time T28. Thus, the potential of the node N1 also returns from Vₜₕ+V_{dt}−V_{rf} to Vₐₙ+Vₜₕ+V_{dt}−V_{rf}.

### [Time T31]

At Time T31, a high-level potential is supplied to the wiring EML. Accordingly, the transistor M6 is turned on, and the source-drain current of the transistor M1, the amount of which corresponds to the image signal (V_{dt} as the potential) retained before Time T20, flows from the wiring VEA to the wiring VEC through the transistor M6 and the light-emitting device ED (see FIG. 11B). As a result, the amount of current corresponding to the image signal flows between the anode and the cathode of the light-emitting device ED, so that the light-emitting device ED emits light with luminance corresponding to the image signal.

By the operation from Time T20 to Time T31 described above, the influence of hysteresis in the transistor M1 can be alleviated in a state of not rewriting the image signal but holding the potential corresponding to the image signal in the previous frame.

### Structure Example of Display Apparatus

Next, a structure example of a display apparatus including a cell array in which a plurality of pixel circuits (each corresponding to the pixel circuit PX in FIG. 1A) are arranged is described.

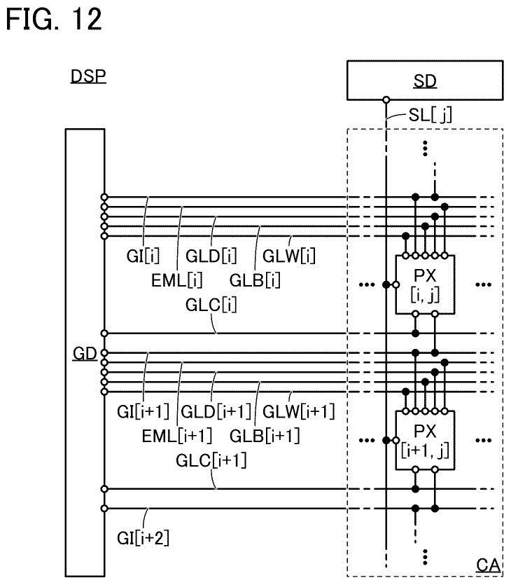

FIG. 12 is a block diagram illustrating a structure example of a display apparatus DSP including a cell array CA in which a plurality of pixel circuits (each corresponding to the pixel circuit PX in FIG. 1A) are arranged. The display apparatus DSP includes, for example, a driver circuit SD and a driver circuit GD in addition to the cell array CA.

The pixel circuits PX are arranged in a matrix in the cell array CA; for example, the pixel circuits PX can be arranged in a matrix of M rows and N columns (each of M and Nis an integer greater than or equal to 1). Note that in FIG. 12, the pixel circuit PX[i,j] (i is an integer greater than or equal to 1 and less than or equal to M−1, and j is an integer greater than or equal to 1 and less than or equal to N) and the pixel circuit PX[i+1,j] are selectively illustrated.

In the cell array CA, wirings GI[1] to GI[M+1], wirings EML[1] to EML[M], wirings GLD[1] to GLD[M], wirings GLB[1] to GLB[M], wirings GLW[1] to GLW[M], and wirings GLC[1] to GLC[M] extend in the row direction. Note that FIG. 12 selectively illustrates the wirings GI[i], GI[i+1], and GI[i+2], the wirings EML[i] and EML[i+1], the wirings GLD[i] and GLD[i+1], the wirings GLB[i] and GLB[i+1], the wirings GLW[i] and GLW[i+1], and the wirings GLC[i] and GLC[i+1].

In the cell array CA, wirings SL[1] to SL[N] extend in the column direction. Note that the wiring SL[j] is selectively illustrated in FIG. 12.

The pixel circuit PX[i,j] is connected to the wiring GI[i], the wiring GI[i+1], the wiring EML[i], the wiring GLD[i], the wiring GLB[i], the wiring GLW[i], the wiring GLC[i], and the wiring SL[j]. Similarly, the pixel circuit PX[i+1,j] is connected to the wiring GI[i+1], the wiring GI[i+2], the wiring EML[i+1], the wiring GLD[i+1], the wiring GLB[i+1], the wiring GLW[i+1], the wiring GLC[i+1], and the wiring SL[j].

In particular, in the pixel circuit PX[i,j], the wiring GI[i] corresponds to the wiring GIa shown in FIG. 1A, the wiring EML[i] corresponds to the wiring EML shown in FIG. 1A, the wiring GLD[i] corresponds to the wiring GLD shown in FIG. 1A, the wiring GLB[i] corresponds to the wiring GLB shown in FIG. 1A, the wiring GLW[i] corresponds to the wiring GLW shown in FIG. 1A, the wiring GLC[i] corresponds to the wiring GLC shown in FIG. 1A, and the wiring GI[i+1] corresponds to the wiring GIb shown in FIG. 1A.

In the pixel circuit PX[i+1,j], the wiring GI[i+1] corresponds to the wiring GIa shown in FIG. 1A, the wiring EML[i+1] corresponds to the wiring EML shown in FIG. 1A, the wiring GLD[i+1] corresponds to the wiring GLD shown in FIG. 1A, the wiring GLB[i+1] corresponds to the wiring GLB shown in FIG. 1A, the wiring GLW[i+1] corresponds to the wiring GLW shown in FIG. 1A, the wiring GLC[i+1] corresponds to the wiring GLC shown in FIG. 1A, and the wiring GI[i+2] corresponds to the wiring GIb shown in FIG. 1A.

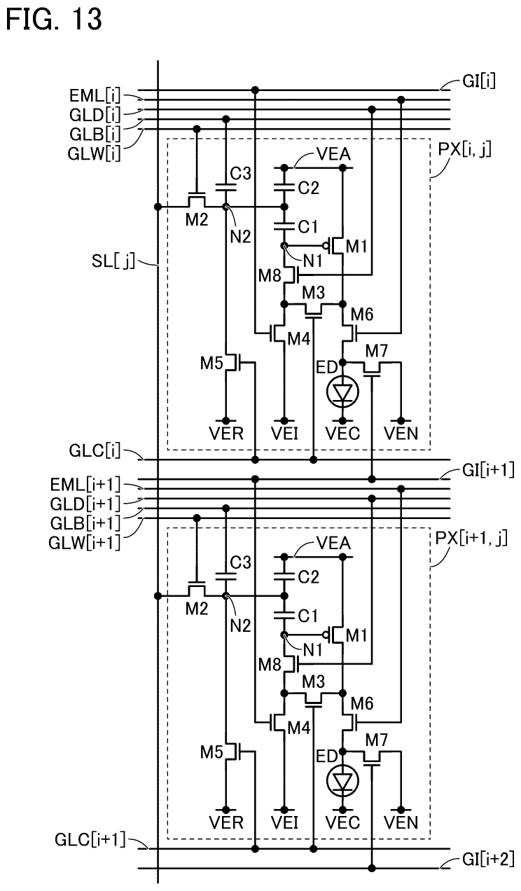

The above description of the correspondence relationship can also be applied to the pixel circuit PX in FIG. 1B. FIG. 13 shows a circuit configuration of the pixel circuit PX[i,j] and the pixel circuit PX[i+1] in the case where the above correspondence relation is applied to the pixel circuit PX in FIG. 1B.

As shown in FIG. 13, the wiring GI[i+1] connected to the pixel circuit PX[i,j] corresponds to the wiring GIb connected to the pixel circuit PX in FIG. 1B, and the wiring GI[i+1] connected to the pixel circuit PX[i+1,j] corresponds to the wiring GIa connected to the pixel circuit PX in FIG. 1B. In other words, the pixel circuit PX in the cell array CA in FIG. 12 has such a wiring connection structure that the wiring GIa of the pixel circuit PX in FIG. 1B is shared with another pixel circuit PX adjacent to the above pixel circuit PX as the wiring GIb.

In the cell array CA in FIG. 12, the wiring GI[i+1] is shared by the pixel circuit PX[i,j] and the pixel circuit PX[i+1,j], whereby the number of wirings extending in the cell array CA can be reduced; accordingly, the pixel density of the cell array CA can be increased.

An operation example of a timing chart shown in FIG. 14 can be applied to operations of the plurality of pixel circuits PX in the cell array CA in FIG. 12. The timing chart in FIG. 14 is a variation of the timing chart in FIG. 2A, and for part of the timing chart in FIG. 14, the description of the timing chart in FIG. 2A can be referred to.

The timing chart in FIG. 14 shows potential fluctuations of the wirings EML[1] to EML[M], the wirings GLD[1] to GLD[M], the wirings GI[i] and GI[i+1], the wirings GLC[i] and GLC[i+1], the wirings GLW[i] and GLW[i+1], and the wirings GLB[1] to GLB[M] during the period from Time T0 to Time T11 and in the vicinity of the period. The timing chart in FIG. 14 also shows an image signal supplied to the wiring SL[j].

Like the wiring EML in FIG. 2A, the wirings EML[1] to EML[M] shown in FIG. 14 are supplied with a high-level potential during the period from Time T0 to Time T1 and after Time T11, and are supplied with a low-level potential during the period from Time T1 to Time T11. Like the wiring GLD in FIG. 2A, the wirings GLD[1] to GLD[M] shown in FIG. 14 are supplied with a low-level potential during the period from Time T1 to Time T2 and after Time T8, and are supplied with a high-level potential during the period from Time T2 to Time T8. Like the wiring GLB in FIG. 2A, the wirings GLB[1] to GLB[M] shown in FIG. 14 are supplied with a low-level potential before Time TO and during the period from Time 9 to Time T10, and are supplied with a high-level potential during the period from Time T0 to Time T9 and after Time T10.

During the period from Time T3 to Time T5, a high-level potential having a pulse width is sequentially supplied to the wirings GI[1] to GI[M]. At the timing when a high-level potential is supplied to the wiring GLC[i], the wiring GI[i+1] is also supplied with a high-level potential having a pulse width.

During the period from Time T6 to Time T7, a high-level potential having a pulse width is sequentially supplied to each of the wirings GLW[1] to GLW[M]. At the timing when a high-level potential is supplied to the wiring GLW[i], a potential V_{dt}[i,j] is supplied as an image signal to the wiring SL[j], and at the timing when a high-level potential is supplied to the wiring GLW[i+1], a potential V_{dt}[i+1,j] is supplied as an image signal to the wiring SL[j]. Accordingly, the potential V_{dt}[i,j] can be written to the pixel circuit PX[i,j] at the timing when a high-level potential is supplied to the wiring GLW[i], and the potential V_{dt}[i+1,j] can be written to the pixel circuit PX[i+1,j] at the timing when a high-level potential is supplied to the wiring GLW[i+1].

The plurality of pixel circuits PX in the cell array CA can be operated in accordance with the timing chart in FIG. 14 as described above. Thus, in each of the pixel circuits PX in the cell array CA, the threshold voltage of the transistor M1 can be corrected and the influence of hysteresis of the I_{ds}−V_{gs} characteristics can be alleviated.

Furthermore, the timing chart in FIG. 14 shows the operation example where the wirings GI[1] to GI[M] and the wirings GLC[1] to GLC[M] are each supplied one time with a potential having a pulse width during the period from Time T3 to Time T5, as in the operation in the timing chart shown in FIG. 2A; however, the operation method of the semiconductor device of one embodiment of the present invention is not limited thereto. For example, in the operation method of the semiconductor device of one embodiment of the present invention, as in FIG. 2B, a potential having a pulse width may be supplied a plurality of times to the wirings during the period from Time T3 to Time T5 (see FIG. 15).

### Variation Example of Pixel Circuit

The pixel circuit relating to a display apparatus of one embodiment of the present invention is not limited to the structure of the pixel circuit PX shown in FIG. 1B. The pixel circuit relating to the display apparatus of one embodiment of the present invention can employ a structure modified from the pixel circuit PX illustrated in FIG. 1B.

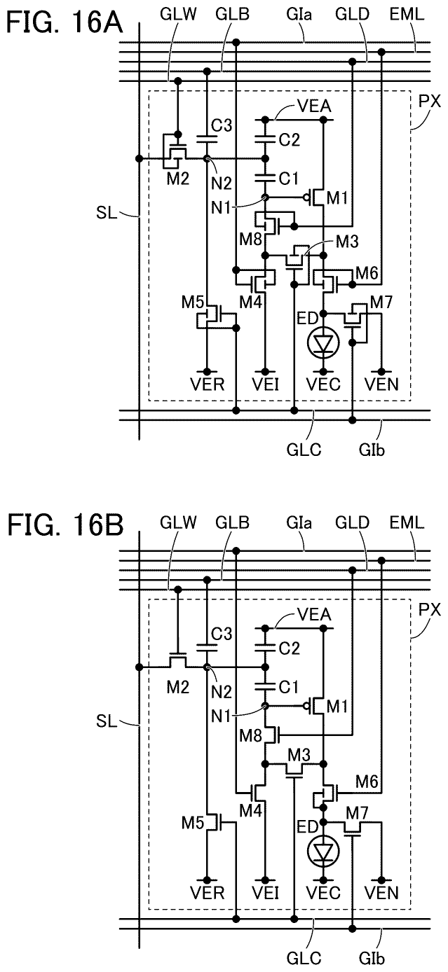

The pixel circuit PX shown in FIG. 16A is a variation of the pixel circuit PX in FIGS. 1B and 1s different from the pixel circuit PX in FIG. 1B in that the transistors M2 to M8 are each provided with a back gate. Since each of the transistors M2 to M8 functions as a switching transistor, each of the transistors M2 to M8 preferably have a structure where the gate and the back gate are connected as illustrated in FIG. 16A. With this structure, each of the transistors has a low threshold voltage while being in an on state and thus enables a high on-state current; each of the transistors has a high threshold voltage while being in an off state and thus enables a low off-state current. Consequently, the driving speed of the pixel circuit PX can be increased, and an increase in power consumption, a malfunction, or the like due to leakage current of these transistors can be prevented.

The pixel circuit PX shown in FIG. 16B is a variation of the pixel circuit PX in FIG. 1B, in which the transistor M6 is provided with a back gate that is connected to the second terminal of the transistor M6. When the back gate of the transistor M6 is connected to the second terminal of the transistor M6, the electrical characteristics of the transistor M6 can be stable. Specifically, when the potential of the back gate of the transistor M6 is set to the potential of the second terminal of the transistor M6 (e.g., the source potential), a shift in the threshold voltage can be inhibited. In particular, since the transistor M6 and the light-emitting device ED are connected in series, it is preferable that the transistor M6 have stable electrical characteristics. Even when the back gate of the transistor M6 is connected to the wiring VEC or the wiring VEN instead of the second terminal of the transistor M6 (not shown), the electrical characteristics of the transistor M6 can be stable.

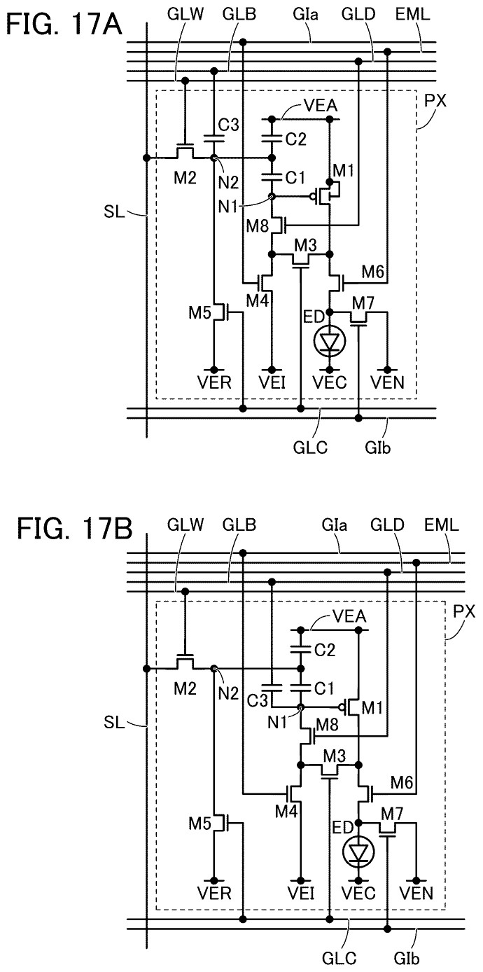

The pixel circuit PX shown in FIG. 17A is a variation of the pixel circuit PX in FIG. 1B, in which the transistor M1 is provided with a back gate that is connected to the wiring VEA or the second terminal of the transistor M1. Accordingly, the electrical characteristics of the transistor M1 can be stable, so that an increase in saturation characteristics, a reduction in shift of the threshold voltage, and the like can be achieved.

The pixel circuit PX shown in FIG. 17B is a variation of the pixel circuit PX in FIG. 1B, and has a structure in which the first terminal of the capacitor C3 is connected not to the first terminal of the transistor M2, the second terminal of the capacitor C1, the first terminal of the capacitor C2, and the first terminal of the transistor M5 but to the gate of the transistor M1, the first terminal of the capacitor C1, and the first terminal of the transistor M8. Also in the pixel circuit PX in FIG. 17B, the potential supplied from the wiring GLB is made lower in the operation at Time T9 shown in FIGS. 2A and 2B or the operation at Time T29 shown in FIG. 8, which enables application of the on-bias voltage to the gate of the transistor M1 with capacitive coupling of the capacitor C3; as a result, the gate voltage of the transistor M1 can be increased (the potential of the gate of the transistor M1 can be significantly reduced). Consequently, the influence of hysteresis of the I_{ds}−V_{gs} characteristics of the transistor M1 can be alleviated.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 2

In this embodiment, a cross-sectional structure example of the display apparatus described in the above embodiment will be described.

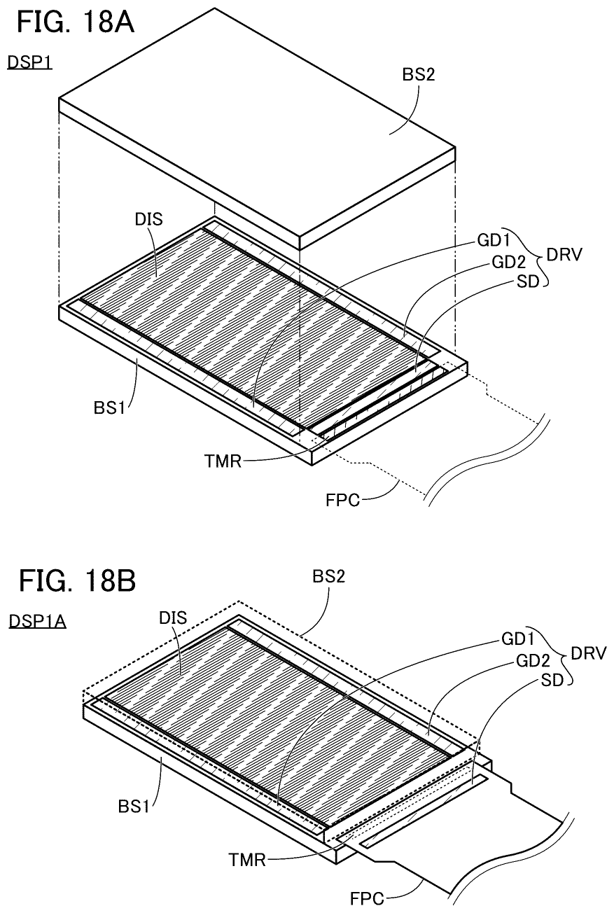

FIG. 18A is a schematic perspective view illustrating a display apparatus of one embodiment of the present invention. A display apparatus DSP1 includes a display region DIS, a driver circuit region DRV, and a terminal region TMR, for example. The display apparatus DSP1 includes a substrate BS1 and a substrate BS2, and the display region DIS, the driver circuit region DRV, and the terminal region TMR are located over the substrate BS1. To protect the display region DIS, the driver circuit region DRV, and the terminal region TMR from atmospheric components or to prevent a physical impact on the display region DIS, the driver circuit region DRV, and the terminal region TMR, the display region DIS, the driver circuit region DRV, and the terminal region TMR are sandwiched between the substrate BS1 and the substrate BS2. Note that the display region DIS can include the cell array CA in FIG. 12 described in Embodiment 1, for example. The driver circuit SD described in Embodiment 1 can be provided outside the display apparatus DSP1 in FIG. 18A.

The driver circuit region DRV includes, for example, a driver circuit GD1, a driver circuit GD2, and the driver circuit SD. The driver circuit GD1 and the driver circuit GD2 correspond to the driver circuit GD of the display apparatus DSP in FIG. 12 described in Embodiment 1, and the driver circuit SD corresponds to the driver circuit SD of the display apparatus DSP in FIG. 12 described in Embodiment 1.

As illustrated in FIG. 18A, a flexible printed circuit FPC can be connected to the terminal region TMR of the display apparatus DSP1. The flexible printed circuit FPC is denoted by a dotted line in FIG. 18A. In particular, the display apparatus DSP1 where the flexible printed circuit FPC is mounted is referred to as a display module in some cases.

As each of the substrates BS1 and BS2, a semiconductor substrate (e.g., a single crystal substrate formed of silicon or germanium) can be used, for example. Besides such a semiconductor substrate, any of the following can be used as the substrates BS1 and BS2: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. Examples of the glass substrate include a barium borosilicate glass substrate, an aluminoborosilicate glass substrate, and a soda lime glass substrate. Examples of materials for the flexible substrate, the attachment film, or the base film include plastic typified by polyethylene terephthalate (PET), polyethylene naphthalate (PEN), polyethersulfone (PES), and polytetrafluoroethylene (PTFE). Another example is a synthetic resin such as an acrylic resin. Other examples are polypropylene, polyester, polyvinyl fluoride, and polyvinyl chloride. Other examples are polyamide, polyimide, aramid, an epoxy resin, an inorganic vapor-deposited film, and paper. Note that in the case where the manufacturing process of the display apparatus DSP1 involves heat treatment, a highly heat-resistant material is preferably used for the substrates BS1 and BS2.

For example, in the case where a semiconductor substrate including silicon as a material is used as the substrate BS1, transistors included in the display region DIS and the driver circuit region DRV can be Si transistors and can be formed over the substrate BS1.

For example, in the case where a glass substrate is used as the substrate BS1, transistors included in the display region DIS and the driver circuit region DRV can be OS transistors or LTPS transistors and can be formed over the substrate BS1.

The substrate BS2 preferably has a high light-transmitting property to transmit light emitted from the display region DIS. When the substrate BS2 is a light-transmitting flexible substrate, attachment film, or base material film, the total thickness of the display apparatus DSP1 can be reduced, so that the size of an electronic device including the display apparatus can be reduced.

One or more selected from the driver circuits GD1, GD2, and SD included in the driver circuit region DRV may be mounted as an integrated circuit (IC) chip on the substrate BS1 by a chip on glass (COG) technique. A display apparatus where the IC chip is mounted by a COG technique is also referred to as a display module in some cases.

The driver circuits GD1 and GD2 each serve as a driver circuit for displaying an image on the display region DIS, for example. Specifically, for example, the driver circuits GD1 and GD2 each serve as a gate driver circuit for the display region DIS. For example, the driver circuit SD serves as a source driver circuit for the display region DIS.

The terminal region TMR includes a terminal for supplying an image signal and a power supply potential into the display apparatus DSP1 from the outside of the display apparatus DSP1. A flexible printed circuit FPC may be connected to the terminal region TMR. An IC chip may be mounted on the flexible printed circuit FPC by a chip on film (COF) technique. The IC chip, for example, may include a driver circuit for displaying an image on the display region DIS. A display apparatus DSP1A illustrated in FIG. 18B has a structure in which an IC chip including the driver circuit SD is mounted on the flexible printed circuit FPC by a COF technique. As illustrated in FIG. 18B, the display apparatus DSP1A provided with a connector such as a flexible printed circuit board on which an IC chip is mounted is also referred to as a display module in some cases.

The display region DIS includes, for example, a plurality of pixels. The plurality of pixels may be arranged in a matrix in the display region DIS.

For the plurality of pixels, a pixel circuit including one or more selected from a liquid crystal display device, a light-emitting device containing an organic EL material, a light-emitting device containing an inorganic EL material, and a light-emitting device including a light-emitting diode (e.g., a micro LED) can be employed.

Each of the plurality of pixels can express one color or a plurality of colors. In particular, the plurality of colors can be, for example, three colors of red, green, and blue. Alternatively, the plurality of colors may be two or more colors selected from, for example, red, green, blue, cyan, magenta, yellow, and white. Note that in the case where each of pixels expressing different colors is called a subpixel and white is expressed by a plurality of subpixels expressing different colors, the plurality of subpixels are collectively called a pixel in some cases. In this specification and the like, a subpixel is referred to as a pixel for convenience in some cases. For example, the pixel circuit PX illustrated in FIG. 1B can also be referred to as a subpixel.

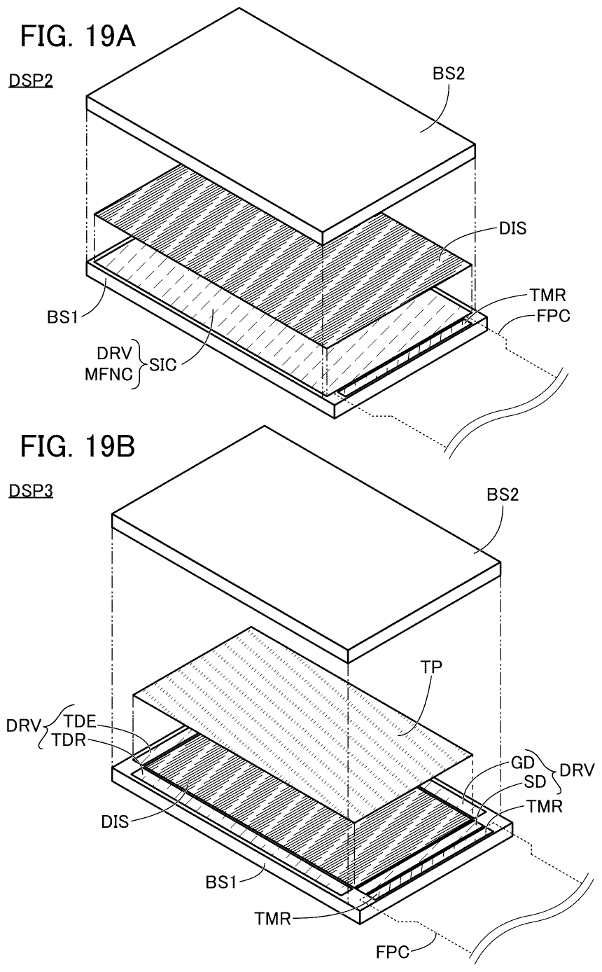

Note that the display apparatus of one embodiment of the present invention is not limited to the structure of the display apparatus DSP1 in FIG. 18A. For example, the display apparatus of one embodiment of the present invention may have a structure of a display apparatus DSP2 illustrated in FIG. 19A.

The display apparatus DSP2 in FIG. 19A includes the display region DIS, a circuit region SIC, and the terminal region TMR, for example. The display apparatus DSP2 further includes the substrates BS1 and BS2, like the display apparatus DSP1. The display apparatus DSP2 is different from the display apparatus DSP1 in that the circuit region SIC and the terminal region TMR are provided over the substrate BS1 and the display region DIS is provided over the circuit region SIC.

The circuit region SIC includes, for example, the driver circuit region DRV described above. The circuit region SIC may include any of a variety of functional circuits other than the driver circuit region DRV. In this embodiment, the functional circuit is included in a functional circuit region MFNC. For example, the driver circuit SD described in Embodiment 1 can be included in the functional circuit region MFNC.

The functional circuit region MFNC may include a graphics processing unit (GPU), for example. In the case where the display apparatus DSP2 includes a touch panel, the functional circuit region MFNC may include a sensor controller for controlling a touch sensor included in the touch panel.

In the case where a light-emitting device containing an organic EL material is used as the display element of the display apparatus DSP2, an EL correction circuit may be included in the functional circuit region MFNC. The EL correction circuit has a function of appropriately adjusting the amount of current input to the light-emitting device containing an organic EL material. Since the emission luminance of the light-emitting device containing an organic EL material is proportional to the current, when the characteristics of a driving transistor electrically connected to the light-emitting device are not favorable, the luminance of light emitted from the light-emitting device might be lower than a desired luminance. For example, the EL correction circuit monitors the amount of current flowing through the light-emitting device and increases the amount of current when the amount of current is smaller than a desired amount, whereby the luminance of light emitted from the light-emitting device can be increased. By contrast, when the amount of current is larger than a desired amount, the amount of current flowing through the light-emitting device can be adjusted to be small.

In the case where a liquid crystal element is used as the display element of the display apparatus DSP2, a gamma correction circuit may be included in the functional circuit region MFNC. In the case where an μLED is used as the display element, a correction circuit capable of controlling pulse width modulation (PWM) may be included in the functional circuit region MFNC.

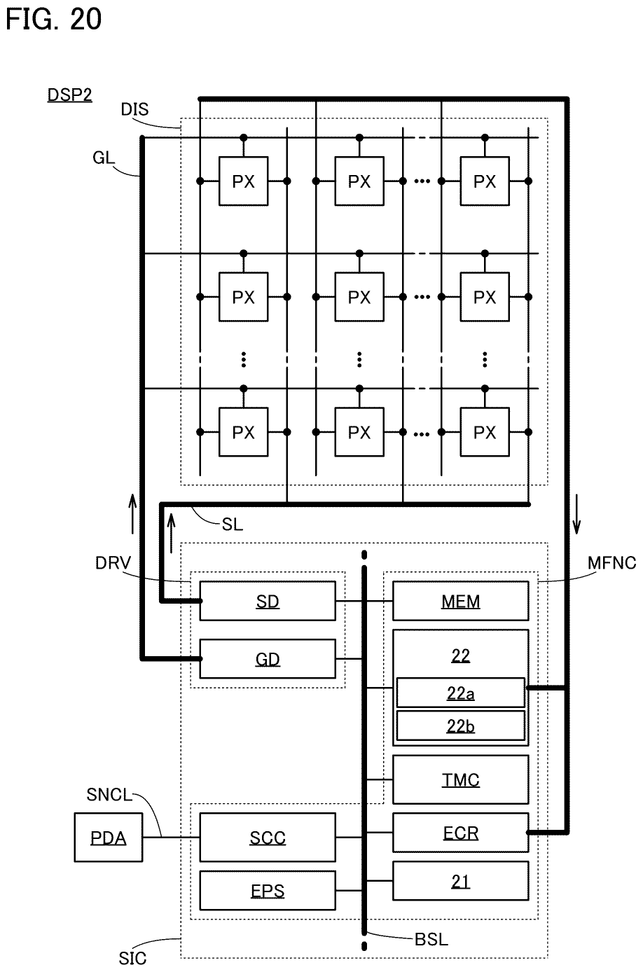

FIG. 20 is a block diagram illustrating a configuration example of the display apparatus DSP2 illustrated in FIG. 19A. The display apparatus DSP2 illustrated in FIG. 20 includes the display region DIS and the circuit region SIC, for example. A sensor PDA illustrated in FIG. 20 may be placed inside or outside the display apparatus DSP2.

The display apparatus DSP1 in FIG. 18A may be electrically connected to the functional circuit region MFNC located outside the display apparatus DSP1 through the terminal region TMR and the flexible printed circuit FPC. The structure of the display apparatus DSP1 in this case can be regarded as similar to that of the display apparatus DSP2 illustrated in FIG. 20.

In FIG. 20, the thick solid lines denote a plurality of wirings or bus wirings.

In FIG. 20, the display region DIS includes a plurality of the pixel circuits PX arranged in a matrix, for example. The display region DIS can be regarded as the cell array CA in FIG. 12 described in Embodiment 1.

In FIG. 20, the circuit region SIC includes the driver circuit region DRV and the functional circuit region MFNC, as described above.

The driver circuit region DRV functions as a peripheral circuit for driving the display region DIS, for example. Specifically, the driver circuit region DRV includes a driver circuit SD and a driver circuit GD, for example. Note that the driver circuit SD corresponds to the driver circuit SD in FIG. 12 described in Embodiment 1, and the driver circuit GD corresponds to the driver circuit GD in FIG. 12 described in Embodiment 1, for example.

The functional circuit region MFNC can be provided with, for example, a circuit such as a memory device storing image data to be displayed on the display region DIS, a decoder for decoding encoded image data, a GPU for processing image data, a power supply circuit, a correction circuit, or a CPU. In FIG. 20, the functional circuit region MFNC includes a memory device MEM, a GPU 22, an EL correction circuit ECR, a timing controller TMC, a CPU 21, a sensor controller SCC, and a power supply circuit EPS, for example.

In the display apparatus DSP2 shown in FIG. 20, for example, a bus wiring BSL is electrically connected to each of the circuits included in the driver circuit region DRV and each of the circuits included in the functional circuit region MFNC.

The driver circuit SD has a function of transmitting image data to the pixel circuit PX included in the display region DIS, for example. Thus, the driver circuit SD is electrically connected to the pixel circuit PX through the wiring SL.

Note that the driver circuit SD may include a digital-to-analog converter circuit. The digital-to-analog converter circuit has a function of, for example, converting image data that has been digitally processed by the GPU or correction circuit described later, into analog data. The image data converted into analog data is transmitted to the display region DIS through the driver circuit SD. Note that the digital-to-analog converter circuit may be placed outside the driver circuit SD.

The driver circuit GD has a function of selecting the pixel circuit PX to which image data is to be transmitted in the display region DIS, for example. Thus, the driver circuit GD is electrically connected to the pixel circuit PX through a wiring GL.

Note that the driver circuit SD may include a level shifter. The level shifter has a function of converting a selection signal for the pixel circuit of the display region DIS into a signal having an appropriate level, for example. The level shifter may have a function of converting the signals to be input to the driver circuit SD, the digital-to-analog converter circuit, the driver circuit GD, and the like into signals having appropriate levels, for example.

The memory device MEM has a function of storing image data to be displayed on the display region DIS, for example. Note that the memory device MEM can be configured to store the image data as digital data or analog data.

In the case where the memory device MEM stores image data, the memory device MEM is preferably a nonvolatile memory. In this case, the memory device MEM can be a NAND memory or the like.

In the case where the memory device MEM stores temporary data generated in the GPU 22, the EL correction circuit ECR, the CPU 21, or the like, the memory device MEM is preferably a volatile memory. In that case, a static random access memory (SRAM), a dynamic random access memory (DRAM), or the like can be used as the memory device MEM.

The GPU 22 has a function of performing processing for plotting the image data read from the memory device MEM on the display region DIS, for example. Specifically, the GPU 22 is configured to perform pipeline processing in parallel and can thus perform high-speed processing of the image data to be displayed on the display region DIS. The GPU 22 can also function as a decoder for decoding an encoded image.

The functional circuit region MFNC may include a plurality of circuits that can increase the display quality of the display region DIS. As such circuits, for example, correction circuits (dimming or toning circuits) that detect and correct color irregularity of an image displayed on the display region DIS to optimize the image may be provided. In the case where the pixel in the display region DIS includes a light-emitting device containing an organic EL material, the functional circuit region MFNC may be provided with an EL correction circuit. Note that because the description in this embodiment is made on the assumption that the pixel circuit PX in the display region DIS includes the light-emitting device containing an organic EL material, the functional circuit region MFNC is provided with the EL correction circuit ECR as an EL correction circuit, for example.

The above-described image correction may be performed using artificial intelligence in the following manner, for example. A current flowing in the display device included in the pixel (or a voltage applied to the display device) is monitored and acquired, an image displayed on the display portion DIS is acquired with an image sensor or the like, the current (or voltage) and the image are used as input data in an arithmetic operation of the artificial intelligence (e.g., an artificial neural network), and the output result is used to determine whether the image should be corrected.

Such an arithmetic operation of artificial intelligence can be applied to not only image correction but also upconversion of image data. In this case, upconversion of low-definition image data in accordance with the image definition of the display region DIS allows a high-display-quality image to be displayed on the display region DIS. The arithmetic operation of artificial intelligence can also be applied to downconversion of image data.

Note that the above-described arithmetic operation of the artificial intelligence can be performed using the GPU 22 included in the functional circuit region MFNC. That is, the GPU 22 can be used to perform arithmetic operations for various kinds of correction (e.g., color irregularity correction and upconversion processing). The GPU 22 may include a circuit 22a that corrects color irregularity and a circuit 22b that performs upconversion processing.

Note that in this specification and the like, a GPU performing an arithmetic operation of the artificial intelligence is referred to as an AI accelerator. That is, the GPU included in the functional circuit region MFNC may be replaced with an AI accelerator in the description in this specification and the like.

The timing controller TMC has a function of changing the frame rate at which an image is displayed on the display region DIS. For example, the display apparatus DSP2 can be driven at a frame rate reduced by the timing controller TMC in the case where the display region DIS displays a still image; for another example, the display apparatus DSP2 can be driven at a frame rate increased by the timing controller TMC in the case where the display region DIS displays a moving image. In other words, the display apparatus DSP2 provided with the timing controller TMC can be driven at a frame rate that is changed depending on which of a still image and a moving image is displayed. Specifically, since the frame rate when the display region DIS displays a still image can be lowered, the power consumption of the display apparatus DSP2 can be reduced.

The CPU 21 has a function of, for example, performing general-purpose processing such as execution of an operating system, control of data, and execution of various arithmetic operations and programs. In the display apparatus DSP2, the CPU 21 has a function of, for example, giving an instruction for an operation for writing or reading image data to/from the memory device MEM, an operation for correcting image data, an operation for a later-described sensor, or the like. Furthermore, the CPU 21 may have a function of, for example, transmitting a control signal to at least one of the circuits included in the functional circuit region MFNC, such as the memory device, the GPU, the correction circuit, the timing controller, and a high frequency circuit.

The CPU 21 may include a circuit for temporarily backing up data (hereinafter referred to as a backup circuit). The backup circuit is preferably capable of retaining the data even after supply of a power supply potential is stopped. For example, in the case where the display region DIS displays a still image, the CPU 21 can cease to work until an image different from the currently displayed still image is displayed. Accordingly, dynamic power consumption by the CPU 21 can be reduced in such a manner that the data under processing by the CPU 21 is backed up in the backup circuit and then supply of a power supply potential to the CPU 21 is stopped to stop the CPU 21. In this specification and the like, a CPU including a backup circuit is referred to as a NoffCPU (registered trademark).

The sensor controller SCC has a function of, for example, controlling the sensor PDA. FIG. 20 shows a wiring SNCL as a wiring for electrically connecting the sensor PDA to the sensor controller SCC.

The sensor PDA may be an illuminance sensor, for example. Specifically, the illuminance sensor acquiring the intensity of the external light with which the display region DIS is irradiated makes it possible to change the brightness (luminance) of an image displayed on the display region DIS in accordance with the intensity of the external light. For example, under intense external light, the luminance of an image displayed on the display region DIS can be increased to enhance the viewability of the image. By contrast, under weak external light, the luminance of an image displayed on the display region DIS can be lowered to reduce the power consumption.

Alternatively, the sensor PDA can be an image sensor, for example. For example, an image or the like acquired with the image sensor can be displayed on the display region DIS.

The power supply circuit EPS has a function of, for example, generating voltages to be supplied to the circuits included in the driver circuit region DRV, the circuits included in the functional circuit region MFNC, the pixels included in the display region DIS, and the like. Note that the power supply circuit EPS may have a function of selecting a circuit to which a voltage is to be supplied. For example, the power supply circuit EPS stops supply of a voltage to the circuits included in the driver circuit region DRV (e.g., the driver circuit SD and the digital-analog converter circuit) and the circuits included in the functional circuit region MFNC (e.g., the CPU 21 and the GPU 22) during a period in which the display region DIS displays a still image, whereby the power consumption of the whole display apparatus DSP can be reduced.

The display apparatus of one embodiment of the present invention may be a display apparatus DSP3 illustrated in FIG. 19B, which is obtained by changing the structure of the display apparatus DSP1 in FIG. 18A.

The display apparatus DSP3 is a variation of the display apparatus DSP1 and has a structure in which a sensor region TP is provided in a region overlapping with the display region DIS.

The display apparatus DSP3 includes a driver circuit TDE and a driver circuit TDR, and each of the driver circuit TDE and the driver circuit TDR is provided over the substrate BS1. Each of the driver circuit TDE and the driver circuit TDR is assumed to be included in the driver circuit region DRV as illustrated in FIG. 19B.

The driver circuit TDR has a function of sequentially transmitting pulse signals to a plurality of sensors included in the sensor region TP. The driver circuit TDE has a function of sensing a change in the amount of current flowing from the plurality of sensors included in the sensor region TP.

As described above, the display apparatus DSP3 has a structure in which a touch panel is provided as a user interface.

Although not illustrated, the sensor region TP may also be provided above the display region DIS of the display apparatus DSP2. In that case, the driver circuit TDR and the driver circuit TDE are preferably provided in the circuit region SIC.

### Layout Example Pf Pixel Circuit

Next, an example of a schematic plan view of the above-described pixel circuit PX in FIG. 1B is described.

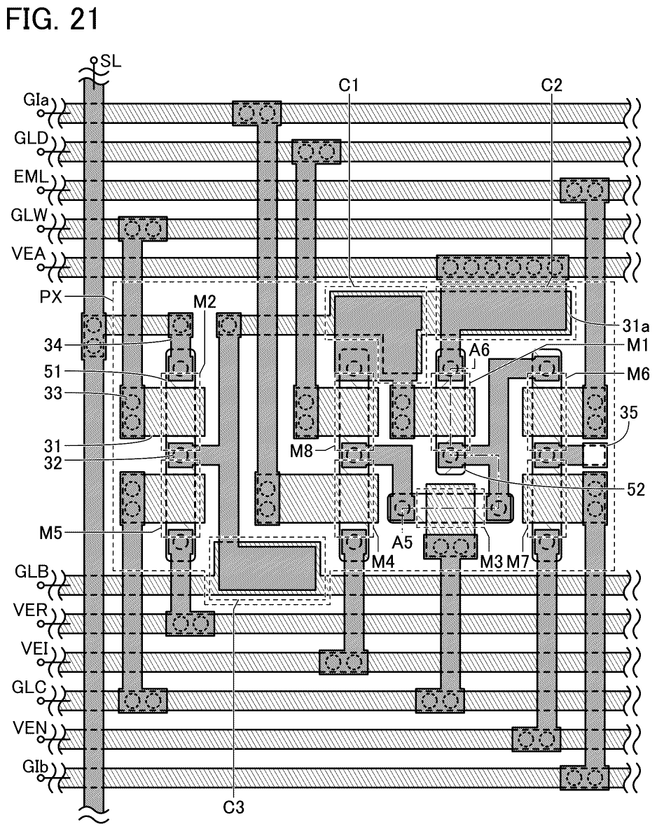

FIG. 21 is a schematic plan view illustrating an example of the pixel circuit PX illustrated in FIG. 1B and can be applied to the pixel circuit included in the display region DIS in FIGS. 18A, 18B, 19A, and 19B described above. In FIG. 21, the pixel circuit PX includes, for example, a conductive layer 31, a conductive layer 32, a conductive layer 33, a conductive layer 34, a conductive layer 35, a semiconductor layer 51, and a semiconductor layer 52. Note that for clarification of the schematic plan view, FIG. 21 does not illustrate an insulating layer included in the pixel circuit PX.

The semiconductor layer 51 and the semiconductor layer 52 are each positioned below the conductive layer 31 and the conductive layer 32, for example. The conductive layer 33 is positioned above the conductive layer 31, for example. The conductive layer 34 is positioned above each of the conductive layers 32 and 33, for example. The conductive layer 35 is positioned above the conductive layer 34, for example. As a feasible formation order, one of the semiconductor layer 51 and the semiconductor layer 52 is formed first, the other of the semiconductor layer 51 and the semiconductor layer 52 is formed second, the conductive layer 31 is formed third, one of the conductive layer 32 and the conductive layer 33 is formed fourth, the other of the conductive layer 32 and the conductive layer 33 is formed fifth, the conductive layer 34 is formed sixth, and the conductive layer 35 is formed seventh.

Part of the semiconductor layer 51 can be, for example, a semiconductor layer included in a channel formation region of a switching transistor included in the pixel circuit PX. For example, in FIG. 21, part of the semiconductor layer 51 can be an n-channel semiconductor layer included in a channel formation region of each of the transistors M2 to M8. Part of the semiconductor layer 52 can be a semiconductor layer included in a channel formation region of a driving transistor included in the pixel circuit PX. For example, in FIG. 21, part of the semiconductor layer 52 can be a p-channel semiconductor layer included in a channel formation region of the transistor M1.

In the pixel circuit PX, part of the conductive layer 31 serves as a gate of each of the transistors M1 to M8, for example. Part of the conductive layer 31 serves as one of a pair of electrodes of each of the capacitors C1, C2, and C3, for example.

Part of the conductive layer 31 can be a wiring extending around the pixel circuit PX. For example, in FIG. 21, part of the conductive layer 31 can be used to form the wiring GIa, the wiring GLD, the wiring EML, the wiring GLW, the wiring VEA, the wiring GLB, the wiring VER, the wiring VEI, the wiring GLC, the wiring VEN, and the wiring GIb extending in the lateral direction of the drawing around the pixel circuit PX.

In the pixel circuit PX, part of the conductive layer 34 serves as a source or a drain of each of the transistors M1 to M8, for example. Part of the conductive layer 34 serves as the other of the pair of electrodes of each of the capacitors C1, C2, and C3.

Part of the conductive layer 34 can be a wiring extending around the pixel circuit PX. For example, in FIG. 21, part of the conductive layer 34 can be used to form the wiring SL extending in the longitudinal direction of the drawing around the pixel circuit PX.

In FIG. 21, the wiring SL extends in the longitudinal direction of the drawing, and the wiring GIa, the wiring GLD, the wiring EML, the wiring GLW, the wiring VEA, the wiring GLB, the wiring VER, the wiring VEI, the wiring GLC, the wiring VEN, and the wiring GIb extend in the lateral direction of the drawing, so that the wiring in the longitudinal direction and the wirings in the lateral direction are preferably provided to intersect with each other.

Each of the conductive layers 31 to 35 and each of the semiconductor layers 51 and 52 can be formed by a lithography method, for example. Specifically, for example, in the case where the conductive layer 31 is formed, a conductive material to be the conductive layer 31 is deposited by one or more methods selected from a sputtering method, a chemical vapor deposition (CVD) method, a pulsed laser deposition (PLD) method, and an atomic layer deposition (ALD) method, and then a desired pattern can be formed through photolithography. The conductive layers 32 to 35 and the semiconductor layers 51 and 52 can also be formed by a method similar to the above.

In this specification and the like, examples of the lithography method includes a photolithography method, an ion beam lithography method, an X-ray lithography method, an electron lithography method, a multiphoton lithography method, an interference lithography method, and a nanoimprinting method.

An insulating layer can be provided between the semiconductor layer 51 or 52 and the conductive layer 31, between the conductive layer 31 and the conductive layer 34, and the like. In particular, an insulating layer provided between the semiconductor layer 51 or 52 and the conductive layer 31 serves as a gate insulating film (sometimes referred to as a front gate insulating film or the like) in some cases. In a region where the capacitors C1 to C3 are provided, an insulating layer functioning as a dielectric of each of the capacitors C1 to C3 is preferably provided between the conductive layer 31 and the conductive layer 34.

As illustrated in FIG. 21, the capacitor C3 is preferably provided in part of a region where the conductive layer 31 extends as the wiring GLB. When part of the extending wiring is used as one of a pair of electrodes of the capacitor and the other of the pair of electrodes of the capacitor is located thereover, a region where the capacitor is provided can be easily ensured and the circuit area of the pixel circuit PX can be reduced.

In order to increase the electrostatic capacitance value, the region of the wiring GLB provided with the capacitor C3 may have a larger width than the region of the wiring GLB not provided with the capacitor C3. Increasing the capacitance of the capacitor C3 in this manner can prolong the retention time of the potential of the node N2 shown in the circuit diagram in FIG. 1B. The fluctuation amount of the potential of the node N2 due to capacitive coupling through the capacitor C3, which is caused by a change in the potential supplied from the wiring GLB, can also be increased.

Since the second terminal of the capacitor C1 and the first terminal of the capacitor C2 are connected to each other in the circuit configuration in FIG. 1B, it is preferable to provide a conductive layer shared by the second terminal of the capacitor C1 and the first terminal of the capacitor C2. Specifically, as illustrated in FIG. 21, a conductive layer 31a that is part of the conductive layer 31 is preferably provided, and the conductive layer 34 serving as the second terminal of the capacitor C1 and the conductive layer 34 serving as the first terminal of the capacitor C2 are preferably provided above the conductive layer 31a. Accordingly, the lead wiring for connecting the second terminal of the capacitor C1 and the first terminal of the capacitor C2 can be minimized, so that the circuit area of the pixel circuit PX can be reduced.

In a region of the insulating layer where part of the semiconductor layer 51 or 52 overlaps with part of the conductive layer 34, an opening portion is provided, and the conductive layer 32 is embedded in the opening portion. Thus, electric charge can be transferred between part of the semiconductor layer 51 or 52 and part of the conductive layer 34 through the conductive layer 32. Similarly, in a region of the insulating layer where part of the conductive layer 31 overlaps with part of the conductive layer 34, an opening portion is provided, and the conductive layer 33 is embedded in the opening portion. Thus, electric charge can be transferred between part of the conductive layer 31 and part of the conductive layer 34 through the conductive layer 33. In other words, the conductive layer 32 and the conductive layer 33 each have a function of a plug.

A plurality of conductive layers functioning as plugs are preferably provided to prevent a decrease in yield due to poor connection between different conductive layers. For example, in the schematic plan view in FIG. 21, two or more conductive layers 33 are provided over the conductive layers 31 of the wiring GIa, the wiring GLD, the wiring EML, the wiring GLW, the wiring VEA, the wiring GLB, the wiring VER, the wiring VEI, the wiring GLC, and the wiring VEN and the wiring GIb extending in the lateral direction of the drawing, and the conductive layer 34 is provided over these conductive layers 33. Note that in the region where the pixel circuit PX is formed, the number of conductive layers 33 functioning as plugs, which serve current paths between the conductive layer 31 and the conductive layer 34, may be reduced to one at minimum, in order to reduce the area of the region.

Meanwhile, in the case where the thickness of the insulating layer between the semiconductor layer 51 and the conductive layer 34 is small in the schematic plan view in FIG. 21, the conductive layer 32 functioning as a plug may be omitted and instead the semiconductor layer 51 and the conductive layer 34 may be in contact with each other. Similarly, in the case where the thickness of the insulating layer between the conductive layer 31 and the conductive layer 34 is small, the conductive layer 33 functioning as a plug may be omitted and instead the conductive layer 31 and the conductive layer 34 may be provided in contact with each other.

The conductive layer 35 has a function of a wiring for connecting the conductive layer 34 and a conductive layer (not illustrated) located above the conductive layer 35. The conductive layer 35 may have a function of a plug. A conductive layer located above the conductive layer 35 can be, for example, a conductive layer functioning as an anode of the light-emitting device ED provided in the pixel circuit PX or a conductive layer connected to the anode.

Since the transistor M2 and the transistor M5 are connected in series in the circuit diagram in FIG. 1B, the transistor M2 and the transistor M5 can be formed to share the island-shaped semiconductor layer 51 as in the schematic plan view in FIG. 21. Similarly, since the transistor M4 and the transistor M8 are connected in series in the circuit diagram in FIG. 1B, the transistor M4 and the transistor M8 can be formed to share the island-shaped semiconductor layer 51 as in the schematic plan view in FIG. 21. Similarly, since the transistor M6 and the transistor M7 are connected in series in the circuit diagram in FIG. 1B, the transistor M6 and the transistor M7 can be formed to share the island-shaped semiconductor layer 51 as in the schematic plan view in FIG. 21. Accordingly, the transistor formation area can be reduced, so that the pixel density of the pixel circuit PX can be increased and the circuit area of the display apparatus DSP can be reduced. In the circuit diagram in FIG. 1B, the transistor M6, the transistor M7, and the transistor M3 are n-channel transistors and connected in series; thus, these three transistors may be formed to share one island-shaped semiconductor layer (not illustrated).

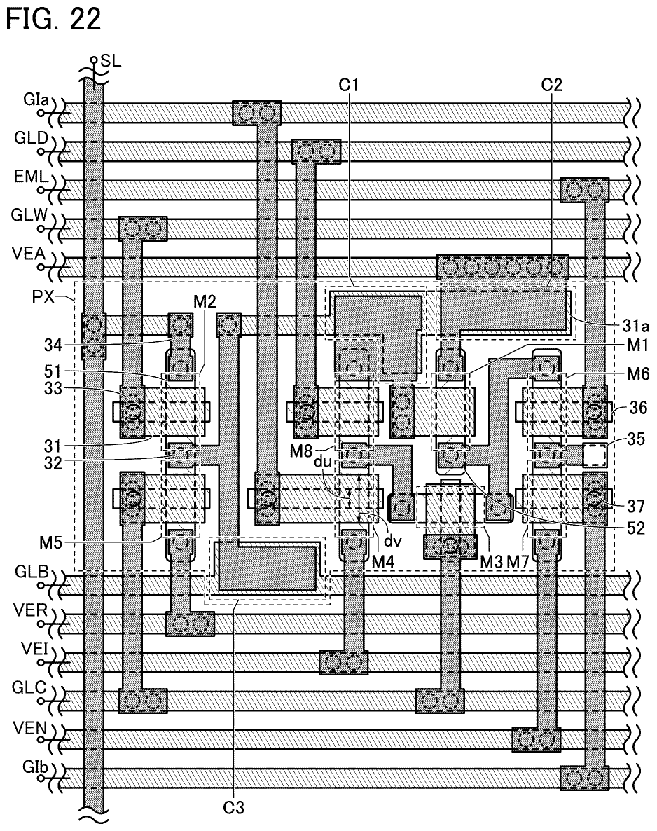

Wirings functioning as back gate electrodes (back gate wirings) may be provided for the transistors M2 to M8 included in the pixel circuit PX in FIG. 21. Specifically, FIG. 22 is a schematic plan view of the pixel circuit PX shown in FIG. 16A, for example. As illustrated in FIG. 22, a conductive layer 36 functioning as a back gate is provided below the semiconductor layer 51 including the channel formation region of each of the transistors M2 to M8. An opening portion is provided in a region of an insulating layer where the conductive layer 36 and the conductive layer 31 overlap with each other, and a conductive layer 37 is embedded in the opening portion. Thus, electric charge can be transferred between part of the conductive layer 36 and part of the conductive layer 31 through the conductive layer 37. That is, the conductive layer 37 serves as a plug. Accordingly, the gate and the back gate of each of the transistors M2 to M8 can be connected to each other, so that an increase in on-state current and a reduction in off-state current of these transistors can be achieved.

When the transistors M2 to M8 is each provided with the back gate electrode, an electric field generated outside these transistors is less likely to act on the channel formation region of each transistor. That is, when the back gate electrode is provided for the transistor, an effect of blocking an electric field from being applied from below the transistor to the channel formation region can be obtained. Examples of the electric field here include an electric field from a substrate provided with the transistor, a wiring located below the transistor, a circuit element, and the like. With the electric field blocking effect, the operation of the transistor can be stabilized. To enhance the electric field blocking effect, the area of a region where the conductive layer 36 and the channel formation region of the semiconductor layer 51 overlap with each other is preferably increased. For example, the area of a region where part of the region of the conductive layer 36, the channel formation region of the semiconductor layer 51, and the region functioning as the gate of the conductive layer 31 overlap with each other is preferably increased.

Specifically, it is preferable that the conductive layer 36 include a first region with a wiring width of du, the conductive layer 31 include a second region with a wiring width of dv, and each of the first region and the second region overlap with the semiconductor layer 51. Although du is shown to be shorter than dv in FIG. 22, in order to enhance the electric field blocking effect, du is preferably the same length as dv or longer than dv.

Note that the schematic plan view of the display apparatus of one embodiment of the present invention is not limited to that in FIG. 21 and FIG. 22. FIG. 21 or FIG. 22 modified appropriately may be used for the schematic plan view of the display apparatus of one embodiment of the present invention. For example, in FIG. 21 and FIG. 22, the transistor M2 and the transistor M5 are formed to share the island-shaped semiconductor layer 51, the transistor M4 and the transistor M8 are formed to share the island-shaped semiconductor layer 51, and the transistor M6 and the transistor M7 are formed to share the island-shaped semiconductor layer 51; however, a layout where an island-shaped semiconductor layer 51 is provided for the transistors M2, M4, M5, M6, M7, and M8 separately is available. That is, the number of semiconductor layers 51 may be seven in the pixel circuit PX.

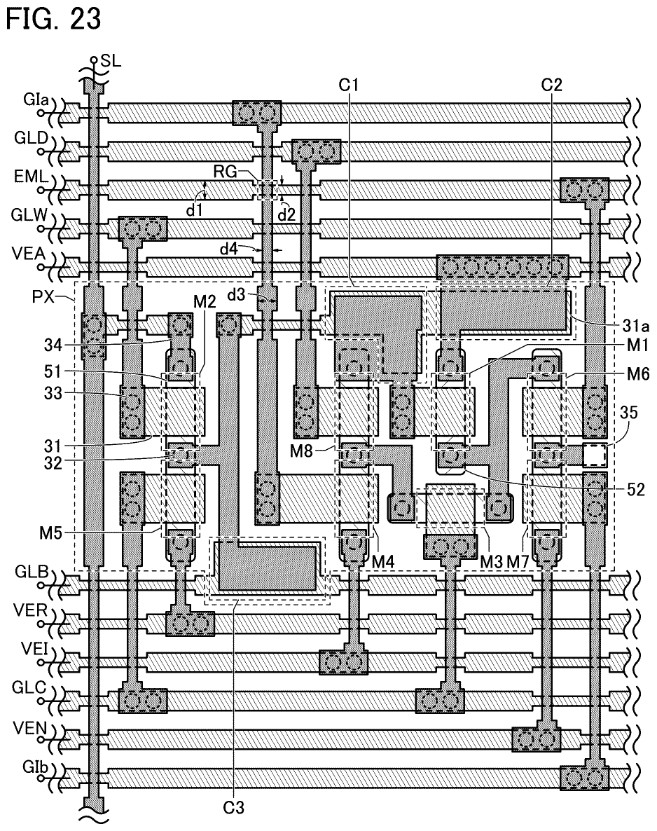

The schematic plan view of the display apparatus of one embodiment of the present invention may be FIG. 23 obtained by modifying FIG. 21. FIG. 23 illustrates an example of a schematic plan view of a display apparatus with a small area of a region RG where the conductive layer 31 and the conductive layer 34 overlap with each other. Specifically, the conductive layer 31 includes a region with a wiring width of d1 and a region with a wiring width of d2, and d2 is shorter than d1. The conductive layer 34 includes a region with a wiring width of d3 and a region with a wiring width of d4, and d4 is shorter than d3. In particular, the region RG and a region in the vicinity thereof each include a region where the width of the wiring in the conductive layer 31 becomes d2 and a region where the width of the wiring in the conductive layer 34 becomes d4.

As described above, when the area of the region RG is reduced, parasitic capacitance generated between the conductive layer 31 and the conductive layer 34 can be reduced. Accordingly, the time constant due to the parasitic capacitance can be reduced, and the driving speed of the pixel circuit PX can be increased.

### Structure Example 1 of Transistor

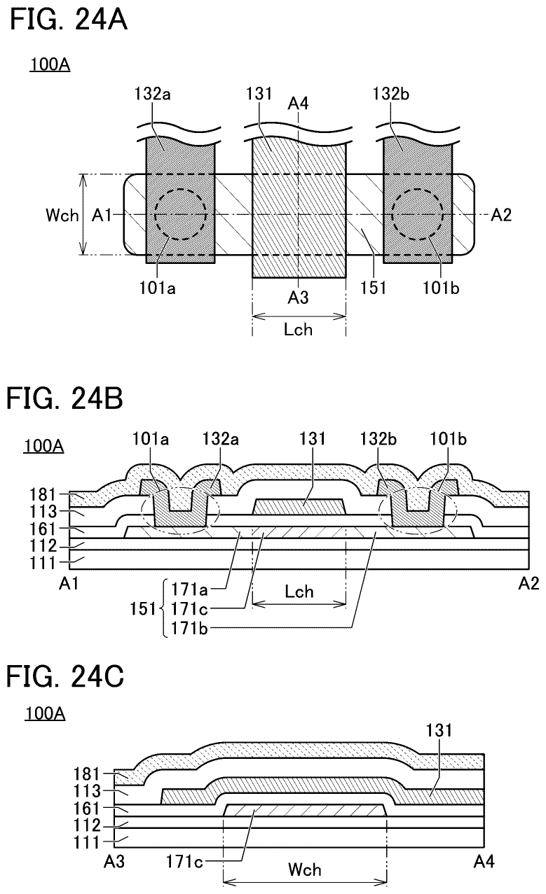

Next, a structure example of a transistor that can be used as the transistors M1 to M8 illustrated in FIGS. 21, 22, and 23 is described. FIG. 24A is a schematic plan view of a transistor 100A that can be used for the semiconductor device of one embodiment of the present invention. FIG. 24B is a schematic cross-sectional view taken along dashed-dotted line A1-A2 in FIG. 24A. FIG. 24C is a schematic cross-sectional view taken along dashed-dotted line A3-A4 in FIG. 24A. Note that for simplification, some components are not illustrated in the schematic plan view of FIG. 24A. Some components may be omitted also in other schematic plan views.

The transistor 100A includes an insulating layer 111 above a substrate (not illustrated), an insulating layer 112 above the insulating layer 111, and a semiconductor layer 151 above the insulating layer 112. An insulating layer 161 is provided above each of the insulating layer 112 and the semiconductor layer 151. A conductive layer 131 is provided above the insulating layer 161. The semiconductor layer 151 and the conductive layer 131 partly overlap with each other with the insulating layer 161 therebetween.

In particular, the conductive layer 131 can be the conductive layer 31 in the schematic plan views in FIGS. 21, 22, and 23.

The semiconductor layer 151 includes a region 171a functioning as one of a source region and a drain region of the transistor 100A, a channel formation region 171c, and a region 171b functioning as the other of the source region and the drain region. The region of the semiconductor layer 151 that overlaps with the conductive layer 131 functions as the channel formation region 171c. Thus, the conductive layer 131 functions as a gate electrode of the transistor 100A. The insulating layer 161 functions as a gate insulating film of the transistor 100A.

In the channel formation region 171c of the semiconductor layer 151, the distance between the region 171a and the region 171b in the direction of the dashed-dotted line A1-A2 is a channel length Lch of the transistor 100A (see FIGS. 24A and 24B). In the channel formation region 171c of the semiconductor layer 151, the length of a portion where the region 171a and the region 171b face each other along the dashed-dotted line A3-A4 is a channel width Wch of the transistor 100A (see FIGS. 24A and 24C).

The semiconductor layer 151 can be the semiconductor layer 51 in the schematic plan views in FIGS. 21, 22, and 23.

An insulating layer 113 is provided above each of the insulating layer 161 and the conductive layer 131. In a region of the semiconductor layer 151 overlapping with the region 171a, an opening portion 101a is provided in each of the insulating layer 161 and the insulating layer 113. In a region of the semiconductor layer 151 overlapping with the region 171b, an opening portion 101b is provided in the insulating layer 161 and the insulating layer 113.

A conductive layer 132a is provided on the side surface of the opening portion 101a and the top surface of the region 171a exposed in the opening portion 101a. Specifically, the conductive layer 132a is provided in contact with the side surface of the insulating layer 161, the side surface of the insulating layer 113, and the region 171a of the semiconductor layer 151 in the opening portion 101a. Note that the conductive layer 132a may also be provided on the top surface of the insulating layer 113 outside the opening portion 101a. Similarly, a conductive layer 132b is provided on the side surface of the opening portion 101b and the top surface of the region 171b exposed in the opening portion 101b. Specifically, the conductive layer 132b is provided in contact with the side surface of the insulating layer 161, the side surface of the insulating layer 113, and the region 171b of the semiconductor layer 151 in the opening portion 101b. Note that the conductive layer 132b may also be provided on the top surface of the insulating layer 113 outside the opening portion 101b.

The conductive layer 132a functions as one of a source electrode and a drain electrode of the transistor 100A, and the conductive layer 132b functions as the other of the source electrode and the drain electrode of the transistor 100A.

An insulating layer 181 is provided above the insulating layer 113 and the conductive layers 132a and 132b (also collectively referred to as conductive layer 132).

The conductive layer 132 can be the conductive layer 32 in the schematic plan views in FIGS. 21, 22, and 23. The conductive layer 132 can extend as a wiring as illustrated in FIG. 24A; thus, the conductive layer 132 can also function as the conductive layer 34 in the schematic plan views in FIGS. 21, 22, and 23.

### Structure Example 2 of Transistor

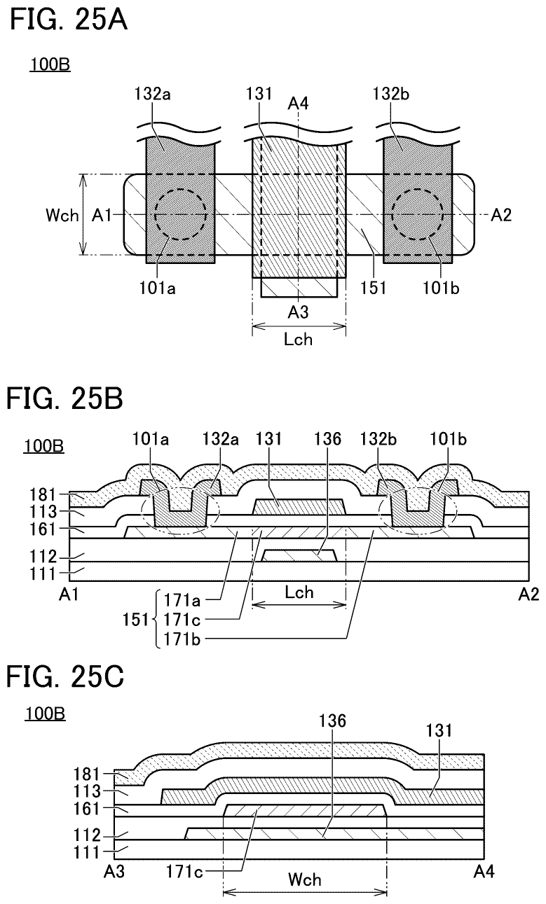

FIG. 25A is a top view of a transistor 100B that can be used for the semiconductor device of one embodiment of the present invention. The transistor 100B is a variation of the transistor 100A. Here, differences of the transistor 100B from the transistor 100A are mainly described.

FIG. 25B is a schematic cross-sectional view taken along the dashed-dotted line A1-A2 in FIG. 25A. FIG. 25C is a schematic cross-sectional views taken along dashed-dotted line A3-A4 in FIG. 25A.

A conductive layer 136 overlaps with the channel formation region 171c with the insulating layer 112 therebetween. Thus, the insulating layer 112 functions as a back gate insulating film of the transistor 100B, and part of the conductive layer 136 functions as a back gate electrode of the transistor 100B. Note that the thickness of the insulating layer 112 in a region not overlapping with the conductive layer 136 may be different from that of the insulating layer 112 in a region overlapping with the conductive layer 136; alternatively, the insulating layer 112 may have a uniform thickness. The conductive layer 136 may extend beyond an end portion of the channel formation region 171c. In other words, the channel formation region 171c may be covered with the conductive layer 136.

Here, in a transistor including a back gate, a gate and the back gate of the transistor are placed such that a channel formation region of a semiconductor layer is sandwiched therebetween. The back gate can function in a manner similar to that of the gate. In the case where the gate is used for control of the on state and the off state of the transistor, the potential of the back gate can be the same as the potential of the gate. Alternatively, the potential of the back gate can be a given potential.

In the case where the transistor is turned on, for example, the amount of on-state current can be larger when both the gate and the back gate are supplied with a potential for turning on the transistor than when only one of them is supplied with the potential. For example, when the gate and the back gate are connected to each other, the gate and the back gate can always have the same potential. By controlling the potential of the back gate independently of that of the gate, the threshold voltage of the transistor can be adjusted.

Alternatively, a fixed potential such as a ground potential may be supplied to the back gate. Since the gate and the back gate are formed using a conductive layer or the like, an electric field generated outside the transistor does not easily act on a channel formation region of a semiconductor layer that is sandwiched between the gate and the back gate (such an effect is also referred to as “electric field blocking effect”). Therefore, the transistor provided with the back gate operates stably. Moreover, a variation in characteristics between a plurality of transistors is reduced when the transistors are provided with back gates. The transistor provided with the back gate can be highly reliable. Accordingly, a semiconductor device including the transistor can be highly reliable. The electric field blocking effect can be achieved in a state where one or both of the gate and the back gate is/are in an electrically floating state (also referred to as a “floating state”); the effect can be enhanced by supplying a potential to the gate and the back gate.

### Structure Example 3 of Transistor

Next, described is a structure example of a transistor that can be used as the transistors M1 to M8 illustrated in FIGS. 21, 22, and 23 and is different from the transistor 100A and the transistor 100B.

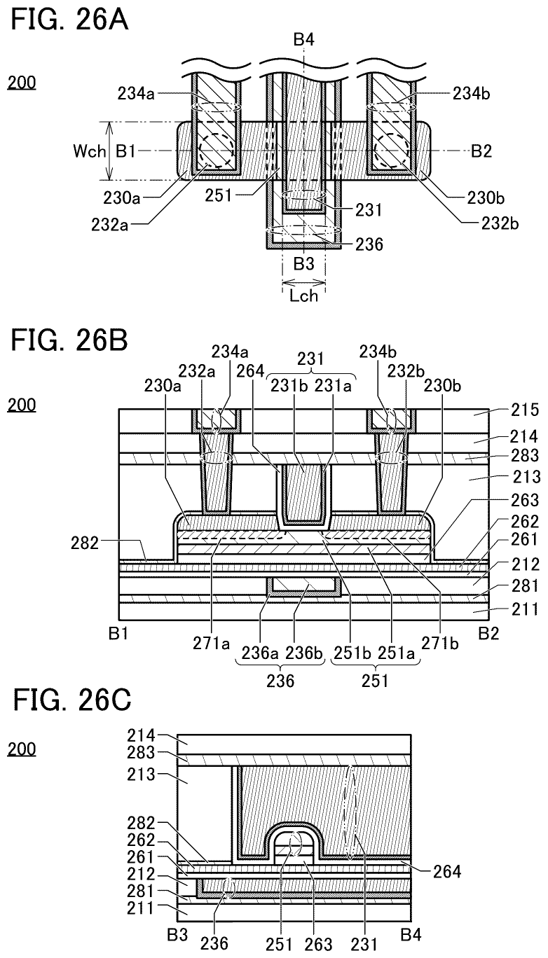

First, a specific transistor structure example that is called a gate last (GL) structure applicable to the transistors M1 to M8 illustrated in FIGS. 21, 22, and 23 is described. A transistor 200 illustrated in FIGS. 26A, 26B, and 26C can be an example of the transistors M1 to M8 illustrated in FIGS. 21, 22, and 23. FIG. 26A is a schematic plan view of the transistor 200 that can be included in the semiconductor device of one embodiment of the present invention. FIG. 26B is a schematic cross-sectional view taken along the dashed-dotted line B1-B2 in FIG. 26A, and FIG. 26C is a schematic cross-sectional view taken along the dashed-dotted line B3-B4 in FIG. 26A.

As illustrated in FIGS. 26B and 26C, the transistor 200 includes, for example, a conductive layer 236, a semiconductor layer 251a, a semiconductor layer 251b, a conductive layer 230a, a conductive layer 230b, a conductive layer 231a, a conductive layer 231b, a conductive layer 232a, a conductive layer 232b, and insulating layers 261, 262, 263, and 264. Note that FIGS. 26A to 26C also illustrate insulating layers 211, 212, 213, 214, and 215, insulating layers 281, 282, and 283, and conductive layers 234a and 234b for convenience.

Note that the transistor 200 does not include all the above components in some cases. For example, although the conductive layer 236 functions as a back gate electrode in the transistor 200 as described later, the transistor 200 as one embodiment of the present invention may have a structure not including the conductive layer 236 functioning as a back gate electrode, as in the transistors illustrated in FIG. 21 and FIG. 23.

As illustrated in FIGS. 26B and 26C, the transistor 200 is provided above the insulating layer 211 and the insulating layer 281. Note that the insulating layer 281 is provided on the top surface of the insulating layer 211. The insulating layer 212 is provided on the top surface of the insulating layer 281. The insulating layer 212 has an opening portion reaching the insulating layer 281.

A conductive layer 236a is preferably provided in contact with the top surface of the insulating layer 281 exposed in the opening portion and the side surface of the insulating layer 212 in the opening portion. A conductive layer 236b is preferably provided to be embedded in a depressed portion formed by the conductive layer 236a in the opening portion. In the transistor 200 in each of FIGS. 26B and 26C, the top surface of the conductive layer 236b is substantially level with the top surfaces of the conductive layer 236a and the insulating layer 212.

The conductive layer 236a and the conductive layer 236b (sometimes collectively referred to as conductive layer 236) have a function of a second gate electrode (sometimes referred to as a bottom gate electrode or a back gate electrode) of the transistor 200. In this case, a potential applied to the conductive layer 236 can be changed independently of a potential applied to a conductive layer 231 having a function of a first gate electrode described later, so that the threshold voltage of the transistor 200 can be controlled. In particular, when a negative potential is applied to the conductive layer 236, the threshold voltage of the transistor 200 can be further increased, and the off-state current can be reduced. Thus, the drain current at the time when a potential applied to the conductive layer 231 is 0 V can be lower in the case where a negative potential is applied to the conductive layer 236 than in the case where the negative potential is not applied to the conductive layer 236.

As illustrated in FIG. 26C, the conductive layer 236 can extend as a wiring in a region outside an end portion of the semiconductor layer 251 that intersects with the channel width direction. In particular, the conductive layer 236 can be the conductive layer 36 in the schematic plan view in FIG. 22.

The insulating layer 261 and the insulating layer 262 are provided in this order above each of the insulating layer 212 and the conductive layer 236. The insulating layer 263, the semiconductor layer 251a, and the semiconductor layer 251b are formed in this order above the insulating layer 262 including a region overlapping with the conductive layer 236. Specifically, a layer including the insulating layer 263, the semiconductor layer 251a, and the semiconductor layer 251b is formed above the insulating layer 262 so as to have an island shape.

The conductive layer 230a and the conductive layer 230b (collectively referred to as conductive layer 230) are provided over the semiconductor layer 251b to be apart from each other. In particular, as illustrated in FIG. 26B, a region 271a is sometimes formed as a low-resistance region at and near the interface between the semiconductor layer 251b and the conductive layer 230a. Similarly, a region 271b is sometimes formed as a low-resistance region at and near the interface between the semiconductor layer 251b and the conductive layer 230b. In that case, the region 271a functions as one of a source region and a drain region, and the region 271b functions as the other of the source region and the drain region. In the semiconductor layer 251b, the channel formation region is formed in a region sandwiched between the region 271a and the region 271b.

In particular, the width of the conductive layer 231 intersecting with the semiconductor layer 251b, described later, can be the channel length Lch of the transistor 200 (see FIG. 26A). The length of a portion where the region 271a and the region 271b face each other in the semiconductor layer 251b along the dashed-dotted line B3-B4 can be the channel width Wch of the transistor 200 (see FIG. 26A).

The insulating layer 282 is provided above the island-shaped layer including the insulating layer 263, the semiconductor layer 251a, and the semiconductor layer 251b and above the insulating layer 262. Specifically, in FIGS. 26B and 26C, the insulating layer 282 is provided above the insulating layer 262 and on the side surface of the insulating layer 263, the side surface of the semiconductor layer 251a, the side surface of the semiconductor layer 251b, the top and side surfaces of the conductive layer 230a, and the top and side surfaces of the conductive layer 230b.

Note that in this specification, the semiconductor layer 251a and the semiconductor layer 251b are collectively referred to as a semiconductor layer 251 in some cases.

The semiconductor layer 251 can be the semiconductor layer 51 or the semiconductor layer 52 in the schematic plan views in FIGS. 21, 22, and 23.

The insulating layer 213 is provided on the top surface of the insulating layer 282. In a region of the insulating layer 213 and the insulating layer 282 that overlaps with the conductive layer 236, an opening portion is provided to reach the semiconductor layer 251b. By providing the opening portion in FIG. 26B, side surfaces of the insulating layer 213, the conductive layer 230a, and the conductive layer 230b are formed, and the top surface of the semiconductor layer 251b is exposed. By providing the opening portion in FIG. 26C, the side surface of the insulating layer 213 is formed, and the side surface of the semiconductor layer 251b and the top surface of the insulating layer 262 are exposed.

The insulating layer 264 is provided in contact with the side surface of the insulating layer 213, the top surface of the insulating layer 262, the side surface of the insulating layer 263, the side surface of the semiconductor layer 251b, and the side surface and the top surface of the semiconductor layer 251a in the opening portion. The conductive layer 231a is provided in contact with the top surface of the insulating layer 264 in the opening portion. The conductive layer 231b is provided in contact with the top surface of the conductive layer 231a to fill the opening portion. Note that the level of the top surface of the conductive layer 231b is substantially equal to the level of the top surface of the insulating layer 213, the level of the upper end portion of the insulating layer 264, and the level of the upper end portion of the conductive layer 231a.

The conductive layer 231a and the conductive layer 231b (sometimes collectively referred to as conductive layer 231) have a function of a first gate electrode (sometimes referred to as a top gate electrode or a front gate electrode) in the transistor 200.

The insulating layer 264 and the conductive layer 231 are formed in a self-aligned manner with respect to the opening portion. In other words, in the transistor 200, the first gate electrode can be positioned between the source electrode and the drain electrode in a self-aligned manner. Thus, the conductive layer 231 can be formed without an alignment margin, resulting in a reduction in the footprint of the transistor 200. Accordingly, the pixel density of the cell array in the display apparatus can be increased.

As illustrated in FIG. 26C, the conductive layer 231 can extend as a wiring in a region outside the end portion of the semiconductor layer 251 that intersects with the channel width direction, like the conductive layer 236. In particular, the conductive layer 231 can be the conductive layer 31 in the schematic plan views in FIGS. 21, 22, and 23.

The insulating layer 283 is provided on the top surface of the insulating layer 213, the upper end portion of the insulating layer 264, the upper end portion of the conductive layer 231a, and the top surface of the conductive layer 231b. The insulating layer 214 is provided on the top surface of the insulating layer 283. An opening portion reaching the conductive layer 230a and an opening portion reaching the conductive layer 230b are provided in a stack of the insulating layer 282, the insulating layer 213, the insulating layer 283, and the insulating layer 214. By providing the opening portion reaching the conductive layer 230a in the stack in FIG. 26B, side surfaces of the insulating layer 282, the insulating layer 213, the insulating layer 283, and the insulating layer 214 are formed, and the top surface of the conductive layer 230a is exposed. By providing the opening portion reaching the conductive layer 230b in the stack in FIG. 26B, side surfaces of the insulating layer 282, the insulating layer 213, the insulating layer 283, and the insulating layer 214 are formed, and the top surface of the conductive layer 230b is exposed, as in the case of providing the opening portion reaching the conductive layer 230a.

The conductive layer 232a is provided to fill the opening portion reaching the conductive layer 230a in the stack. Thus, the conductive layer 232a is in contact with the top surface of the conductive layer 230a corresponding to the bottom portion of the opening portion. The conductive layer 232b is provided to fill the opening portion reaching the conductive layer 230b in the stack. Thus, the conductive layer 232b is in contact with the top surface of the conductive layer 230b corresponding to the bottom portion of the opening portion.

In this specification, the conductive layer 232a and the conductive layer 232b are sometimes collectively referred to as a conductive layer 232.

Although the conductive layer 232a have a stacked-layer structure of two layers in FIG. 26B, a structure relating to one embodiment of the present invention is not limited thereto. For example, the conductive layer 232a may have a single-layer structure or a stacked-layer structure of three or more layers. Similarly, the conductive layer 232b may have a single-layer structure or a stacked-layer structure of three or more layers instead of a stacked-layer structure of two layers.

The conductive layer 232 can be the conductive layer 32 in the schematic plan views in FIGS. 21, 22, and 23.

The insulating layer 215 is provided above the insulating layer 214. The insulating layer 215 is provided with opening portions in a region overlapping with the conductive layer 234a and a region overlapping with the conductive layer 234b. By providing these opening portions in FIG. 26B, side surfaces of the insulating layer 215 are formed. The top surface of the insulating layer 214 and the top surface of the conductive layer 232a are exposed in the opening portion provided in the insulating layer 215 in the region overlapping with the conductive layer 234a. The top surface of the insulating layer 214 and the top surface of the conductive layer 232b are exposed in the opening portion provided in the insulating layer 215 in the region overlapping with the conductive layer 234b.

The conductive layer 234a is provided to fill the opening portion reaching the conductive layer 234a in the insulating layer 215. Thus, the conductive layer 234a is in contact with the top surface of the conductive layer 232a corresponding to the bottom portion of the opening portion. The conductive layer 234b is provided to fill the opening portion reaching the conductive layer 234b in the insulating layer 215. Thus, the conductive layer 234b is in contact with the top surface of the conductive layer 232b corresponding to the bottom portion of the opening portion.

In this specification, the conductive layer 234a and the conductive layer 234b are sometimes collectively referred to as a conductive layer 234.

Although the conductive layer 234a has a two-layer structure in FIGS. 26A and 26B, a structure relating to one embodiment of the present invention is not limited to this. For example, the conductive layer 234a may have a single-layer structure or a stacked-layer structure of three or more layers. Similarly, the conductive layer 234b may have a single-layer structure or a stacked-layer structure of three or more layers instead of a stacked-layer structure of two layers.

The conductive layer 234 can be the conductive layer 34 in the schematic plan views in FIGS. 21, 22, and 23.

### Constituent Material of Transistor

Next, constituent materials that can be used for the transistor 100A, the transistor 100B, and the transistor 200 described above are described.

### [Substrate]

In the case where the transistor is provided over a substrate, there is no particular limitation on a material used for the substrate. The material used for the substrate can be determined in accordance with the purpose considering whether it has a light-transmitting property, heat resistance high enough to withstand heat treatment, and the like. As the substrate, an insulator substrate, a semiconductor substrate, or a conductor substrate may be used, for example. As the insulator substrate, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used, for example. Alternatively, a semiconductor substrate, a flexible substrate, a resin substrate, or the like may be used as the substrate.

Examples of the semiconductor substrate include a semiconductor substrate containing a material such as silicon or germanium and a compound semiconductor substrate containing a material such as silicon carbide, silicon germanium, gallium arsenide, indium phosphide, zinc oxide, or gallium oxide. Other examples include the above semiconductor substrates provided with an insulator region, such as a silicon on insulator (SOI) substrate. The semiconductor substrate may be a single crystal semiconductor or a polycrystalline semiconductor.

Examples of the conductor substrate include a graphite substrate, a metal substrate, an alloy substrate, and a conductive resin substrate. Other examples include a substrate including a nitride of a metal and a substrate including an oxide of a metal. Moreover, other examples of the conductor substrate include an insulator substrate provided with a conductive layer or a semiconductor layer, a semiconductor substrate provided with a conductive layer or an insulating layer, and a conductor substrate provided with a semiconductor layer or an insulating layer.

For the material of the flexible substrate, the resin substrate, or the like, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), a polyamide (e.g., nylon or aramid), polysiloxane, a cycloolefin resin, polystyrene, polyamide-imide, polyurethane, polyvinyl chloride, polyvinylidene chloride, polypropylene, polytetrafluoroethylene (PTFE), an ABS resin, or cellulose nanofiber can be used, for example.

When any of the above-described materials is used for the substrate, a lightweight semiconductor device can be provided. Furthermore, with use of any of the materials described above for the substrate, a shock-resistant semiconductor device can be provided. Furthermore, with use of any of the materials described above for the substrate, a semiconductor device that is less likely to be broken can be provided. Alternatively, these substrates provided with elements may be used. Examples of the element provided over the substrate include a capacitor, a resistor, a switching element, a light-emitting element, and a memory element.

### [Insulating Layer]

An inorganic insulating film can be used for the insulating layers (the insulating layers 111 to 113, the insulating layer 161, the insulating layer 181, the insulating layers 211 to 215, the insulating layers 281 to 283, the insulating layers 261 to 264, and the like). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used as each of the insulating layers included in the semiconductor device.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content. Note that the content of each element can be measured by Rutherford backscattering spectrometry (RBS), for example.

As scaling down and high integration of transistors progress, for example, a problem such as generation of leakage current may arise because of a thinner gate insulating film. When a material with a high dielectric constant (high-k material) is used for an insulating layer functioning as a gate insulating film, such as the insulating layer 161 and the insulating layers 261 to 264, the voltage at the time of operation of the transistor can be reduced while the physical thickness is maintained. Furthermore, the equivalent oxide thickness (EOT) of the gate insulating film can be reduced. When a material with a high dielectric constant is used for an insulating layer functioning as a dielectric of a capacitor, the capacitance per unit area can be increased. By contrast, when a material with a low dielectric constant is used for the insulating layer functioning as an interlayer film, the parasitic capacitance generated between wirings can be reduced. Thus, a material can be selected depending on the function of an insulating layer. Note that a low-dielectric-constant material is a material with high dielectric strength.

Examples of the material with a high dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as a polyester, a polyolefin, a polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

### [Conductive Layer]

For each of the conductive layers (e.g., the conductive layers 131, 132, 136, 230 to 234, and 236) included in the transistor 200, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high conductivity, typified by polycrystalline silicon containing an impurity element such as phosphorus, or silicide such as nickel silicide may be used.

It is preferable to use a conductive material that is less likely to be oxidized, a conductive material having a function of inhibiting diffusion of oxygen, or a material that maintains its conductivity even after absorbing oxygen. Examples of such a material include a conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum. Other examples include a conductive material containing oxygen, such as ruthenium oxide, an oxide containing strontium and ruthenium, or an oxide containing lanthanum and nickel. Another example is a material containing a metal element such as titanium, tantalum, or ruthenium. Examples of the conductive material containing oxygen include a material containing tungsten oxide and indium oxide, a material containing titanium oxide and indium oxide, indium tin oxide (also referred to as ITO), indium tin oxide containing titanium oxide, indium tin oxide containing silicon oxide (also referred to as ITSO), indium zinc oxide (also referred to as IZO (a registered trademark)), and indium zinc oxide containing tungsten oxide. In this specification and the like, a conductive layer formed using the conductive material containing oxygen may be referred to as an oxide conductive layer.

Furthermore, as a material having high conductivity, a conductive material containing tungsten, copper, or aluminum as its main component is preferably used.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

For example, in the case where the semiconductor layer 151 of the transistor 100A or 100B is formed using an oxide semiconductor, which is a kind of metal oxide, the conductive layers functioning as the gate electrodes such as the conductive layers 131 and 136 may each have a stacked-layer structure combining a material containing any of the above metal elements and a conductive material containing oxygen. In that case, the conductive material containing oxygen may be provided on the semiconductor layer 151 side. By providing the conductive material containing oxygen on the semiconductor layer 151 side in the conductive layer 131 or 136 with a stacked structure, oxygen released from the conductive material is easily supplied to the channel formation region of the semiconductor layer 151.

For example, in the case where the semiconductor layer 251 of the transistor 200 is formed using an oxide semiconductor, which is a kind of metal oxide, the conductive layers functioning as the gate electrodes such as the conductive layers 231 and 236 may each have a stacked-layer structure obtained by combining a material containing any of the above metal elements and a conductive material containing oxygen. Specifically, the conductive layer 231a may be formed using a conductive material containing oxygen, and the conductive layer 231b may be formed using a material containing any of the above metal elements for example. For another example, a conductive material containing oxygen may be used for the conductive layer 231b, and a material containing any of the above metal elements may be used for the conductive layer 231a. With this structure, oxygen released from the conductive material is easily supplied to the channel formation region of the semiconductor layer 251.

In the case where the semiconductor layer 151 of the transistor 100A or 100B is formed using an oxide semiconductor, which is a kind of metal oxide, the conductive layer 132 is in contact with the semiconductor layer 151. Thus, the conductive layer 132 may be formed using a conductive material that is less likely to be oxidized, a conductive material that maintains its low electric resistance even after being oxidized, a metal oxide that has conductivity (also referred to as an oxide conductor), or a conductive material that has a function of inhibiting diffusion of oxygen. Examples of the conductive materials include a conductive material containing nitrogen and a conductive material containing oxygen. Thus, a decrease in conductivity of the conductive layer 132 can be inhibited.

When a conductive material containing oxygen is used for the conductive layer 132, the conductive layer 132 can maintain its conductivity even when absorbing oxygen. For example, it is suitable to use an insulating layer containing excess oxygen as the insulating layer in contact with the conductive layer 132 because the conductive layer 132 can maintain its conductivity. The conductive layer 132 can be formed using ITO, ITSO, IZO (registered trademark), or the like.

Similarly, in the case where the semiconductor layer 251 of the transistor 200 is formed using an oxide semiconductor, which is one kind of metal oxide, the conductive layer 230 is preferably formed using a conductive material that is less likely to be oxidized, a conductive material that maintains low electric resistance even after being oxidized, a conductive metal oxide (also referred to as an oxide conductor), or a conductive material having a function of inhibiting diffusion of oxygen because the conductive layer 230 is in contact with the semiconductor layer 251. This can inhibit a decrease in the conductivity of the conductive layer 230. When a conductive material containing oxygen is used for the conductive layer 230, the conductive layer 230 can maintain its conductivity even after absorbing oxygen. This is preferable because the conductivity of the conductive layer 230 can be maintained, for example, even in the case where an insulating layer in contact with the conductive layer 230 contains excess oxygen.

Each of the conductive layers 131, 132, 136, and the like in the transistor 100A or 100B may have a stacked-layer structure obtained by combining a material containing any of the above metal elements and a conductive material having a function of inhibiting diffusion of oxygen. Similarly, each of the conductive layers 231, 232, 234, 236, and the like in the transistor 200 may have the stacked-layer structure. Specifically, a material containing any of the above metal elements is used for the conductive layer 231b and a conductive material having a function of inhibiting diffusion of oxygen is used for the conductive layer 231a, whereby diffusion of oxygen into the conductive layer 231b can be inhibited and a decrease in the conductivity of the conductive layer 231b can be inhibited, for example. Similarly, a material containing any of the above metal elements is used for the conductive layer 236b and a conductive material having a function of inhibiting diffusion of oxygen is used for the conductive layer 236a, whereby a decrease in the conductivity of the conductive layer 236b can be inhibited. In a manner similar to the above, the conductive layer 232 or 234 is formed to have a stacked-layer structure where a material containing any of the above metal elements is partly or wholly surrounded by a material with a function of inhibiting diffusion of oxygen, whereby a decrease in the conductivity of the conductive layer 232 or 234 can be inhibited.

### [Semiconductor Layer]

For each of the semiconductor layers (e.g., the semiconductor layers 151 and 251), a single-crystal semiconductor, a polycrystalline semiconductor, a microcrystalline semiconductor, an amorphous semiconductor, or the like can be used alone or in combination.

A single-element semiconductor or a compound semiconductor may be used for the semiconductor layers. Examples of the single-element semiconductor include silicon and germanium. Examples of the compound semiconductor include gallium arsenide, silicon carbide, and silicon germanium. Other examples of the compound semiconductor include an organic semiconductor and a nitride semiconductor. Note that an oxide semiconductor is also a kind of compound semiconductor. These semiconductor materials may contain an impurity as a dopant.

In the case where silicon is used for the semiconductor layers, examples of silicon that can be used for the semiconductor layers include single crystal silicon, polycrystalline silicon, microcrystalline silicon, and amorphous silicon. An example of polycrystalline silicon is low-temperature polysilicon (LTPS).

When silicon is used for the semiconductor layer 151 and phosphorus or arsenic is contained as an n-type dopant in the regions 171a and 171b of the semiconductor layer 151 in the transistor 100A or 100B, for example, the transistor can function as an n-channel transistor. When boron is contained as a p-type dopant in the regions 171a and 171b in the semiconductor layer 151, the transistor can function as a p-channel transistor. Note that in the case where both an n-type dopant and a p-type dopant are contained in the regions 171a and 171b of the semiconductor layer 151, the conductive type of the dopant having a higher concentration is likely to be exhibited.

Alternatively, the semiconductor layers may be formed using a two-dimensional material functioning as a semiconductor. The two-dimensional material, which is also referred to as a layered material, generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high conductivity in a unit layer, that is, high two-dimensional conductivity. When a material that functions as a semiconductor and has high two-dimensional conductivity is used for the semiconductor layers, the transistors can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layers include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

For the semiconductor layers, an oxide semiconductor, which is a kind of metal oxide, may be used, for example. In that case, the band gap of the metal oxide is preferably greater than or equal to 2.0 eV, further preferably greater than or equal to 2.5 eV. The use of such a metal oxide having a wide band gap for the semiconductor layers can significantly reduce the amounts of the off-state currents of the transistors. The off-state current of an OS transistor is low, so that power consumption of the semiconductor device can be reduced. Specifically, for example, in the transistor 200, an oxide semiconductor can be used for the semiconductor layer 251.

It is preferable that a channel formation region of a transistor including an oxide semiconductor in a semiconductor layer include less oxygen vacancies or have a lower impurity concentration (e.g., concentration of hydrogen, nitrogen, and a metal element) than a source region and a drain region. In some cases, V_{O}H (a defect that is an oxygen vacancy into which hydrogen has entered) is formed with hydrogen in the vicinity of the oxygen vacancy and an electron serving as a carrier is generated; therefore, it is also preferable that the amount of V_{O}H be small. Thus, the channel formation region of the transistor is a high-resistance region having a low carrier concentration. Accordingly, the channel formation region of the transistor can be regarded as an i-type (intrinsic) or substantially i-type region.

The source region and the drain region of the transistor preferably include more oxygen vacancies, include more V_{O}H, or have a higher impurity concentration than the channel formation region. Thus, the source region and the drain region of the transistor are n-type regions having higher carrier concentrations and lower resistances than the channel formation region.

### [Oxide Semiconductor Layer]

Next, an oxide semiconductor layer that can be used as the semiconductor layer of the transistor of one embodiment of the present invention is described.

The oxide semiconductor layer of one embodiment of the present invention preferably includes a metal oxide having crystallinity. Examples of the structure of a metal oxide having crystallinity include a c-axis aligned crystalline (CAAC) structure, a polycrystalline structure, a microcrystalline structure and a nano-crystalline (nc) structure. By using a metal oxide having crystallinity for the oxide semiconductor layer, the density of defect states in the oxide semiconductor layer can be reduced. This can improve the reliability of the transistor including the oxide semiconductor layer of one embodiment of the present invention, thereby improving the reliability of a semiconductor device including the transistor.

It is particularly preferable that the oxide semiconductor layer of one embodiment of the present invention include a metal oxide having a CAAC structure. The CAAC structure is a crystal structure in which a plurality of nanocrystals (typically, a plurality of nanocrystals each having a hexagonal crystal structure) have c-axis alignment and are connected on the a-b plane without alignment. In cross-sectional observation of an oxide semiconductor layer having the CAAC structure with use of a high-resolution transmission electron microscope (TEM) image, metal atoms are observed to be arranged in a layered manner in a crystal part. Thus, the oxide semiconductor layer having the CAAC structure can also be referred to as a structure including the layered crystal parts.

The crystallinity of the oxide semiconductor layer can be analyzed by X-ray diffraction (XRD), TEM, or electron diffraction (ED), for example. Alternatively, these methods may be combined to be employed for analysis.

Note that there is no particular limitation on the crystallinity of a semiconductor material contained in the oxide semiconductor layer. The oxide semiconductor layer sometimes contains, for example, at least one of an amorphous semiconductor (a semiconductor having an amorphous structure), a single crystal semiconductor (a semiconductor having a single crystal structure), and a semiconductor having crystallinity other than single crystal (a nanocrystalline semiconductor, a polycrystalline semiconductor, or a semiconductor partly including crystal regions). The oxide semiconductor layer having crystallinity can inhibit deterioration of the transistor characteristics in some cases.

Examples of the metal oxide of one embodiment of the present invention include indium oxide, gallium oxide, and zinc oxide. The metal oxide of one embodiment of the present invention preferably contains at least indium (In). The metal oxide preferably contains at least indium (In) or zinc (Zn). The metal oxide preferably contains two or three selected from indium, an element M, and zinc. The element M is a metal element or a metalloid element that has a high binding energy with oxygen and is, for example, a metal element or a metalloid element whose binding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, and still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

An example of the metal oxide of one embodiment of the present invention is indium oxide. Examples of the metal oxide of one embodiment of the present invention include indium zinc oxide (also referred to as In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide, IGTO), indium tungsten oxide (In—W oxide), gallium zinc oxide (also referred to as Ga—Zn oxide or GZO), aluminum zinc oxide (also referred to as Al—Zn oxide or AZO), indium aluminum zinc oxide (also referred to as In-Al-Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO). Alternatively, indium tin oxide containing silicon oxide (also referred to as ITSO), gallium tin oxide (Ga—Sn oxide), aluminum tin oxide (Al—Sn oxide), or the like can be used.

By increasing the proportion of the number of indium atoms (also referred to as indium (In) content percentage) in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in the electrical characteristics of the transistor can be reduced to improve the reliability of the transistor.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in the electrical characteristics of the transistor can be reduced to improve the reliability of the transistor.

In particular, in the pixel circuit PX that is the semiconductor device of one embodiment of the present invention, the transistor M1 that is a p-channel transistor can contain silicon in a channel formation region, and the transistors M2 to M8 that are n-channel transistors can contain a metal oxide as an oxide semiconductor in a channel formation region. The transistor M1 can be referred to as a Si transistor, and the transistors M2 to M8 can each be referred to as an OS transistor. Furthermore, the Si transistor can be referred to as an LTPS transistor. Note that a structure in which an LTPS transistor and an OS transistor are used in combination is referred to as LTPO in some cases.

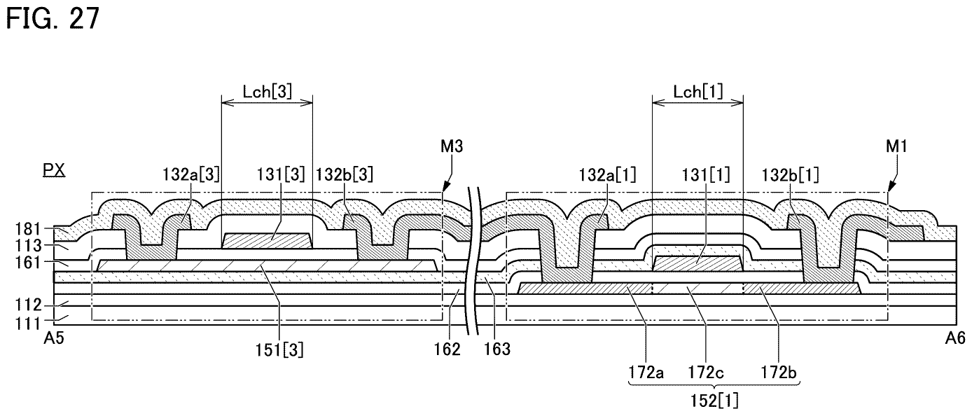

A specific structure example of LTPO is described. The pixel circuit PX illustrated in FIG. 27 is a schematic cross-sectional view along the dashed-dotted line A5-A6 in the schematic plan view of FIG. 21, and shows a structure example in which an LTPS transistor is used as the transistor M1 and an OS transistor is used as the transistor M3.

The transistor M1 and the transistor M3 illustrated in FIG. 27 each have the structure illustrated in FIGS. 24A to 24C. Note that in the structure of the pixel circuit PX in FIG. 27, an insulating layer 162 and an insulating layer 163 are provided between the insulating layer 112 and the insulating layer 161. Specifically, the insulating layer 162 is positioned over the insulating layer 112 and a semiconductor layer 152[1] described later, the insulating layer 163 is positioned over the insulating layer 112 and a conductive layer 131[1] described later, a semiconductor layer 151[3] described later is positioned over the insulating layer 163, and the insulating layer 161 is positioned over the insulating layer 163 and the semiconductor layer 151[3]. For each of the insulating layer 162 and the insulating layer 163, a material usable for the insulating layer 161 can be used.

The transistor M3 illustrated in FIG. 27 includes the semiconductor layer 151[3], a conductive layer 131[3], a conductive layer 132a[3], and a conductive layer 132b[3], for example. The semiconductor layer 151[3], the conductive layer 131[3], the conductive layer 132a[3], and the conductive layer 132b[3] respectively correspond to the semiconductor layer 151, the conductive layer 131, the conductive layer 132a, and the conductive layer 132b in FIGS. 24A to 24C.

In the transistor M3, the insulating layer 161 is provided over each of the insulating layer 163 and the semiconductor layer 151[3], which is different from the structure in FIGS. 24A to 24C.

The semiconductor layer 151[3] contains a metal oxide as an oxide semiconductor, as described above. Thus, it can be said that the semiconductor layer 151[3] includes a low-resistance region and a channel formation region as described with reference to FIG. 26B.

The transistor M1 illustrated in FIG. 27 includes the semiconductor layer 152[1], the conductive layer 131[1], a conductive layer 132a[1], and a conductive layer 132b[1], for example. The semiconductor layer 152[1], the conductive layer 131[1], the conductive layer 132a[1], and the conductive layer 132b[1] respectively correspond to the semiconductor layer 151, the conductive layer 131, the conductive layer 132a, and the conductive layer 132b in FIGS. 24A to 24C.

Note that in the transistor M1, the semiconductor layer 152[1] is provided over the insulating layer 112. The insulating layer 162 is provided over each of the insulating layer 112 and the semiconductor layer 152[1]. This is different from the structure illustrated in FIGS. 24A to 24C.

As described above, the semiconductor layer 152[1] contains low-temperature polysilicon. The semiconductor layer 152[1] includes a region 172a, a region 172b, and a channel formation region 172c. The region 172a, the region 172b, and the channel formation region 172c respectively correspond to the region 171a, the region 171b, and the channel formation region 171c in FIG. 24B.

As described above, the semiconductor layer 152[1] containing low-temperature polysilicon, the insulating layer 162, the conductive layer 131[1], the insulating layer 163, and the semiconductor layer 151[3] containing a metal oxide as an oxide semiconductor are formed in this order over the insulating layer 112, whereby the pixel circuit PX can adopt LTPO.

In the case where the pixel circuit PX adopts LTPO, it should be noted that the conductive layer 131[1] having a function of the gate of the transistor M1 and the conductive layers having a function of gates of the transistors M2 to M8 (typically, the conductive layer 131[3] having a function of the gate of the transistor M3 in FIG. 27) are formed in different steps. In FIG. 27, the conductive layers 132a[1] and 132b[1] having a function of a wiring connected to the source or the drain of the transistor M1 are formed in the same step as the conductive layer having a function of a wiring connected to the source or the drain of each of the transistors M2 to M8 (typically, the conductive layers 132a[3] and 132b[3] having a function of a wiring connected to the source or the drain of the transistor M3 in FIG. 27); however, the semiconductor device of one embodiment of the present invention is not limited to this structure. For example, the conductive layers 132a[1] and 132b[1] may be formed in a different step from that for forming the conductive layers 132a[3] and 132b[3]. Specifically, the conductive layers 132a[3] and 132b[3] are formed between the insulating layer 161 and the insulating layer 113, the conductive layers 132a[1] and 132b[1] are formed over the insulating layer 113, and the conductive layer 132a[3] or 132b[3] is in contact with the conductive layer 132a[1] or 132b[1] through an opening provided in the insulating layer 113, so that a current path may be established.

Since the transistor M1 has a function of a driving transistor, the saturation in I_{ds}−V_{ds} characteristics is preferably higher than those of the transistors M2 to M8. Thus, a channel length Lch[1] of the transistor M1 is preferably larger than a channel length Lch[3] of each of the transistors M2 to M8 (typically, the channel length Lch[3] of the transistor M3 in FIG. 27). Alternatively, the channel length Lch[1] of the transistor M1 may be larger than one or more channel lengths Lch selected from the transistors M2 to M8.

In order to reduce a variation in threshold voltages of the transistors M1 in different pixel circuits PX, the transistor size of the transistor M1 is preferably increased. In other words, the channel width Wch of the transistor M1 is preferably large as well as the channel length Lch[1]. Specifically, the channel width Wch of the transistor M1 is preferably larger than the channel width Wch of each of the transistors M2 to M8 (typically, the transistor M3 in FIG. 27) having a function of a switching transistor. Alternatively, a channel width Wch[1] of the transistor M1 may be larger than one or more channel widths Wch selected from the transistors M2 to M8. Note that FIG. 24C is referred to for the channel width Wch of each of the transistor M1 and the transistor M3.

### Structure Example 1 of Display Apparatus

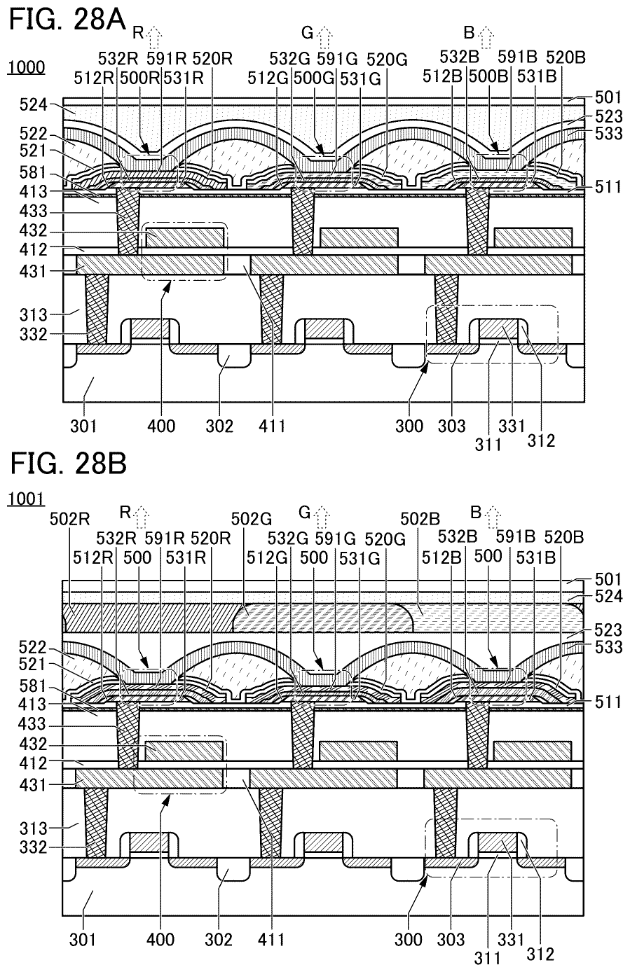

A display apparatus 1000 illustrated in FIG. 28A includes a substrate 301, a light-emitting device 500R, a light-emitting device 500G, a light-emitting device 500B, a capacitor 400, and a transistor 300.

The substrate 301 corresponds to the substrate BS1 in FIGS. 18A, 18B, 19A, and 19B. The transistor 300 includes a channel formation region in the substrate 301. As the substrate 301, a semiconductor substrate such as a single crystal silicon substrate can be used, for example. In the case where a single crystal silicon substrate is used as the substrate 301, the transistor 300 can be a Si transistor.

The transistor 300 includes part of the substrate 301, a conductive layer 331, low-resistance regions 303, an insulating layer 311, and an insulating layer 312. The conductive layer 331 functions as a gate electrode. The insulating layer 311 is positioned between the substrate 301 and the conductive layer 331 and functions as a gate insulating layer. The low-resistance region 303 is a region where the substrate 301 is doped with an impurity, and functions as a source or a drain. The insulating layer 312 is provided to cover the side surface of the conductive layer 331.

An element isolation layer 302 is provided between two adjacent transistors 300 to be embedded in the substrate 301.

An insulating layer 313 is provided to cover the transistor 300, and the capacitor 400 is provided over the insulating layer 313.

As the insulating layers 311 to 313, any of the insulating layers applicable to the insulating layers 111 to 113 described above can be used, for example.

The capacitor 400 includes a conductive layer 431, a conductive layer 432, and an insulating layer 412 positioned between the conductive layers 431 and 432. The conductive layer 431 functions as one electrode of the capacitor 400, the conductive layer 432 functions as the other electrode of the capacitor 400, and the insulating layer 412 functions as a dielectric of the capacitor 400.

For the insulating layer 412, the high-k material applicable to the insulating layers 161, 261 to 264 described above can be used, for example.

The conductive layer 431 is provided over the insulating layer 313 and embedded in an insulating layer 411. The conductive layer 431 is connected to one of a source and a drain of the transistor 300 through a plug 332 embedded in the insulating layer 313. The insulating layer 412 is provided to cover the conductive layer 431. The conductive layer 432 is provided in a region overlapping with the conductive layer 431 with the insulating layer 412 therebetween.

As each of the conductive layer 431 and the conductive layer 432, the conductive layer applicable to the conductive layer 131 described above can be used, for example.

An insulating layer 413 is provided to cover the capacitor 400, an insulating layer 581 is provided over the insulating layer 413, and an insulating layer 511 is provided over the insulating layer 581. The light-emitting devices 500R, 500G, and 500B are provided over the insulating layer 511. An insulator is provided in regions between adjacent light-emitting devices. For example, in FIG. 28A, an inorganic insulating layer 521 and an insulating layer 522 over the inorganic insulating layer 521 are provided in those regions.

As the insulating layer 413, for example, any of the insulating layers applicable to the insulating layers 111 to 113 described above can be used.

An insulating layer 512R is provided to include a region overlapping with a side surface of a conductive layer 531R of the light-emitting device 500R, an insulating layer 512G is provided to include a region overlapping with a side surface of a conductive layer 531G of the light-emitting device 500G, and an insulating layer 512B is provided to include a region overlapping with a side surface of a conductive layer 531B of the light-emitting device 500B. Furthermore, a conductive layer 532R is provided to cover the conductive layer 531R and the insulating layer 512R, a conductive layer 532G is provided to cover the conductive layer 531G and the insulating layer 512G, and a conductive layer 532B is provided to cover the conductive layer 531B and the insulating layer 512B. Furthermore, a sacrificial layer 520R is positioned over an organic compound layer 591R of the light-emitting device 500R, a sacrificial layer 520G is positioned over an organic compound layer 591G of the light-emitting device 500G, and a sacrificial layer 520B is positioned over an organic compound layer 591B of the light-emitting device 500B.

Each of the organic compound layers 591R, 591G, and 591B includes at least a light-emitting layer. Other than the light-emitting layer, each of the organic compound layers includes functional layers such as a hole-injection layer, a hole-transport layer, an electron-transport layer, and an electron-injection layer.

Specifically, the light-emitting device 500R can have such a structure that a hole-injection layer, a hole-transport layer, a light-emitting layer, an electron-transport layer, and an electron-injection layer are stacked in this order from the bottom when the conductive layers 531R and 532R serve as anode and a common electrode 533 serves as a cathode. The light-emitting device 500G can have a structure similar to that of the light-emitting device 500R when the conductive layers 531G and 532G serve as an anode and the common electrode 533 serves as a cathode. The light-emitting device 500B can also have a structure similar to that of the light-emitting device 500R when the conductive layers 531B and 532B serve as an anode and the common electrode 533 serves as a cathode. Such a structure is referred to as a light-emitting device having a single structure in some cases.

The light-emitting layer included in the organic compound layer 591R preferably contains a light-emitting substance exhibiting red, the light-emitting layer included in the organic compound layer 591G preferably contains a light-emitting substance exhibiting green, and the light-emitting layer included in the organic compound layer 591B preferably contains a light-emitting substance exhibiting blue. That is, it is preferable that the light-emitting device 500R exhibit red, the light-emitting device 500G exhibit green, and the light-emitting device 500B exhibit blue. Note that at least one of the light-emitting device 500R, the light-emitting device 500G, and the light-emitting device 500B may exhibit a color other than red, green, and blue. The colors exhibited by the plurality of light-emitting devices provided in the display apparatus 1000 may be one color, two colors, or four or more colors, instead of three colors of red, green, and blue. For example, the plurality of light-emitting devices provided in the display apparatus 1000 may exhibit four colors of red, green, blue, and white, four colors of red, green, blue, and yellow, or four colors of red, green, blue, and infrared light (IR).

Each of the conductive layers 531R, 531G, and 531B is electrically connected to one of the source and the drain of the corresponding transistor 300 through a plug 433 embedded in the insulating layers 412, 413, 581, and 511, the conductive layer 431 embedded in the insulating layer 411, and the plug 332 embedded in the insulating layer 313. The top surface of the insulating layer 511 and the top surface of the plug 433 are level with or substantially level with each other. Any of a variety of conductive materials can be used for the plugs.

Specifically, for example, any of the conductive layers applicable to the conductive layer 131 described above can be used as the plug 433.

The common electrode 533 is provided over the organic compound layer 591R, the sacrificial layer 520R, the organic compound layer 591G, the sacrificial layer 520G, the organic compound layer 591B, the sacrificial layer 520B, the inorganic insulating layer 521, and the insulating layer 522. The common electrode 533 preferably contains a light-transmitting material so as to transmit and eject light emitted from the organic compound layers 591R, 591G, and 591B, toward the above.

A protective layer 523 is provided over the common electrode 533. A substrate 501 is attached to the protective layer 523 with a resin layer 524. The substrate 501 corresponds to the substrate BS2 in FIGS. 18A, 18B, 19A, and 19B.

Note that the display apparatus of one embodiment of the present invention is not limited to the display apparatus 1000 having the structure illustrated in FIG. 28A. The display apparatus of one embodiment of the present invention can have a structure of a display apparatus 1001 illustrated in FIG. 28B as a variation of the display apparatus 1000. The display apparatus 1001 is different from the display apparatus 1000 in that coloring layers 502R, 502G, and 502B are included and light-emitting devices 500 are provided instead of the light-emitting devices 500R, 500G, and 500B. In the display apparatus 1001, each light-emitting device 500 preferably exhibits white, for example. Each of the plurality of light-emitting devices 500 includes a region overlapping with any of the coloring layer 502R, 502G, or 502B. Thus, white light emitted from each of the plurality of light-emitting devices 500 can be transmitted as red light through the coloring layer 502R, green light through the coloring layer 502G, and blue light through the coloring layer 502B.

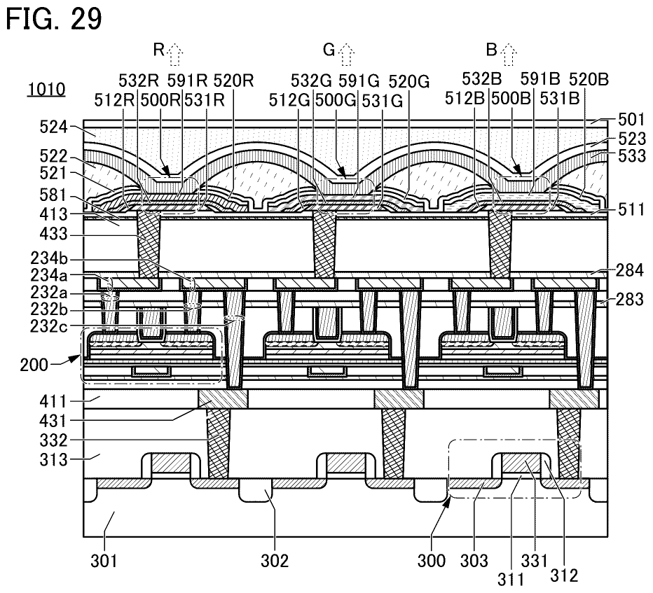

The display apparatus of one embodiment of the present invention can have the structure of a display apparatus 1010 illustrated in FIG. 29 as a variation of the display apparatus 1000. The display apparatus 1010 has a structure in which the transistor 200 illustrated in FIGS. 26A to 26C is provided between a substrate on which the transistor 300 is formed and the layer where light-emitting devices 500R, 500G, and 500B are formed.

In FIG. 29, a plug 232c for ensuring a current path between the conductive layer 431 and the conductive layer 234b is embedded in a stack of the insulating layers between the conductive layer 431 and the conductive layer 234b. The plug 433 for ensuring a current path toward the light-emitting device 500 is positioned on the top surface of the conductive layer 234a. The plug 232c can be formed concurrently with the conductive layers 232a and 232b in some cases.

In FIG. 29, an insulating layer 284 functioning as a barrier layer is provided over the conductive layer 234a and the conductive layer 234b. In particular, the barrier layer preferably inhibits diffusion of impurities from the outside of the transistor 200. This structure enables higher reliability of the display apparatus 1010.

For example, when the substrate 301 is a single crystal substrate containing silicon as a semiconductor substrate, the transistor 300 formed on the substrate 301 can be a Si transistor. The transistor 200 provided above the transistor 300 can be formed by repeating film deposition (by a sputtering method, a CVD method, a PLD method, an ALD method, or the like) and pattern formation (by a lithography method or the like). Thus, an OS transistor or the like can be formed as the transistor 200, for example. Thus, the display apparatus 1010 can include different transistors, i.e., the transistor 200 and the transistor 300.

Alternatively, the transistor 300 formed on the substrate 301 may be a p-channel transistor, and the transistor 200 formed above the transistor 300 may be an n-channel transistor, so that the pixel circuit or the driver circuit included in the display apparatus 1010 is provided as a CMOS circuit. In particular, when only p-channel transistors are employed as the transistors 300 formed on the substrate 301 and n-channel transistors are employed for the transistors 200 formed above the transistor 300, a process for forming an n-channel transistor as the transistor 300 on the substrate 301 is not needed; accordingly, the takt time for forming the transistor 300 provided on the substrate 301 can be shortened. For example, in the pixel circuit PX in FIG. 1B, the transistors M2 to M8 that are n-channel transistors each function as a switching transistor. That is, when such a transistor is used as the transistor 200, the transistor 200 is preferably an OS transistor having characteristics of a low off-state current. In particular, with use of an IO transistor (containing indium oxide in a channel formation region) having a high on/off ratio of current among OS transistors, a malfunction due to leakage current can be inhibited and a circuit with high driving speed can be achieved.

### Structure Example 2 of Display Apparatus

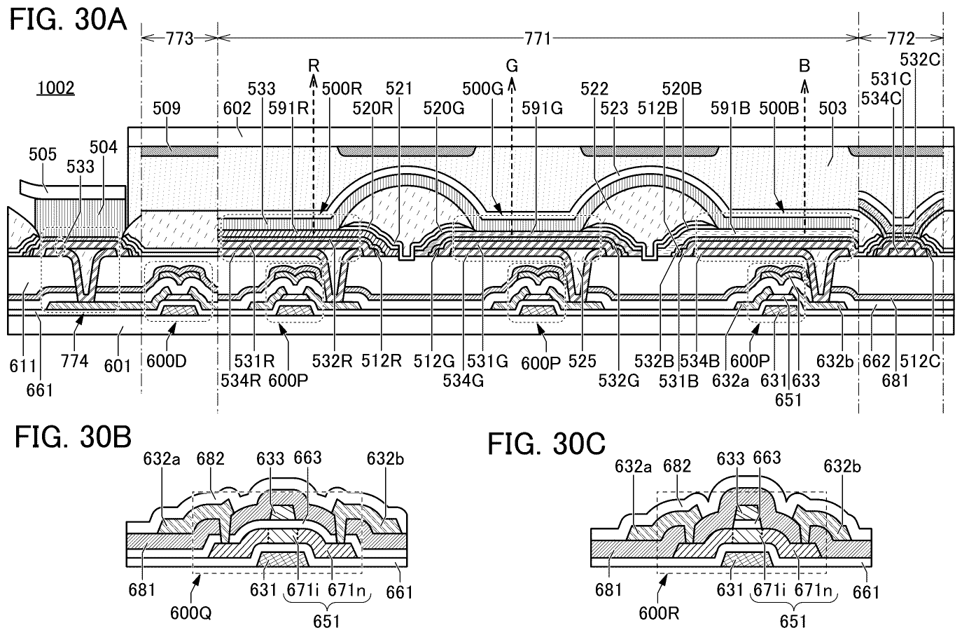

Next, a display apparatus 1002 illustrated in FIG. 30A, which is a display apparatus of one embodiment of the present invention and different from the display apparatuses 1000 and 1001 illustrated in FIGS. 28A and 28B, is described. FIG. 30A is a schematic cross-sectional view of the display apparatus 1002, which is an example of the display apparatus DSP1 in FIG. 18A. The display apparatus 1002 includes a pixel portion 771, a connection portion 772, and a circuit 773, and FIG. 30A shows a cross-sectional example of part of a region including a flexible printed circuit 505, part of the circuit 773, part of the pixel portion 771, part of the connection portion 772, and part of a region including an end portion.

The connection portion 772 is provided outside the pixel portion 771, for example. The connection portion 772 can be provided along one side or a plurality of sides of the pixel portion 771. The number of connection portions 772 may be one or more. In the connection portion 772, a common electrode of a light-emitting device is electrically connected to a conductive layer, so that a potential can be supplied to the common electrode.

As the circuit 773, a driver circuit can be used, for example. Examples of the driver circuit include a source driver circuit and a gate driver circuit.

In the display apparatus 1002 illustrated in FIG. 30A, a substrate 602 and a substrate 601 are bonded to each other. In the display apparatus 1002, a transistor 600D, a transistor 600P, the light-emitting device 500R that emits red light, the light-emitting device 500G that emits green light, and the light-emitting device 500B that emits blue light are provided between the substrate 601 and the substrate 602. To prevent entry of external light from the substrate 601 side or leakage of light emitted from the light-emitting devices to the substrate 601 side, the display apparatus 1002 may be provided with a light-blocking layer on a surface of the substrate 601 opposite to a surface where the transistor 600D and the transistor 600P are provided, for example. Note that the light-blocking layer may be provided between the substrate 601 and each of the transistors 600P and 600D or between the transistors 600P and 600D and each of the light-emitting devices 500R, 500G, and 500B. Note that according to structures, components, and the like of the transistor 600D and the transistor 600P, the characteristics of the transistors might deteriorate owing to external light, e.g., ultraviolet rays; thus, a light-blocking layer is preferably provided to protect the transistor 600D and the transistor 600P.

The light-emitting devices 500R, 500G, and 500B have the stacked-layer structure illustrated in FIGS. 28A and 28B except for the structure of the pixel electrode.

The light-emitting device 500R includes a conductive layer 534R, the conductive layer 531R over the conductive layer 534R, and the conductive layer 532R over the conductive layer 531R. The light-emitting device 500G includes a conductive layer 534G, the conductive layer 531G over the conductive layer 534G, and the conductive layer 532G over the conductive layer 531G. The light-emitting device 500B includes a conductive layer 534B, the conductive layer 531B over the conductive layer 534B, and the conductive layer 532B over the conductive layer 531B. Here, the conductive layers 534R, 531R, and 532R can be collectively referred to as a pixel electrode of the light-emitting device 500R; the conductive layers 531R and 532R excluding the conductive layer 534R can also be referred to as the pixel electrode of the light-emitting device 500R. Similarly, the conductive layers 534G, 531G and 532G can be collectively referred to as a pixel electrode of the light-emitting device 500G; the conductive layers 531G and 532G excluding the conductive layer 534G can also be referred to as the pixel electrode of the light-emitting device 500G. The conductive layers 534B, 531B, and 532B can be collectively referred to as a pixel electrode of the light-emitting device 500B; the conductive layers 531B and 532B excluding the conductive layer 534B can also be referred to as the pixel electrode of the light-emitting device 500B.

The conductive layer 534R is connected to a conductive layer 632b included in the transistor 600P through an opening provided in an insulating layer 611. An end portion of the conductive layer 531R is positioned outward from an end portion of the conductive layer 534R. The insulating layer 512R is provided to include a region that is in contact with the side surface of the conductive layer 531R, and the conductive layer 532R is provided to cover the conductive layer 531R and the insulating layer 512R.

The conductive layers 534G, 531G, and 532G, and the insulating layer 512G in the light-emitting device 500G are not described in detail because they are respectively similar to the conductive layers 534R, 531R, and 532R, and the insulating layer 512R in the light-emitting device 500R; the same applies to the conductive layers 534B, 531B, and 532B, and the insulating layer 512B in the light-emitting device 500B.

The conductive layers 534R, 534G, and 534B each have a depressed portion covering the opening provided in the insulating layer 611. A layer 525 is embedded in the depressed portion.

The layer 525 has a function of filling the depressed portions of the conductive layers 534R, 534G, and 534B. Over the conductive layers 534R, 534G, and 534B and the layer 525, the conductive layers 531R, 531G, and 531B that are respectively electrically connected to the conductive layers 534R, 534G, and 534B are provided. Thus, regions overlapping with the depressions of the conductive layers 534R, 534G, and 534B can also be used as the light-emitting regions, increasing the aperture ratio of the pixels.

The layer 525 may be an insulating layer or a conductive layer. Any of a variety of inorganic insulating materials, organic insulating materials, and conductive materials can be used for the layer 525 as appropriate. Specifically, the layer 525 is preferably formed using an insulating material and is particularly preferably formed using an organic insulating material. The layer 525 can be formed using an organic insulating material usable for the insulating layer 522, for example.

The protective layer 523 is provided over the light-emitting devices 500R, 500G, and 500B. The protective layer 523 and the substrate 602 are bonded to each other with an adhesive layer 503. The substrate 602 is provided with a light-blocking layer 509. A solid sealing structure, a hollow sealing structure, or the like can be employed to seal the light-emitting device 500. In FIG. 30A, a solid sealing structure is employed, in which a space between the substrate 602 and the substrate 601 is filled with the adhesive layer 503. Alternatively, the space may be filled with an inert gas (e.g., nitrogen or argon), i.e., a hollow sealing structure may be employed. In that case, the adhesive layer 503 may be provided in a frame shape not to overlap with the light-emitting device. Furthermore, the space may be filled with a resin other than the frame-like adhesive layer 503.

FIG. 30A illustrates an example in which the connection portion 772 includes a conductive layer 534C obtained by processing the same conductive film as the conductive layers 534R, 534G, and 534B; a conductive layer 531C obtained by processing the same conductive film as the conductive layers 531R, 531G, and 531B; and a conductive layer 532C obtained by processing the same conductive film as the conductive layers 532R, 532G, and 532B. In the example illustrated in FIG. 30A, an insulating layer 512C is provided to include a region overlapping with the side surface of the conductive layer 531C.

The display apparatus 1002 has a top-emission structure. Light emitted from the light-emitting device is emitted toward the substrate 602. For the substrate 602, a material having a high visible-light-transmitting property is preferably used. The pixel electrode includes a material that reflects visible light, and a counter electrode (the common electrode 533) includes a material that transmits visible light.

The transistor 600D and the transistor 600P are both formed over the substrate 601. These transistors can be fabricated using the same materials in the same steps. The transistor 600P and the transistor 600D illustrated in FIG. 30A can employ any of the above-described structures of the transistors. Specifically, for example, the transistor 600P can be the transistor M1 illustrated in FIG. 27. In this case, the transistor M3 illustrated in FIG. 27 can be provided over the substrate 601 in a different step from that for formation of the transistor M1. That is, over the substrate 601, transistors having different semiconductor layers or transistors having different structures can be provided. For example, when the transistor M1 is an LTPS transistor and the transistor M3 is an OS transistor, the pixel circuit of the display apparatus 1002 can adopt LTPO.

Over the substrate 601, an insulating layer 661, an insulating layer 662, an insulating layer 681, and the insulating layer 611 are provided in this order. Part of the insulating layer 661 functions as a gate insulating layer of each transistor. Part of the insulating layer 662 functions as a gate insulating layer of each transistor. The insulating layer 681 is provided to cover the transistors. The insulating layer 611 is provided to cover the transistors and has a function of a planarization layer. Note that the number of gate insulating layers and the number of insulating layers covering the transistors are not limited and may each be one or more.

A material that does not easily allow diffusion of impurities such as water and hydrogen is preferably used for at least one of the insulating layers covering the transistors. This is because such an insulating layer can function as a barrier layer. Such a structure can effectively inhibit diffusion of impurities into the transistors from the outside and improve the reliability of the display apparatus.

An inorganic insulating film is preferably used as each of the insulating layers 661, 662, and 681. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

An organic insulating layer is suitable as the insulating layer 611 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 611 may have a stacked-layer structure of an organic insulating layer and an inorganic insulating layer. The outermost layer of the insulating layer 611 preferably functions as an etching protective layer. This can inhibit formation of a depressed portion in the insulating layer 611 at the time of processing of the conductive layer 534R, 531R, or 532R or the like. Alternatively, a depressed portion may be provided in the insulating layer 611 at the time of processing of the conductive layer 534R, 531R, or 532R or the like.

Each of the transistor 600D and 600P includes a conductive layer 631 functioning as a gate, the insulating layer 661 functioning as a first gate insulating layer, a conductive layer 632a and the conductive layer 632b functioning as a source and a drain, a semiconductor layer 651, the insulating layer 662 functioning as a second gate insulating layer, and a conductive layer 633 functioning as a second gate. Here, a plurality of layers obtained by processing the same conductive film are shown with the same hatching pattern. The insulating layer 661 is positioned between the conductive layer 631 and the semiconductor layer 651. The insulating layer 662 is positioned between the conductive layer 633 and the semiconductor layer 651.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is sandwiched between the first gate and the second gate is employed for each of the transistors 600D and 600P. The first gate and the second gate may be connected to each other and supplied with the same signal to drive the transistor. Alternatively, a potential for controlling the threshold voltage may be applied to one of the first gate and the second gate and a potential for driving may be applied to the other, whereby the threshold voltage of the transistor may be controlled.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

The semiconductor layer of an n-channel transistor preferably includes a metal oxide. That is, a transistor including a metal oxide in its channel formation region (hereinafter referred to as an OS transistor) is preferably used in the display apparatus of this embodiment.

Examples of an oxide semiconductor having crystallinity include a c-axis-aligned crystalline oxide semiconductor (CAAC-OS) and a nanocrystalline oxide semiconductor (nc-OS).

Alternatively, a transistor including silicon in its channel formation region (a Si transistor) may be used. Examples of silicon include single crystal silicon, polycrystalline silicon, and amorphous silicon. In particular, an LTPS transistor containing low-temperature polysilicon in its semiconductor layer can be used. The LTPS transistor has high field-effect mobility and excellent frequency characteristics.

With use of Si transistors such as LTPS transistors, a circuit required to be driven at a high frequency (e.g., a source driver circuit) can be formed on the same substrate as the display portion. This allows simplification of an external circuit mounted on the display apparatus and reductions in component costs and mounting costs.

An OS transistor has much higher field-effect mobility than a transistor including amorphous silicon. In addition, the OS transistor has extremely low leakage current between a source and a drain in an off state (hereinafter also referred to as off-state current), and electric charge accumulated in a capacitor that is connected in series to the transistor can be retained for a long period. Furthermore, the use of an OS transistor can reduce the power consumption of the display apparatus.

To increase the emission luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the emission luminance of the light-emitting device can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, by using OS transistors as the driving transistors included in the pixel circuits, it is possible to suppress black-level degradation, increase the luminance, increase the number of gray levels, and suppress variations in light-emitting devices, for example.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably higher than or equal to the atomic proportion of M in the In-M-Zn oxide. Examples of the atomic ratio of the metal elements, In:M:Zn, in such an In-M-Zn oxide 1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. Note that the neighborhood of the atomic ratio includes ±30% of an intended atomic ratio.

For example, in the case of describing an atomic ratio of In:Ga:Zn as 4:2:3 or a composition in the neighborhood thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn as 5:1:6 or a composition in the neighborhood thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn as 1:1:1 or a composition in the neighborhood thereof, the case is included in which with the atomic proportion of In being 1, the atomic proportion of Ga is greater than 0.1 and less than or equal to 2 and the atomic proportion of Zn is greater than 0.1 and less than or equal to 2.

The transistors included in the circuit 773 and the transistors included in the pixel portion 771 may have the same structure or different structures. One structure or two or more kinds of structures may be employed for a plurality of transistors included in the circuit 773. Similarly, one structure or two or more kinds of structures may be employed for a plurality of transistors included in the pixel portion 771.

All transistors included in the pixel portion 771 may be OS transistors, or all transistors included in the pixel portion 771 may be Si transistors. Alternatively, some of the transistors included in the pixel portion 771 may be OS transistors and the others may be Si transistors.

For example, when both an LTPS transistor and an OS transistor are used (i.e., LTPO is adopted) in the pixel portion 771, the display apparatus can have low power consumption and high driving capability. For example, it is preferable that an OS transistor be used as a transistor functioning as a switch for controlling electrical continuity between wirings and an LTPS transistor be used as a transistor for controlling current. For the structure example of LTPO, the structure illustrated in FIG. 27 can be referred to.

For example, one transistor included in the pixel portion 771 functions as a transistor for controlling a current flowing through the light-emitting device and can be referred to as a driving transistor. One of a source and a drain of the driving transistor is connected to the pixel electrode of the light-emitting device. An LTPS transistor is preferably used as the driving transistor. In that case, the amount of current flowing through the light-emitting device can be increased in the pixel circuit.

Another transistor included in the pixel portion 771 functions as a switch for controlling selection or non-selection of a pixel and can also be referred to as a selection transistor. A gate of the selection transistor is connected to a gate line, and one of a source and a drain thereof is connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having a metal maskless (MML) structure. This structure can significantly reduce a leakage current that would flow through a transistor and a leakage current that would flow between adjacent light-emitting devices (sometimes referred to as a horizontal leakage current or a lateral leakage current). Displaying images on the display apparatus having this structure can bring one or more of image crispness, image sharpness, high color saturation, and a high contrast ratio to the viewer. When a leakage current that would flow through the transistor and a lateral leakage current that would flow between the light-emitting devices are extremely low, leakage of light at the time of black display (black-level degradation) or the like can be minimized.

In particular, in the case where a light-emitting device having an MML structure employs a side-by-side (SBS) structure, which is the above-described structure for separately forming or coloring light-emitting layers, a layer provided between light-emitting devices (for example, also referred to as an organic layer or a common layer which is shared by the light-emitting devices) is disconnected; accordingly, side leakage can be prevented or be made extremely low.

FIGS. 30B and 30C illustrate other structure examples of transistors.

A transistor 600Q and a transistor 600R each include the conductive layer 631 functioning as a gate, the insulating layer 661 functioning as a gate insulating layer, the semiconductor layer 651 including a channel formation region 671i and a pair of low-resistance regions 671n, the conductive layer 632a connected to one of the low-resistance regions 671n, the conductive layer 632b connected to the other of the low-resistance regions 671n, an insulating layer 663 functioning as a gate insulating layer, the conductive layer 633 functioning as a gate, and the insulating layer 681 covering the conductive layer 633. The insulating layer 661 is positioned between the conductive layer 631 and the channel formation region 671i. The insulating layer 663 is positioned at least between the conductive layer 633 and the channel formation region 671i. Furthermore, an insulating layer 682 covering the transistor may be provided.

FIG. 30B illustrates an example of the transistor 600Q in which the insulating layer 663 covers the top and side surfaces of the semiconductor layer 651. The conductive layer 632a and the conductive layer 632b are connected to the corresponding low-resistance regions 671n through the openings provided in the insulating layer 663 and the insulating layer 681. One of the conductive layers 632a and 632b functions as a source and the other functions as a drain.

In the transistor 600R illustrated in FIG. 30C, the insulating layer 663 overlaps with the channel formation region 671i of the semiconductor layer 651 and does not overlap with the low-resistance regions 671n. The structure illustrated in FIG. 30C is obtained by processing the insulating layer 663 with the conductive layer 633 as a mask, for example. In FIG. 30C, the insulating layer 681 is provided to cover the insulating layer 663 and the conductive layer 633, and the conductive layer 632a and the conductive layer 632b are connected to the corresponding low-resistance regions 671n through openings in the insulating layer 681.

A connection portion 774 is provided in a region of the substrate 601 that does not overlap with the substrate 602. The connection portion 774 includes the common electrode 533 as a wiring provided over the substrate 601, and a conductive layer formed concurrently with the conductive layers 632a and 632b. The connection portion 774 is connected to the flexible printed circuit 505 through a connection layer 504.

As an example, the common electrode 533 has a stacked-layer structure of a conductive film obtained by processing the same conductive film as the conductive layers 534R, 534G, and 534B; a conductive film obtained by processing the same conductive film as the conductive layers 531R, 531G, and 531B; and a conductive film obtained by processing the same conductive film as the conductive layers 532R, 532G, and 532B. On the top surface of the connection portion 774, the common electrode 533 is exposed. Thus, the connection portion 774 and the flexible printed circuit 505 can be connected to each other through the connection layer 504.

The light-blocking layer 509 is preferably provided on the surface of the substrate 602 on the substrate 601 side. The light-blocking layer 509 can be provided in a region between adjacent light-emitting devices, in the connection portion 772, in the circuit 773, and the like. A variety of optical members can be arranged on the outer surface of the substrate 602.

A material applicable to the substrate 501 can be used for each of the substrates 601 and 602.

A material that can be used for the resin layer 524 can be used for the adhesive layer 503.

As the connection layer 504, an anisotropic conductive film (ACF), an anisotropic conductive paste (ACP), or the like can be used.

### Structure Example 3 of Display Apparatus

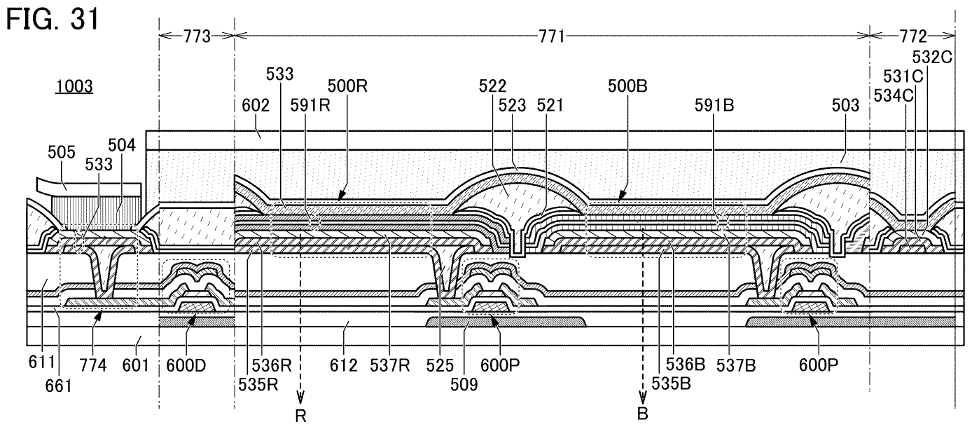

Next, a display apparatus 1003 illustrated in FIG. 31, which is a variation of the display apparatus 1002 illustrated in FIG. 30A, is described as a display apparatus of one embodiment of the present invention. The display apparatus 1003 is different from the display apparatus 1002 in FIG. 30A mainly in having a bottom-emission structure.

Light from the light-emitting device is emitted toward the substrate 601. For the substrate 601, a material having a good property of transmitting visible light is preferably used. By contrast, there is no limitation on the light-transmitting property of a material used for the substrate 602.

The light-blocking layer 509 is preferably formed between the substrate 601 and the transistor 600D and between the substrate 601 and the transistor 600P. FIG. 31 illustrates an example in which the light-blocking layer 509 is provided over the substrate 601, an insulating layer 612 is provided over the light-blocking layer 509, and the transistors 600D and 600P and the like are provided over the insulating layer 612.

The light-emitting device 500R includes a conductive layer 535R, a conductive layer 536R over the conductive layer 535R, and a conductive layer 537R over the conductive layer 536R.

The light-emitting device 500B includes a conductive layer 535B, a conductive layer 536B over the conductive layer 535B, and a conductive layer 537B over the conductive layer 536B.

A material having a high visible-light-transmitting property is used for each of the conductive layers 535R, 535B, 536R, 536B, 537R, and 537B. A material that reflects visible light is preferably used for the common electrode 533.

Although not illustrated in FIG. 31, the light-emitting device 500G is also provided.

Although FIG. 31 and the like illustrate an example in which the top surface of the layer 525 includes a flat portion, the shape of the layer 525 is not particularly limited.

### Structure Example 4 of Display Apparatus

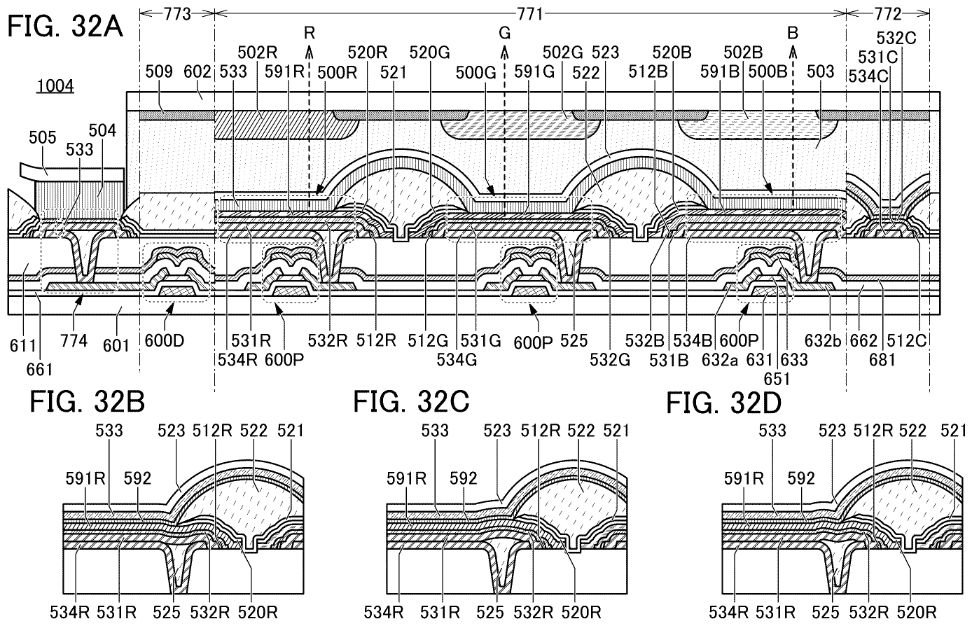

Next, a display apparatus 1004 illustrated in FIG. 32A, which is a variation of the display apparatus 1002 illustrated in FIG. 30A, is described as a display apparatus of one embodiment of the present invention. The display apparatus 1004 illustrated in FIG. 32A is different from the display apparatus 1002 mainly in including the coloring layers 502R, 502G, and 502B.

In the display apparatus 1004, the light-emitting device 500 includes a region overlapping with one of the coloring layers 502R, 502G, and 502B. The coloring layers 502R, 502G, and 502B can be provided on a surface of the substrate 602 on the substrate 601 side. End portions of the coloring layers 502R, 502G, and 502B can overlap with the light-blocking layer 509.

In the display apparatus 1004, the light-emitting device 500 can emit white light, for example. The coloring layer 502R, the coloring layer 502G, and the coloring layer 502B can transmit red light, green light, and blue light, respectively, for example. Note that in the display apparatus 1004, the coloring layers 502R, 502G, and 502B may be provided between the protective layer 523 and the adhesive layer 503.

Next, the layer 525 is described. Although FIG. 30A and FIG. 32A illustrate an example in which the top surface of the layer 525 includes a flat portion, the shape of the layer 525 is not particularly limited. FIGS. 32B, 32C, and 32D show variations of the layer 525.

As illustrated in FIGS. 32B and 32D, the top surface of the layer 525 can have a shape such that its middle and the vicinity thereof are depressed (i.e., a shape including a concave surface) in the cross section. A common layer 592 may be provided so as to be in contact with the common electrode 533.

As illustrated in FIG. 32C, the top surface of the layer 525 can have a shape in which its center and the vicinity thereof bulge (i.e., a shape including a convex surface) in a cross-sectional view.

The top surface of the layer 525 may include one or both of a convex surface and a concave surface. The number of convex surfaces and the number of concave surfaces included in the top surface of the layer 525 are not limited and can each be one or two or more.

The level of the top surface of the layer 525 and the level of the top surface of the conductive layer 534R may be the same or substantially the same, or may be different from each other. For example, the level of the top surface of the layer 525 may be either lower or higher than the level of the top surface of the conductive layer 534R.

In the example illustrated in FIG. 32B, it can be said that the layer 525 fits inside the depression portion of the conductive layer 534R. By contrast, as illustrated in FIG. 32D, the layer 525 is also present outside the depression portion of the conductive layer 534R, i.e., the top surface of the layer 525 may extend beyond the depression portion.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 3

In this embodiment, an indium oxide film that can be used for the semiconductor layer of the transistor included in the semiconductor device of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

The dependence of the Hall mobility on the carrier concentration of indium oxide, silicon, and IGZO will be described.

IGZO has a tendency in which the Hall mobility is higher as the carrier concentration is higher. By contrast, single crystal indium oxide has a tendency in which the Hall mobility is higher as the carrier concentration is lower. This tendency is similar to that of silicon; as the concentration of a dopant (impurity) in a material is lower, impurity scattering is inhibited more and thus the Hall mobility is higher. That is, single crystal indium oxide having higher purity and being more intrinsic has higher Hall mobility. Consequently, the physical properties of single crystal indium oxide are different from those of IGZO and similar to those of silicon. Note that the tendency of non-single-crystal (e.g., polycrystal) indium oxide is sometimes different from that of single crystal indium oxide.

A carrier concentration range suitable for a channel formation region of a transistor is a range including a value of 1×10¹⁵ cm⁻³, e.g., a range higher than or equal to 1×10¹⁴ cm⁻³ and lower than or equal to 1×10¹⁸ cm⁻³. The adequately lowered carrier concentration will increase the Hall mobility to approximately 270 cm²/(V·s).

Indium oxide can include an element that reduces the carrier concentration. Examples of the element that reduces the carrier concentration include magnesium, calcium, zinc, cadmium, and copper. When indium is replaced with any of these elements, the carrier concentration can be reduced. Other examples include nitrogen, phosphorus, arsenic, and antimony. When oxygen is replaced with any of these elements, the carrier concentration can be reduced.

By contrast, an increase in carrier concentration can reduce electrical resistance. A carrier concentration range suitable for a source region and a drain region of a transistor, a resistor, or a transparent conductive film is, for example, a range including a value of 1×10²⁰ cm⁻³, e.g., a range higher than or equal to 1×10¹⁹ cm⁻³ and lower than or equal to 1×10²² cm⁻³. The adequately increased carrier concentration will decrease the resistivity to 1×10⁻⁴ Ω·cm or lower.

Indium oxide can include an element that increases the carrier concentration. For example, the same element as a source electrode and a drain electrode of a transistor is preferably included. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

Accordingly, indium oxide is an oxide whose valence electron can be controlled; a region of indium oxide a low carrier concentration and a region thereof with a high carrier concentration of are used as a channel formation region and source and drain regions, respectively, of a transistor. That is, the indium oxide enables formation of what is called an n-i-n junction (junction between an n-type region, an i-type region, and an n-type region). Incidentally, the valence electron control by a transistor with silicon is generally known, whereas the valence electron control in a transistor containing indium oxide is a novel technical idea that cannot be conceived usually. With use of this technical idea, a transistor that has high mobility, has a low off-state current, can be normally off, and has high reliability can be achieved.

An indium oxide film preferably has crystallinity. In particular, the indium oxide film is preferably a polycrystalline film, further preferably a single crystal film. A single crystal film does not have a crystal grain boundary (also referred to as a grain boundary). The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystalline film is preferable because it can reduce carrier scattering as compared with a microcrystalline film or an amorphous film and enables a transistor to have high field-effect mobility. In the case of using a polycrystalline film, it is preferable to use a film that has as large a crystal grain size as possible and few crystal grain boundaries. In the case where the crystal grain boundary is neither included nor observed in a channel formation region of a transistor including a polycrystalline film, the channel formation region is positioned in a single crystal region included in the polycrystalline film and thus the transistor can be regarded as a transistor including a single crystal film.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be regarded as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A crystal grain, a crystal grain boundary, a crystal axis, a crystal orientation, or the like in a channel formation region can be confirmed in observation of a cross section including a semiconductor layer, a source electrode, and a drain electrode.

Impurities in the indium oxide film can function as a carrier scattering source and thus can cause a reduction in field-effect mobility and inhibit crystal growth. Examples of the impurities for the indium oxide film include boron and silicon. The concentrations of the impurities in the indium oxide film in the channel formation region are preferably as low as possible. For example, the concentrations of the impurity elements are each lower than or equal to 0.1%, preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. For example, oxygen diffusing in an indium oxide film is transmitted through the indium oxide film and released as an oxygen molecule. When reacting with hydrogen contained in the film, oxygen is released as a water molecule in some cases. In the case where the film includes oxygen vacancies, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

Hydrogen diffuses in the indium oxide film. Hydrogen diffusing into the indium oxide film from the outside is transmitted through the indium oxide film and is released as a hydrogen molecule. When reacting with oxygen contained in the film, hydrogen is released as a water molecule.

Indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon, a transistor containing indium oxide can have higher field-effect mobility and lower off-state current than a Si transistor.

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In that case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 4

In this embodiment, electronic devices each including a display apparatus fabricated using one embodiment of the present invention will be described. Electronic devices described in this embodiment as examples are each provided with a display apparatus of one embodiment of the present invention in a display portion. Thus, the electronic devices achieve high definition.

One embodiment of the present invention includes the display apparatus and one or more selected from an antenna, a battery, a housing, a camera, a speaker, a microphone, a touch panel, and an operation button.

The electronic device of one embodiment of the present invention may include a secondary battery. It is preferable that the secondary battery be capable of being charged by non-contact power transmission.

Examples of the secondary battery include a lithium ion secondary battery (such as a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna may be used for contactless power transmission.

The display portion of the electronic device of one embodiment of the present invention can display, for example, an image with full high definition, 4K2K, 8K4K, 16K8K, or higher display resolution.

As examples of the electronic device, electronic devices having a relatively large screen, such as a television device, a laptop personal computer, a monitor device, digital signage, a pachinko machine, and a game machine are given. In addition, as the electronic device, such as a digital camera, a digital video camera, a digital photo frame, a mobile phone device, a portable game machine, a portable information terminal, and an audio reproducing device are given.

An electronic device to which one embodiment of the present invention is applied can be incorporated along a flat surface or a curved surface of an inner wall or an outer wall of a house or a building. The electronic device can be incorporated along a flat surface or a curved surface of an interior or an exterior of an automobile or the like.

### [Mobile Phone]

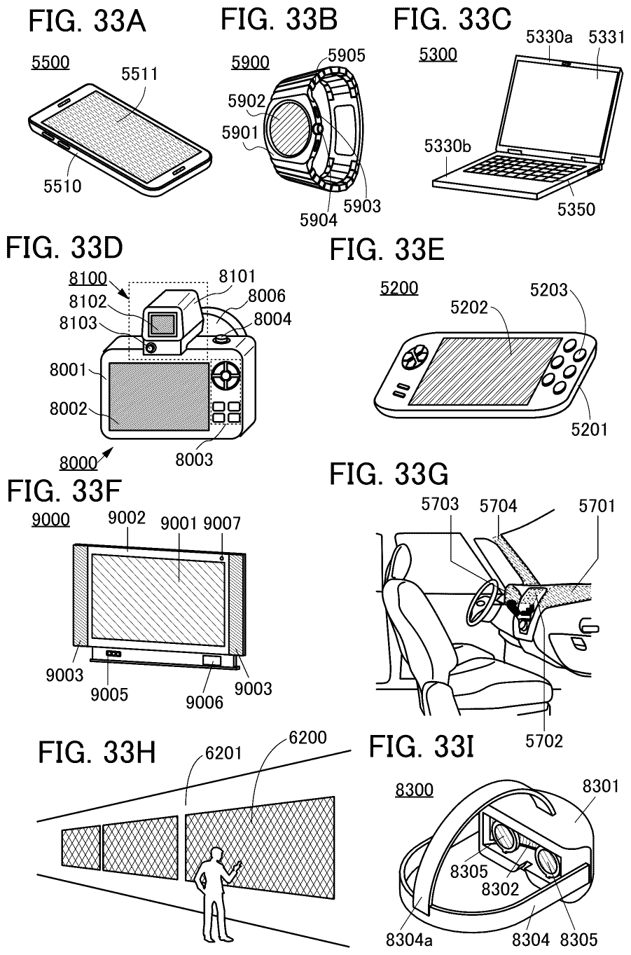

An information terminal 5500 illustrated in FIG. 33A is a mobile phone (a smartphone), which is a type of information terminal. The information terminal 5500 includes a housing 5510 and a display portion 5511. As input interfaces, a touch panel and a button are provided in the display portion 5511 and the housing 5510, respectively.

### [Wearable Terminal]

FIG. 33B is an external view of an information terminal 5900 as an example of a wearable terminal. The information terminal 5900 includes a housing 5901, a display portion 5902, an operation button 5903, a crown 5904, and a band 5905.

### [Information Terminal]

FIG. 33C illustrates a notebook information terminal 5300. The notebook information terminal 5300 in FIG. 33C includes, for example, a display portion 5331 in a housing 5330a and a keyboard portion 5350 in a housing 5330b.

Note that although FIGS. 33A to 33C illustrate a smartphone, a wearable terminal, and a notebook information terminal as examples of electronic devices, one embodiment of the present invention can also be applied to an information terminal other than a smartphone, a wearable terminal, and a notebook information terminal. Examples of the information terminals other than a smartphone, a wearable terminal, and a notebook information terminal include a personal digital assistant (PDA), a desktop information terminal, and a workstation.

### [Camera]

FIG. 33D is an external view of a camera 8000 to which a finder 8100 is attached. The camera 8000 includes a housing 8001, a display portion 8002, operation buttons 8003, and a shutter button 8004. Furthermore, a detachable lens 8006 is attached to the camera 8000. The finder 8100 includes a housing 8101, a display portion 8102, and a button 8103.

Note that the lens 8006 may be included in the housing of the camera 8000.

Images can be taken with the camera 8000 by the press of the shutter button 8004 or the touch of the display portion 8002 serving as a touch panel.

The housing 8001 includes a mount including an electrode, so that a stroboscope, for example, as well as the finder 8100 can be connected to the housing.

The housing 8101 is attached to the camera 8000 by a mount for engagement with the mount of the camera 8000. The finder 8100 can display an image received from the camera 8000 on the display portion 8102.

The button 8103 functions as a power supply button.

A display apparatus of one embodiment of the present invention can be used in the display portion 8002 of the camera 8000 and the display portion 8102 of the finder 8100. Note that a finder may be incorporated in the camera 8000.

### [Game Machines]

FIG. 33E is an external view of a portable game machine 5200 as an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

The portable game machine 5200 can have low power consumption by including the display apparatus described in the above embodiment. Furthermore, heat generation from a circuit can be reduced owing to low power consumption; thus, the influence of heat generation on the circuit, the peripheral circuit, and the module can be reduced.

Although FIG. 33E illustrates the portable game machine as an example of a game machine, the electronic device of one embodiment of the present invention is not limited thereto. Examples of the electronic device of one embodiment of the present invention include a stationary game machine, an arcade game machine installed in an entertainment facility (e.g., a game center or an amusement park), and a throwing machine for batting practice installed in sports facilities.

### [Television Device]

FIG. 33F is a perspective view illustrating a television device. The television device 9000 includes a housing 9002, a display portion 9001, a speaker 9003, an operation key 9005 (including a power switch or an operation switch), a connection terminal 9006, a sensor 9007 (e.g., a sensor having a function of measuring force, displacement, position, speed, acceleration, angular velocity, rotational frequency, distance, light (including infrared rays), liquid, magnetism, temperature, chemical substance, sound, time, hardness, electric field, current, voltage, power, radiation, flow rate, humidity, gradient, oscillation, or odor or a sensor having a function of sensing or detecting odor or light). The memory device of one embodiment of the present invention can be provided in the television device. The television device can include the display portion 9001 having a screen size of, for example, 50 inches or more, or 100 inches or more.

The television device 9000 to which the display apparatus described in the above embodiment is applied achieves low power consumption. Furthermore, heat generation from a circuit can be reduced owing to low power consumption; thus, the influence of heat generation on the circuit, the peripheral circuit, and the module can be reduced.

### [Moving Vehicle]

The display apparatus of one embodiment of the present invention can be used around a driver's seat in a car, which is a moving vehicle.

FIG. 33G illustrates the vicinity of a windshield inside a car. FIG. 33G shows a display panel 5701, a display panel 5702, and a display panel 5703 which are attached to a dashboard, and a display panel 5704 attached to a pillar.

The display panels 5701 to 5703 can display various kinds of information by displaying navigation data, a speedometer, a tachometer, a mileage, a fuel meter, a gearshift state, air-conditioning settings, and the like. Items displayed on the display panel and their layout can be changed as appropriate to suit the user's preferences, resulting in more sophisticated design. The display panels 5701 to 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car body leads to elimination of blind areas and enhancement of safety. Moreover, displaying a video to compensate for the area that a driver cannot see makes it possible for the driver to confirm safety more easily and comfortably. The display panel 5704 can also be used as a lighting device.

The display apparatus of one embodiment of the present invention can be used for the display panels 5701 to 5704, for example.

Note that although an automobile is described above as an example of a moving vehicle, the moving vehicle is not limited to an automobile. Examples of the moving vehicles include a train, a monorail train, a ship, and a flying object (a helicopter, an unmanned aircraft (a drone), an airplane, and a rocket), and these moving vehicles can use the display apparatus of one embodiment of the present invention.

### [Digital Signage]

FIG. 33H illustrates an example of a digital signage that can be attached to a wall. FIG. 33H illustrates a state where a digital signage 6200 is attached to a wall 6201. The display apparatus of one embodiment of the present invention can be used in a display portion in the digital signage 6200, for example. An interface such as a touch panel may be provided in the digital signage 6200.

Note that an electronic device attachable to a wall is described above as an example of a digital signage, the kind of the digital signage is not limited thereto. Examples of the digital signage include a digital signage mounted on a pillar, a freestanding digital signage placed on the ground, and a digital signage mounted on a rooftop or a side wall of a building.

### [Head-Mounted Display]

FIG. 33I is an external view of an electronic device 8300 which is a head-mounted display for VR, for example. The electronic device 8300 includes the housing 8301, a display portion 8302, a band-like fixing member 8304, a fixture member 8304a worn on a head, and a pair of lenses 8305.

Although not illustrated in FIG. 33I, the electronic device 8300 may include an interface such as an operation button or a power button.

A user can see display on the display portion 8302 through the lenses 8305. The display portion 8302 is preferably curved because the user can feel a high realistic sensation. Another image displayed in another region of the display portion 8302 is viewed through the lenses 8305, so that three-dimensional display using parallax can be performed. Note that the number of the display portions 8302 is not limited to one; two display portions 8302 may be provided for user's respective eyes.

As the display portion 8302, a display apparatus with high resolution is preferably used, for example. With use of a display apparatus with extremely high resolution for the display portion 8302, even when the display portion 8302 is enlarged by the lens 8305, a more realistic image can be displayed without user's visual recognition of pixels.

The head-mounted display, which is an electronic device of one embodiment of the present invention, may be an electronic device which is a glasses-type head-mounted display, instead of the electronic device 8300 in FIG. 33I, which is a goggle-types head-mounted display. In particular, a glasses-type head-mounted display is suitable for an electronic device for AR.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

This application is based on Japanese Patent Application Serial No. 2025-040662 filed with Japan Patent Office on Mar. 13, 2025, the entire contents of which are hereby incorporated by reference.

What is claimed is:

1. A semiconductor device comprising:
a first transistor, a second transistor, a third transistor, a fourth transistor, a fifth transistor, a sixth transistor, a seventh transistor, an eighth transistor, a first capacitor, a second capacitor, a third capacitor, and a light-emitting device,
wherein the first transistor is a p-channel transistor,
wherein the second transistor, the third transistor, the fourth transistor, the fifth transistor, the sixth transistor, the seventh transistor, and the eighth transistor are each an n-channel transistor,
wherein one of a source and a drain of the first transistor is electrically connected to one of a source and a drain of the third transistor and one of a source and a drain of the sixth transistor,
wherein a gate of the first transistor is electrically connected to a first terminal of the first capacitor and one of a source and a drain of the eighth transistor,
wherein the other of the source and the drain of the sixth transistor is electrically connected to one of a source and a drain of the seventh transistor and an anode of the light-emitting device,
wherein the other of the source and the drain of the third transistor is electrically connected to the other of the source and the drain of the eighth transistor and one of a source and a drain of the fourth transistor,
wherein a second terminal of the first capacitor is electrically connected to one of a source and a drain of the second transistor, one of a source and a drain of the fifth transistor, a first terminal of the second capacitor, and a first terminal of the third capacitor,
wherein the other of the source and the drain of the first transistor and a second terminal of the second capacitor are each electrically connected to a first wiring,
wherein a second terminal of the third capacitor is electrically connected to a second wiring, and
wherein a gate of the third transistor and a gate of the fifth transistor are each electrically connected to a third wiring.

2. The semiconductor device according to claim 1,
wherein the p-channel transistor comprises a first semiconductor layer comprising silicon, and
wherein the n-channel transistor comprises a second semiconductor layer comprising an oxide semiconductor.

3. The semiconductor device according to claim 2, wherein the oxide semiconductor comprises indium.

4. The semiconductor device according to claim 3,
wherein the oxide semiconductor comprises at least one of zinc and an element M, and
wherein the element Mis at least one selected from aluminum, gallium, silicon, yttrium, tin, copper, vanadium, chromium, manganese, beryllium, boron, titanium, iron, nickel, germanium, zirconium, molybdenum, lanthanum, cerium, neodymium, hafnium, tantalum, tungsten, magnesium, calcium, strontium, barium, cobalt, and antimony.

5. The semiconductor device according to claim 1,
wherein the n-channel transistor comprises a back gate, and
wherein the gate and the back gate of the n-channel transistor are electrically connected to each other.
